(19) United States
(12) Patent Application Publication
(10) Pub. No.: US 2013/0228724 A1
(43) Pub. Date: Sep. 5, 2013

(54) POLYMER COMPOUND AND PRODUCTION METHOD THEREOF

(71) Applicants: Kazuei Ohuchi, Tsukuba-shi (JP); Mari Seto, Takarazuka-shi (JP)

(72) Inventors: Kazuei Ohuchi, Tsukuba-shi (JP); Mari Seto, Takarazuka-shi (JP)

(73) Assignee: SUMITOMO CHEMICAL COMPANY, LIMITED, Chuo-ku, Tokyo (JP)

(21) Appl. No.: 13/885,004

(22) PCT Filed: Nov. 14, 2011
(86) PCT No.: PCT/JP2011/076609

§ 371 Date: May 13, 2013

(30) Foreign Application Priority Data
Nov. 15, 2010 (JP) 2010-254540

(51) Int. Cl. H01L 51/00

(52) U.S. Cl. CPC H01L 51/0039
USPC 252/500; 528/422; 252/301.35

(57) ABSTRACT

A polymer compound comprising as a constitutional unit a residue of a compound represented by the following general formula:

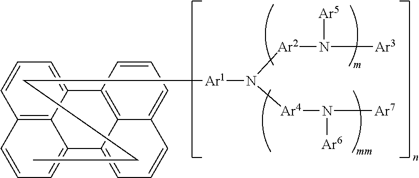

wherein
n is an integer of 1 to 4;
m and mm are 0 or 1;
Ar¹ represents an arylene group or a divalent aromatic heterocyclic group;
Ar² and Ar⁴ represent an arylene group, a divalent aromatic heterocyclic group or a divalent group obtained by linking two or more identical or different groups selected from the group consisting of an arylene group and a divalent aromatic heterocyclic group;
Ar³, Ar⁵, Ar⁶ and Ar⁷ each independently represent an aryl group or a monovalent aromatic heterocyclic group;
R^{A} represents an alkyl group, an aryl group or a monovalent aromatic heterocyclic group.

### TECHNICAL FIELD

The present invention relates to a polymer compound containing as a constitutional unit a perylene skeleton having an aromatic amine residue, a composition containing the polymer compound, and the like.

### BACKGROUND ART

Known as a light emitting material to be used in an organic light emitting device are polymer compounds containing as a repeating unit only a perylenediyl group and a fluorenediyl group (Synthetic Metals 102 (1999) 1087-1088).

### DISCLOSURE OF THE INVENTION

An organic light emitting device using the above-described polymer compound, however, has not necessarily sufficient light emission efficiency.

The present invention has an object of providing a polymer compound which is useful for production of an organic light emitting device excellent in light emission efficiency. Further, the present invention has an object of providing a composition containing the polymer compound, and the like.

The present invention provides the following [1] to [24].

[1] A polymer compound comprising as a constitutional unit a residue of a compound represented by the following general formula (1):

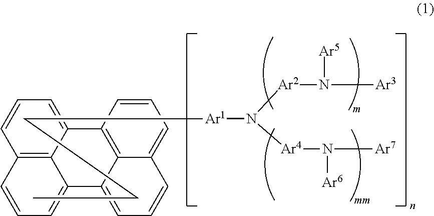

wherein

n is an integer of 1 to 4;

m and mm are each independently 0 or 1;

Ar¹ represents an arylene group or a divalent aromatic heterocyclic group,

Ar² and Ar⁴ each independently represent an arylene group, a divalent aromatic heterocyclic group or a divalent group obtained by linking two or more identical or different groups selected from the group consisting of an arylene group and a divalent aromatic heterocyclic group,

Ar³, Ar⁵, Ar⁶ and Ar⁷ each independently represent an aryl group or a monovalent aromatic heterocyclic group,

Ar¹, Ar², Ar³, Ar⁴, Ar⁵, Ar⁶ and Ar⁷ may have one or several substituents selected from the group consisting of an alkyl group, an aryl group, a monovalent aromatic heterocyclic group, a group represented by —O—R^{A}, a group represented by —S—R^{A}, a group represented by —C(═O)—R^{A}, a group represented by —C(═O)—O—R^{A}, a cyano group and a fluorine atom, and

of groups represented by Ar¹, Ar², Ar³, Ar⁴, Ar⁵, Ar⁶ and Ar⁷, groups linked to the same nitrogen atom may be mutually linked via a single bond or a group represented by —O—, —S—, —C(═O)—, —C(═O)—O—, —N(R^{A})—, —C(═O)—N(R^{A})— or —C(R^{A})(R^{A})—;

R^{A} represents an alkyl group, an aryl group or a monovalent aromatic heterocyclic group, and these groups may have a substituent, when a plurality of R^{A}s are present, these may be the same or different.

[2] The polymer compound according to [1], wherein the compound represented by the above-described general formula (1) is a compound represented by the following general formula (1a) or the following general formula (1b):

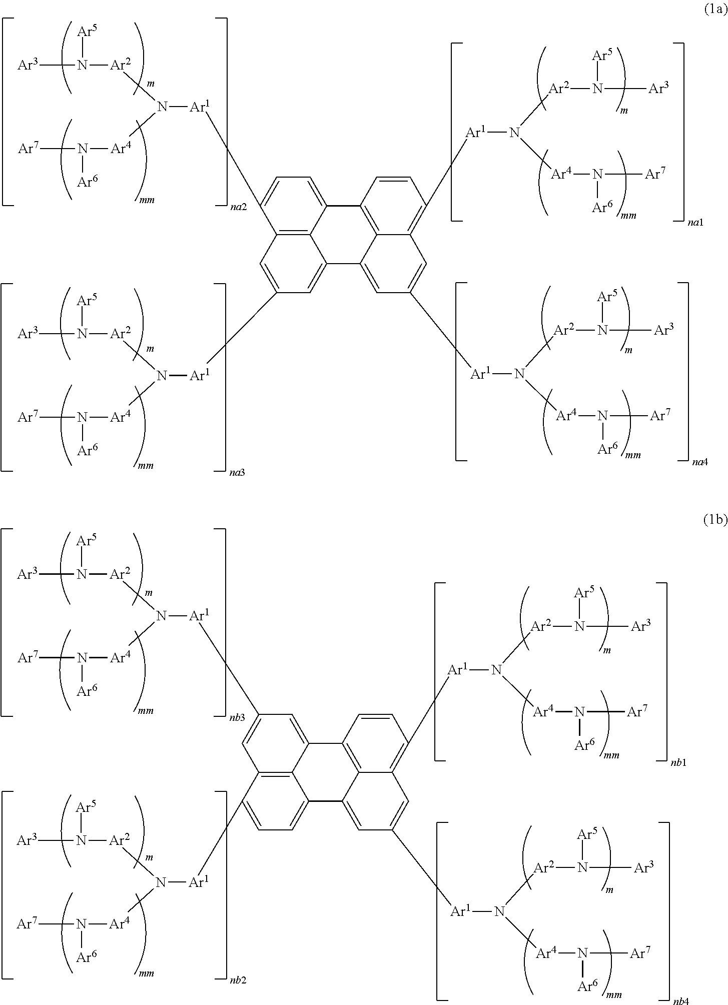

wherein

m, mm, Ar¹, Ar², Ar³, Ar⁴, Ar⁵, Ar⁶ and Ar⁷ represent the same meaning as described above. na1, na2, na3, na4, nb1, nb2, nb3 and nb4 are each independently 0 or 1,

with the proviso that at least one of na1, na2, na3 and na4 is 1, and at least one of nb1, nb2, nb3 and nb4 is 1,

when there are a plurality of ms, mms, Ar¹s, Ar²s, Ar³s, Ar⁴s, Ar⁵s, Ar⁶s and Ar⁷s, respective symbols may be the same or different.

[3] The polymer compound according to [2], wherein na1 and nb1 are 1 and na3, na4, nb3 and nb4 are 0.

[4] The polymer compound according to [3], wherein na1 and nb2 are 0.

[5] The polymer compound according to [4], wherein m is 1 and mm is 0.

[6] The polymer compound according to anyone of [1] to [5], further comprising a constitutional unit represented by the following general formula (2):

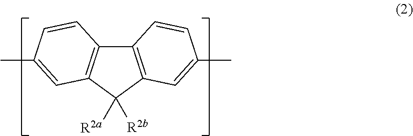

wherein

R^{2a} and R^{2b} each independently represent an alkyl group, an aryl group or a monovalent aromatic heterocyclic group, alternatively R^{2a} and R^{2b} are mutually linked together to represent a divalent group;

the constitutional unit represented by the formula (2) may have one or several substituents selected from the group consisting of an alkyl group, an aryl group, a monovalent aromatic heterocyclic group, a group represented by —O—R^{A}, a group represented by —S—R^{A}, a group represented by —C(═O)—R^{A}, a group represented by —C(═O)—O—R^{A}, a group represented by —N(R^{A})₂, a cyano group and a fluorine atom;

R^{A} represents the same meaning as described above.

[7] The polymer compound according to [6], wherein the content of the constitutional unit composed of the residue of the compound represented by the above-described general formula (1) is 0.1% by mol or more and 20% by mol or less with respect to the total content of the constitutional unit composed of the residue of the compound represented by the above-described general formula (1) and the constitutional unit represented by the above-described general formula (2).

[8] The polymer compound according to [6] or [7], wherein the total content of the constitutional unit composed of the residue of the compound represented by the above-described general formula (1) and the constitutional unit represented by the above-described general formula (2) is 80% by mass or more with respect to the total amount of the above-described polymer compound.

[9] The polymer compound according to [6], further comprising a constitutional unit represented by the following general formula (3):

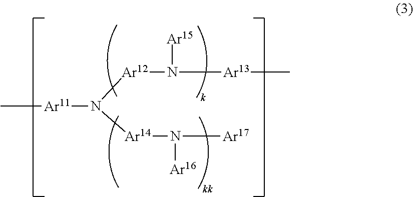

wherein

k and kk are each independently 0 or 1;

Ar¹¹, Ar¹², Ar¹³ and Ar¹⁴ each independently represent an arylene group, a divalent aromatic heterocyclic group or a divalent group obtained by linking two or more identical or different groups selected from the group consisting of an arylene group and a divalent aromatic heterocyclic group,

Ar¹⁵, Ar¹⁶ and Ar¹⁷ each independently represent an aryl group or a monovalent aromatic heterocyclic group,

Ar¹¹, Ar¹², Ar¹³, Ar¹⁴, Ar¹⁵, Ar¹⁶ and Ar¹⁷ may have one or several substituents selected from the group consisting of an alkyl group, an aryl group, a monovalent aromatic heterocyclic group, a group represented by —O—R^{A}, a group represented by —S—R^{A}, a group represented by —C(═O)—R^{A}, a group represented by —C(═O)—O—R^{A}, a cyano group and a fluorine atom, and of groups represented by Ar¹¹, Ar¹², Ar¹³, Ar¹⁴, Ar¹⁵, Ar¹⁶ and Ar¹⁷, groups linked to the same nitrogen atom may be mutually linked via a single bond or a group represented by —O—, —S—, —C(═O)—, —C(═O)—O—, —N(R^{A})—, —C(═O)—N(R^{A})— or —C(R^{A})(R^{A})—;

R^{A} represents the same meaning as described above.

[10] The polymer compound according to [9], wherein the content of the constitutional unit composed of the residue of the compound represented by the above-described general formula (1) is 0.1% by mol or more and 15% by mol or less with respect to the total content of the constitutional unit composed of the residue of the compound represented by the above-described general formula (1), the constitutional unit represented by the above-described general formula (2) and the constitutional unit represented by the above-described general formula (3).

[11] The polymer compound according to [9] or [10], wherein the total content of the constitutional unit composed of the residue of the compound represented by the above-described general formula (1), the constitutional unit represented by the above-described general formula (2) and the constitutional unit represented by the above-described general formula (3) is 80% by mass or more with respect to the total amount of the above-described polymer compound.

[12] The polymer compound according to any one of [2] to [11], comprising as a constitutional unit a residue of a compound represented by the above-described general formula (1a) and comprising as a constitutional unit a residue of a compound represented by the above-described general formula (1b).

[13] The polymer compound according to any one of [1] to [12], further comprising a constitutional unit derived from a phosphorescent compound.

[14] A composition comprising the polymer compound according to any one of [1] to [13] and at least one material selected from the group consisting of a hole transporting material, an electron transporting material and a light emitting material (hereinafter, referred to as “high molecular weight composition”).

[15] A composition comprising the polymer compound according to any one of [1] to [13] and a solvent.

[16] A composition comprising the polymer compound according to any one of [1] to [13], a solvent and at least one material selected from the group consisting of a hole transporting material, an electron transporting material and a light emitting material.

[17] An organic film comprising the polymer compound according to any one of [1] to [13] or the composition according to [14].

[18] An organic film produced by using the composition according to [15] or [16].

[19] An organic semiconductor device having the organic film according to [17].

[20] An organic light emitting device having the organic film according to [17].

[21] A surface light source having the organic light emitting device according to [20].

[22] A display having the organic light emitting device according to [20].

[23] A compound represented by the following general formula (Ma) or the following general formula (Mb):

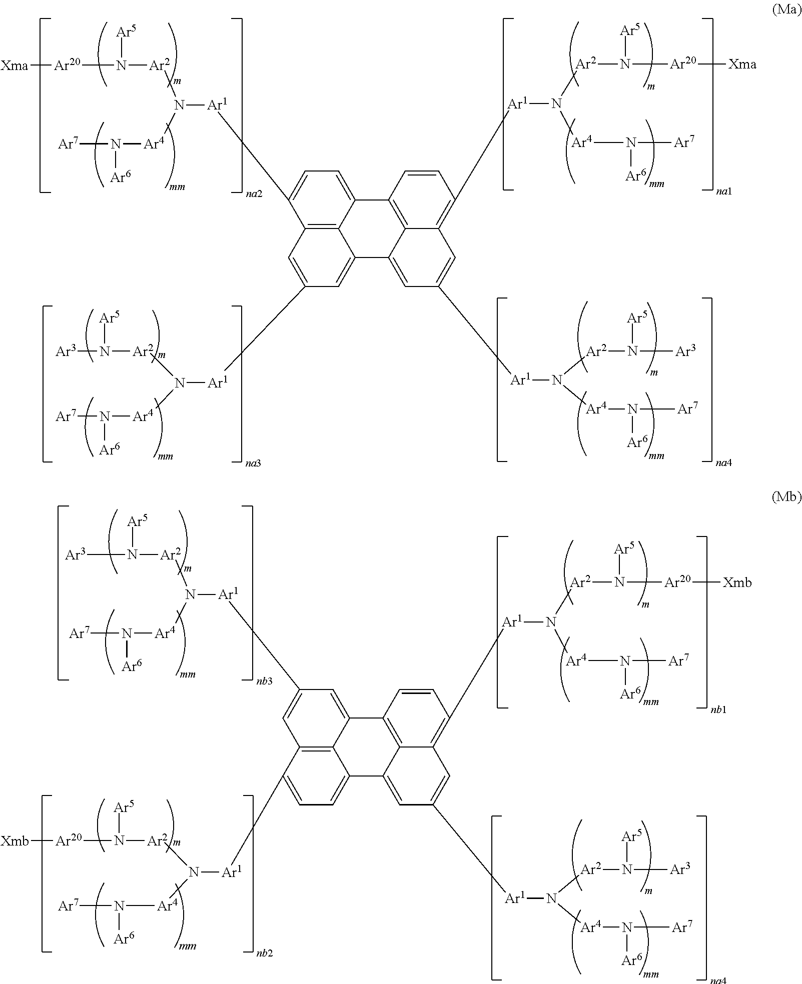

wherein

m and mm are each independently 0 or 1;

Ar¹ represents an arylene group or a divalent aromatic heterocyclic group,

Ar² and Ar⁴ each independently represent an arylene group, a divalent aromatic heterocyclic group or a divalent group obtained by linking two or more identical or different groups selected from the group consisting of an arylene group and a divalent aromatic heterocyclic group,

Ar³, Ar⁵, Ar⁶ and Ar⁷ each independently represent an aryl group or a monovalent aromatic heterocyclic group,

Ar¹, Ar², Ar³, Ar⁴, Ar⁵, Ar⁶ and Ar⁷ may have one or several substituents selected from the group consisting of an alkyl group, an aryl group, a monovalent aromatic heterocyclic group, a group represented by —O—R^{A}, a group represented by —S—R^{A}, a group represented by —C(═O)—R^{A}, a group represented by —C(═O)—O—R^{A}, a cyano group and a fluorine atom, and
of groups represented by Ar¹, Ar², Ar³, Ar⁴, Ar⁵, Ar⁶ and Ar⁷, groups linked to the same nitrogen atom may be mutually linked via a single bond or a group represented by —O—, —S—, —C(═O)—C(═O)—O—, —N(R^{A})—C(═O)—N(R^{A})— or —C)(R^{A})—;

R^{A} represents an alkyl group, an aryl group or a monovalent aromatic heterocyclic group, and these groups may have a substituent, when a plurality of R^{A}s are present, these may be the same or different;

na1, na2, na3, na4, nb1, nb2, nb3 and nb4 are each independently 0 or 1,

with the proviso that at least one of na1, na2, na3 and na4 is 1, and at least one of nb1, nb2, nb3 and nb4 is 1,

when there are a plurality of ms, rams, Ar¹s, Ar²s, Ar³s, Ar⁴s, Ar⁵s, Ar⁶s and Ar⁷s, respective symbols may be the same or different;

Ar²⁰ represents an arylene group or a divalent aromatic heterocyclic group, and when there are a plurality of Ar²⁰s, these may be the same or different;

Xma and Xmb each independently represent a group selected from the group consisting of the following substituent group A and the following substituent group B, and two Xmas may be the same or different and two Xmbs may be the same or different;

### (Substituent Group A)

a chlorine atom, a bromine atom, an iodine atom and groups represented by —O—S(═O)₂R²⁰ wherein R²⁰ represents an alkyl group or an aryl group optionally substituted by an alkyl group, an alkoxy group, a nitro group, a fluorine atom or a cyano group;

### (Substituent Group B)

groups represented by —B(OR²¹)₂ wherein R²¹ represents a hydrogen atom or an alkyl group, two R²¹s may be the same or different, and may be mutually linked together to form a ring,

groups represented by —BF₄Q¹ wherein Q¹ represents a monovalent cation of lithium, sodium, potassium, rubidium or cesium,

groups represented by —Sn(R²²)₃ wherein R²² represents a hydrogen atom or an alkyl group, three R²²s may be the same or different, and may be mutually linked together to form a ring,

groups represented by —MgY¹ wherein Y¹ represents a chlorine atom, a bromine atom or an iodine atom, and

groups represented by —ZnY² wherein Y² represents a chlorine atom, a bromine atom or an iodine atom.

[24] A composition comprising a compound represented by the following general formula (Ma) and a compound represented by the following general formula (Mb) (hereinafter, referred to as “low molecular weight composition”):

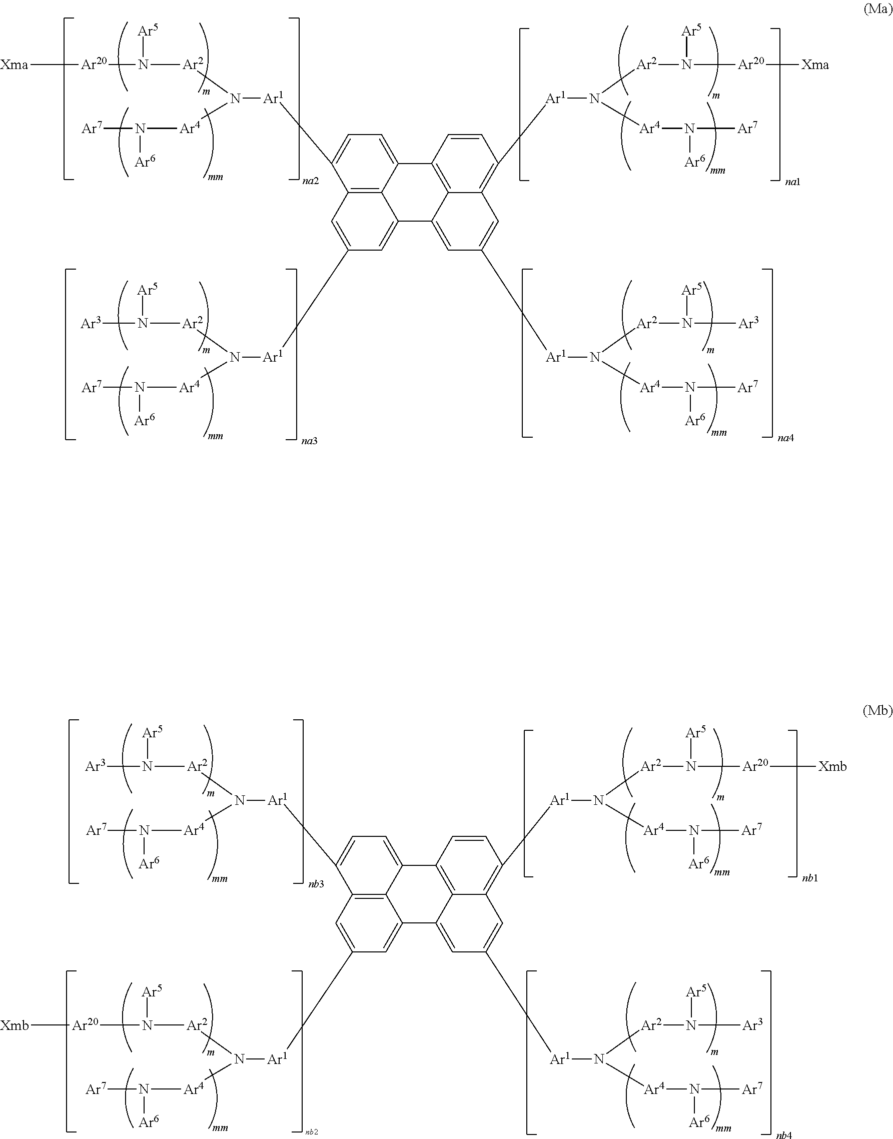

wherein

m and mm are each independently 0 or 1;

Ar¹ represents an arylene group or a divalent aromatic heterocyclic group,

Ar² and Ar⁴ each independently represent an arylene group, a divalent aromatic heterocyclic group or a divalent group obtained by linking two or more identical or different groups selected from the group consisting of an arylene group and a divalent aromatic heterocyclic group,

Ar³, Ar⁵, Ar⁶ and Ar⁷ each independently represent an aryl group or a monovalent aromatic heterocyclic group,

Ar¹, Ar², Ar³, Ar⁴, Ar⁵, Ar⁶ and Ar⁷ may have one or several substituents selected from the group consisting of an alkyl group, an aryl group, a monovalent aromatic heterocyclic group, a group represented by —O—R^{A}, a group represented by —S—R^{A}, a group represented by —C(═O)—R^{A}, a group represented by —C(═O)—O—R^{A}, a cyano group and a fluorine atom, and

of groups represented by Ar¹, Ar², Ar³, Ar⁴, Ar⁵, Ar⁶ and Ar⁷, groups linked to the same nitrogen atom may be mutually linked via a single bond or a group represented by —O—, —S—, —C(═O)—, —C(═O)—O—, —N(R^{A})—, —C(═O)—N(R^{A})— or —C(R^{A})(R^{A})—;

R^{A} represents an alkyl group, an aryl group or a monovalent aromatic heterocyclic group, and these groups may have a substituent, when a plurality of R^{A}s are present, these may be the same or different;

na1, na2, na3, na4, nb1, nb2, nb3 and nb4 are each independently 0 or 1,

with the proviso that at least one of na1, na2, na3 and na4 is 1, and at least one of nb1, nb2, nb3 and nb4 is 1,

when there are a plurality of ms, rams, Ar¹s, Ar²s, Ar³s, Ar⁴s, Ar⁵s, Ar⁶s and Ar⁷s, respective symbols may be the same or different;

Ar²⁰ represents an arylene group or a divalent aromatic heterocyclic group, and when there are a plurality of Ar²⁰s, these may be the same or different;

Xma and Xmb each independently represent a group selected from the group consisting of the following substituent group A and the following substituent group B, and two Xmas may be the same or different and two Xmbs may be the same or different;

### (Substituent Group A)

a chlorine atom, a bromine atom, an iodine atom and groups represented by —O—S(═O)₂R²⁰ wherein R²⁰ represents an alkyl group or an aryl group optionally substituted by an alkyl group, an alkoxy group, a nitro group, a fluorine atom or a cyano group;

### (Substituent Group B)

groups represented by —B(OR²¹)₂ wherein R²¹ represents a hydrogen atom or an alkyl group, two R²¹s may be the same or different, and may be mutually linked together to form a ring,

groups represented by —BF₄Q¹ wherein Q¹ represents a monovalent cation of lithium, sodium, potassium, rubidium or cesium,

groups represented by —Sn(R²²)₃ wherein R²² represents a hydrogen atom or an alkyl group, three R²²s may be the same or different, and may be mutually linked together to form a ring,

groups represented by —MgY¹ wherein Y¹ represents a chlorine atom, a bromine atom or an iodine atom, and
groups represented by —ZnY² wherein Y² represents a chlorine atom, a bromine atom or an iodine atom.

### BRIEF EXPLANATION OF DRAWINGS

FIG. 1 shows the ¹H-NMR spectrum (300 MHz, THF-d₈) of a yellow crystal obtained in Synthesis Example 1.

FIG. 2 shows the ¹H-NMR spectrum (300 MHz, CDCl₃) of an orange solid obtained in Example 1.

FIG. 3 shows the ¹H-NMR spectrum (300 MHz, THF-d₉) of a yellow crystal obtained in Synthesis Example 2.

FIG. 4 shows the ¹H-NMR spectrum (300 MHz, CDCl₅) of a yellow crystal obtained in Example 2.

FIG. 5 shows the EL spectrum at 1000 cd/m² of a light emitting device DP7 obtained in Example 14.

### MODES FOR CARRYING OUT THE INVENTION

Suitable embodiments of the present invention will be illustrated in detail below. In the present specification, Me represents a methyl group, Et represents an ethyl group, i-Pr represents an isopropyl group, n-Bu represents a normal butyl group, t-Bu represents a tert-butyl group, Ph represents a phenyl group and Cy represents a cyclohexyl group. THF represents tetrahydrofuran and DMF represents N,N-dimethylformamide.

In the present specification, “a residue of a compound” indicates “a k-valent group represented by the remaining atomic group after removing k hydrogen atoms from a compound having a neutral valence” and the number represented by k and the position of a hydrogen atom to be removed will be, if necessary, described more in detail in the present specification.

In the present specification, “constitutional unit” indicates one or more unit structures present in a polymer compound. It is preferable that “constitutional unit” is usually contained as “repeating units” (namely, two or more unit structures present in a polymer compound) in a polymer compound.

In the present specification, “aryl group” is an atomic group obtained by removing from an aromatic hydrocarbon one hydrogen atom linked directly to the aromatic ring, and includes those having a fused ring. The aryl group has a carbon atom number of usually 6 to 60 and this carbon atom number does not include the carbon atom number of a substituent, unless otherwise stated in descriptions in the present specification. The above-described aryl group includes a phenyl group, a 1-naphthyl group, a 2-naphthyl group, a 1-anthracenyl group, a 2-anthracenyl group, a 9-anthracenyl group, a 1-tetracenyl group, a 2-tetracenyl group, a 5-tetracenyl group, a 1-pyrenyl group, a 2-pyrenyl group, a 4-pyrenyl group, a 2-perylenyl group, a 3-perylenyl group, a 2-fluorenyl group, a 3-fluorenyl group, a 4-fluorenyl group, a 1-biphenylyl group, a 2-biphenylyl group, a 2-phenanthrenyl group, a 9-phenanthrenyl group, a 6-chrysenyl group, a 1-coronenyl group and the like.

In the above-described aryl group, part or all of hydrogen atoms may be substituted by an alkyl group, an aryl group, a monovalent aromatic heterocyclic group, a group represented by —O—R^{A}, a group represented by —S—R^{A}, a group represented by —C(═O)—R^{A}, a group represented by —O(═O)—O—R^{A}, a cyano group or a fluorine atom, unless otherwise stated in descriptions in the present specification.

In the present specification, “n-valent aromatic heterocyclic group” means an atomic group obtained by removing from a heterocyclic compound having aromaticity n hydrogen atoms among hydrogen atoms linked directly to the aromatic ring, and includes those having a fused ring. “Heterocyclic compound” indicates an organic compound having a cyclic structure in which atoms constituting the ring include not only a carbon atom but also a hetero atom such as an oxygen atom, a sulfur atom, a nitrogen atom, a phosphorus atom, a boron atom, a silicon atom and the like. “Aromatic heterocyclic compound” is a heterocyclic compound containing a hetero atom such as oxadiazole, thiadiazole, thiazole, oxazole, thiophene, pyrrole, phosphole, furan, pyridine, pyrazine, pyrimidine, triazine, pyridazine, quinoline, isoquinoline, carbazole, dibenzophosphole and the like, and includes those in which the hetero ring itself shows aromaticity and those in which an aromatic ring is fused to the hetero ring containing a hetero atom even if the hetero ring itself shows no aromaticity, such as phenoxazine, phenothiazine, dibenzoborole, dibenzosilole, benzopyran and the like. “n-valent fused aromatic heterocyclic group” includes those having a fused ring among the above-described “n-valent aromatic heterocyclic groups”.

In the present specification, “monovalent aromatic heterocyclic group” has a carbon atom number of usually 2 to 60, preferably 3 to 60 and this carbon atom number does not include the carbon atom number of a substituent, unless otherwise stated in descriptions in the present specification. The above-described monovalent aromatic heterocyclic group includes a 1,3,4-oxadiazol-2-yl group, a 1,3,4-thiadiazol-2-yl group, a 2-thiazolyl group, a 2-oxazolyl group, a 2-thienyl group, a 2-pyrrolyl group, a 2-furyl group, a 2-pyridyl group, a 3-pyridyl group, a 4-pyridyl group, a 2-pyrazinyl group, a 2-pyrimidinyl group, a 2-triazinyl group, a 3-pyridazinyl group, a 5-quinolyl group, a 5-isoquinolyl group, a 2-carbazolyl group, a 3-carbazolyl group, a 2-phenoxazinyl group, a 3-phenoxazinyl group, a 2-phenothiazinyl group, a 3-phenothiazinyl group and the like.

In the above-described monovalent aromatic heterocyclic group, part or all of hydrogen atoms may be substituted by an alkyl group, an aryl group, a monovalent aromatic heterocyclic group, a group represented by —O—R^{A}, a group represented by —S—R^{A}, a group represented by —C(═O)—R^{A}, a group represented by —C(═O)—O—R^{A}, a cyano group or a fluorine atom, unless otherwise stated in descriptions in the present specification.

The above-described R^{A} is an alkyl group, an aryl group or a monovalent aromatic heterocyclic group. R^{A} may have a substituent, and when a plurality of R^{A}s are present, R^{A}s may be mutually the same or different.

The alkyl group represented by R^{A} includes a methyl group, an ethyl group, a propyl group, an isopropyl group, a butyl group, an isobutyl group, a tert-butyl group, a pentyl group, an isoamyl group, a hexyl group, a cyclohexyl group, a heptyl group, an octyl group, a 2-ethylhexyl group, a noyl group, a decyl group, a 3,7-dimethyloctyl group, a dodecyl group and the like. In the above-described alkyl group, part or all of hydrogen atoms may be substituted by an aryl group, a monovalent aromatic heterocyclic group, a group represented by —C—R^{A}, a group represented by —S—R^{A}, a group represented by —C(═O)—R^{A}, a group represented by —C(═O)—O—R^{A}, a cyano group or a fluorine atom. As the alkyl group substituted by a fluorine atom, exemplified are a trifluoromethyl group, a pentafluoroethyl group, a perfluorobutyl group, a perfluorohexyl group and a perfluorooctyl group.

The group represented by “—O—R^{A}” in the above-described general formula (1) includes alkoxy groups having a linear, branched or cyclic alkyl group, when R^{A} is an alkyl group. The above-described alkoxy group has a carbon atom number of usually 1 to 20. The above-described alkoxy group includes a methoxy group, an ethoxy group, a propyloxy group, an isopropyloxy group, a butoxy group, an isobutoxy group, a tert-butoxy group, a pentyloxy group, a hexyloxy group, a nonyloxy group, a decyloxy group, a 3,7-dimethyloctyloxy group, a dodecyloxy group, a trifluoromethoxy group, a pentafluoroethoxy group, a perfluorobutoxy group, a perfluorohexyloxy group, a perfluorooctyloxy group, a methoxymethyloxy group, a 2-methoxyethyloxy group, a 2-ethoxyethyloxy group and the like.

The group represented by “—O—R^{A}” includes aryloxy groups having usually 6 to 60 carbon atoms, when R^{A} is an aryl group. As this aryl group portion, the same portions as the above-described aryl group are mentioned. The above-described aryloxy group includes a phenoxy group, C₁ to C₁₂ alkoxyphenoxy groups (“C₁ to C₁₂ alkoxy” means that the alkoxy portion has a carbon atom number of 1 to 12, the same shall apply hereinafter.), C₁ to C₁₂ alkylphenoxy groups (“C₁ to C₁₂ alkyl” means that the alkyl portion has a carbon atom number of 1 to 12, the same shall apply hereinafter.), a 1-naphthyloxy group, a 2-naphthyloxy group, a pentafluorophenyloxy group and the like.

Further, the group represented by “—O—R^{A}” includes groups having a carbon atom number of 2 to 60, particularly, groups having a carbon atom number of 3 to 20, when R^{A} is a monovalent aromatic heterocyclic group. As this monovalent aromatic heterocyclic group, the same groups as the above-described monovalent aromatic heterocyclic group are mentioned.

The group represented by “—S—R^{A}” in the above-described general formula (1) includes alkylthio groups, arylthio groups and the like.

The group represented by “—C(═O)—R^{A}” in the above-described general formula (1) includes alkylcarbonyl groups, arylcarbonyl groups and the like.

The group represented by “—C(═O)—O—R^{A}” in the above-described general formula (1) includes alkyloxycarbonyl groups, aryloxycarbonyl groups and the like.

### <Residue of Compound Represented by the Formula (1)>

The compound according to the present embodiment is a polymer compound containing as a constitutional unit a residue of a compound represented by the above-described general formula (1).

The arylene group represented by Ar¹ has a carbon atom number of preferably 6 to 48, more preferably 6 to 30, further preferably 6 to 14. This carbon atom number does not include the carbon atom number of a substituent. In the arylene group, part or all of hydrogen atoms may be substituted by an alkyl group, an aryl group, a monovalent aromatic heterocyclic group, a group represented by —O—R^{A}, a group represented by —S—R^{A}, a group represented by —C(═O)—R^{A}, a group represented by —C(═O)—O—R^{A}, a cyano group or a fluorine atom.

The above-described arylene group includes phenylene groups such as a 1,4-phenylene group (the formula 2-001), a 1,3-phenylene group (the formula 2-002), a 1,2-phenylene group (the formula 2-003) and the like; naphthalenediyl groups such as a naphthalene-1,4-diyl group (the formula 2-004), a naphthalene-1,5-diyl group (the formula 2-005), a naphthalene-2,6-diyl group (the formula (2-006) and the like; dihydrophenanthrene diyl groups such as a 9,10-dihydrophenanthrene-2,7-diyl group (the formula 2-007) and the like; a fluorene-3,6-diyl group (the formula 2-008); a fluorene-2,7-diyl group (the formula 2-009); benzofluorene diyl groups represented by (the formula 2-010) to (the formula 2-012); anthracenediyl groups such as an anthracene-2,6-diyl group (the formula 2-013), an anthracene-9,10-diyl group (the formula 2-014) and the like; etc. In these arylene groups, part or all of hydrogen atoms may be substituted by an alkyl group, an aryl group, a monovalent aromatic heterocyclic group, a group represented by —O—R^{A}, a group represented by —S—R^{A}, a group represented by —C(═O)—R^{A}, a group represented by —C(═O)—O—R^{A}, a cyano group or a fluorine atom.

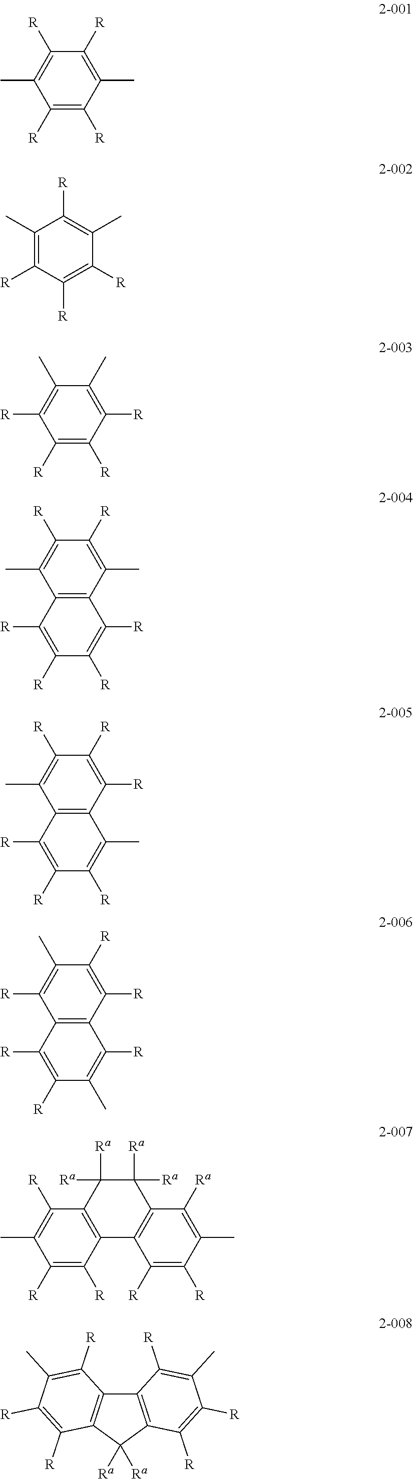

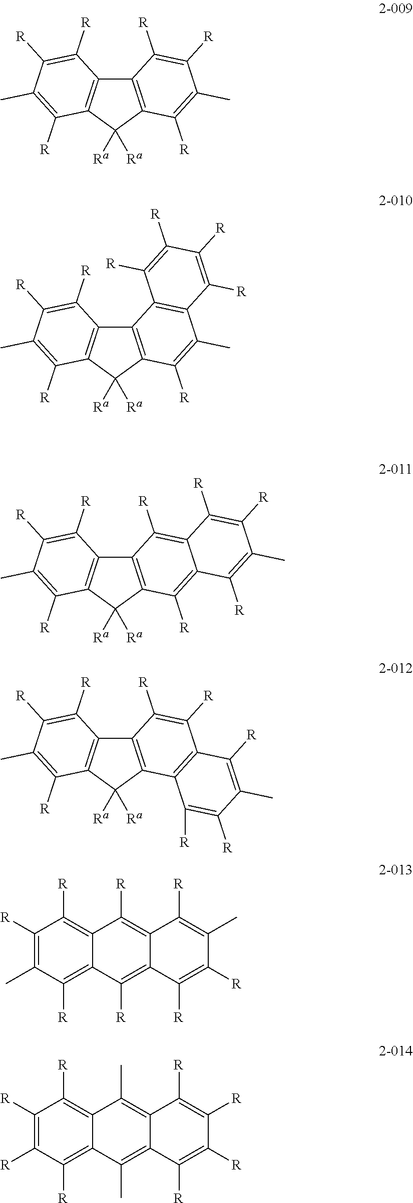

[in the formulae, R represents a hydrogen atom, an alkyl group, an aryl group, a monovalent aromatic heterocyclic group, a group represented by —O—R^{A}, a group represented by —S—R^{A}, a group represented by —C(═O)—R^{A}, a group represented by —C(═O)—O—R^{A}, a cyano group or a fluorine atom and R^{a} represents an alkyl group, an aryl group or a monovalent aromatic heterocyclic group, and a plurality of R⁵ may be the same or different and a plurality of R^{a}s may be the same or different.].

In the above-described formulae 2-001 to 2-014, R represents preferably a hydrogen atom, an alkyl group, an aryl group or a monovalent aromatic heterocyclic group, more preferably a hydrogen atom or an alkyl group, and R^{a} represents preferably an alkyl group or an aryl group, since then the heat resistance and solubility in an organic solvent of the polymer compound according to the present embodiment are excellent.

The divalent aromatic heterocyclic group represented by Ar¹ has a carbon atom number of preferably 3 to 60, more preferably 8 to 20. This carbon atom number does not include the carbon atom number of a substituent. In the divalent aromatic heterocyclic group, part or all of hydrogen atoms may be substituted by an alkyl group, an aryl group, a monovalent aromatic heterocyclic group, a group represented by —O—R^{A}, a group represented by —S—R^{A}, a group represented by —C(═O)—R^{A}, a group represented by —C(═O)—O—R^{A}, a cyano group or a fluorine atom.

As the above-described divalent aromatic heterocyclic group, a divalent fused aromatic heterocyclic group is preferable. This divalent fused aromatic heterocyclic group includes quinolinediyl groups such as a quinoline-2,6-diyl group (the formula 2-107) and the like; isoquinolinediyl groups such as an isoquinoline-1,4-diyl group (the formula 2-108) and the like; quinoxalinediyl groups such as a quinoxaline-5,8-diyl group (the formula 2-109) and the like; carbazolediyl groups such as a carbazole-3,6-diyl group (the formula 2-110), a carbazole-2,7-diyl group (the formula 2-111) and the like; dibenzofurandiyl groups such as a dibenzofuran-2,8-diyl group (the formula 2-112), a dibenzofuran-3,7-diyl group (the formula 2-113) and the like; dibenzothiophenediyl groups such as a dibenzothiophene-2,8-diyl group (the formula 2-114), a dibenzothiophene-3,7-diyl group (the formula 2-115) and the like; dibenzosilolediyl groups such as a dibenzosilole-2,8-diyl group (the formula 2-116), a dibenzosilole-3,7-diyl group (the formula 2-117) and the like; phenoxazinediyl groups such as (the formula 2-118), (the formula 2-119) and the like; phenothiazinediyl groups such as (the formula 2-120), (the formula 2-121) and the like; dihydroacridinediyl groups such as (the formula 2-123) and the like; a divalent group represented by (the formula 2-124); and the like. In these divalent fused aromatic heterocyclic groups, part or all of hydrogen atoms may be substituted by an alkyl group, an aryl group, a monovalent aromatic heterocyclic group, a group represented by —O—R^{A}, a group represented by —S—R^{A}, a group represented by —C(═O)—R^{A}, a group represented by —C(═O)—O—R^{A}, a cyano group or a fluorine atom.

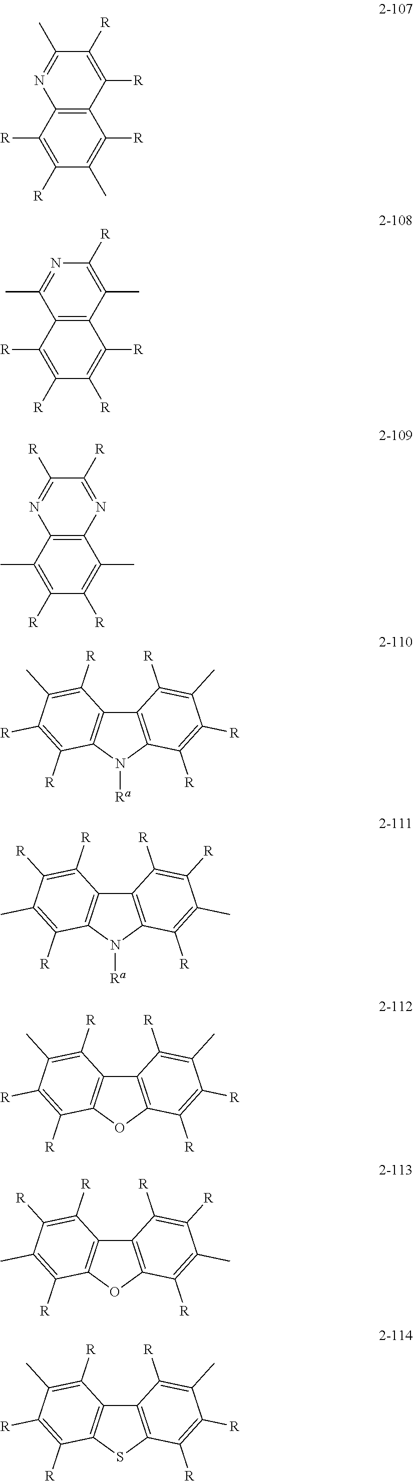

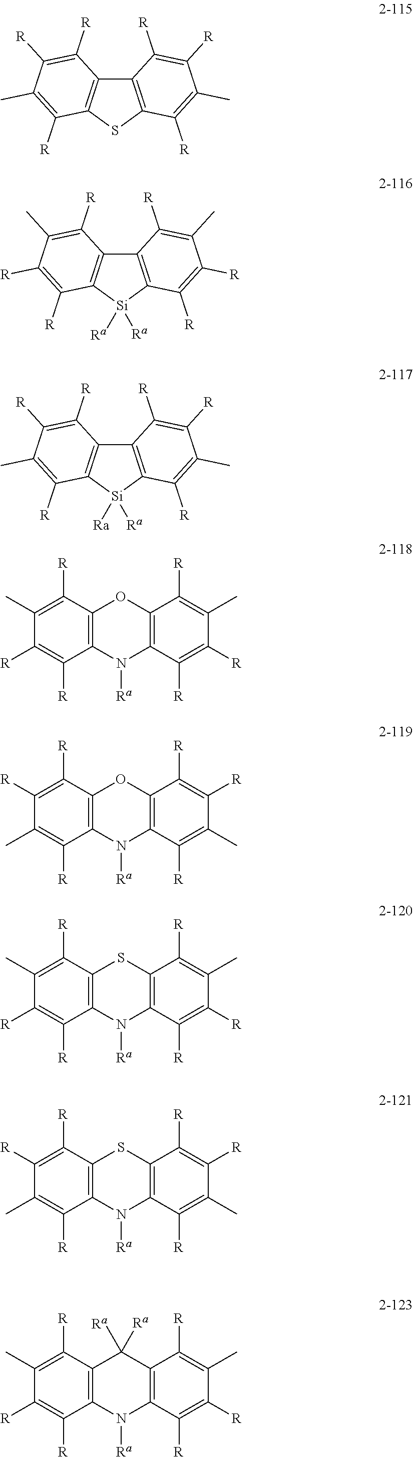

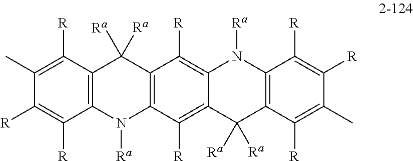

[in the formulae 2-107 to 2-124, R and R^{a} are the same as described above.].

Ar¹ represents preferably a 1,4-phenylene group (the formula 2-001) or a 1,3-phenylene group (the formula 2-002), particularly preferably a 1,4-phenylene group (the formula 2-001), since then the stability of the polymer compound according to the present embodiment is excellent and the light emission efficiency of an organic light emitting device using the polymer compound is excellent.

The above-described R in Ar¹ represents preferably a hydrogen atom, an alkyl group, an aryl group or a monovalent aromatic heterocyclic group, more preferably a hydrogen atom or an alkyl group, particularly preferably a hydrogen atom, since then the stability of the polymer compound according to the present embodiment is excellent and the light emission efficiency of an organic light emitting device using the polymer compound is excellent.

As the arylene group and divalent aromatic heterocyclic group represented by Ar² and Ar⁴, the same groups as the above-described group represented by Ar¹ are exemplified.

“Divalent group obtained by linking two or more identical or different groups selected from the group consisting of an arylene group and a divalent aromatic heterocyclic group” represented by Ar² and Ar⁴ has a carbon atom number of usually 4 to 60, preferably 12 to 60. This carbon atom number does not include the carbon atom number of a substituent. Such a group includes groups represented by the following formulae 2-201 to 2-208.

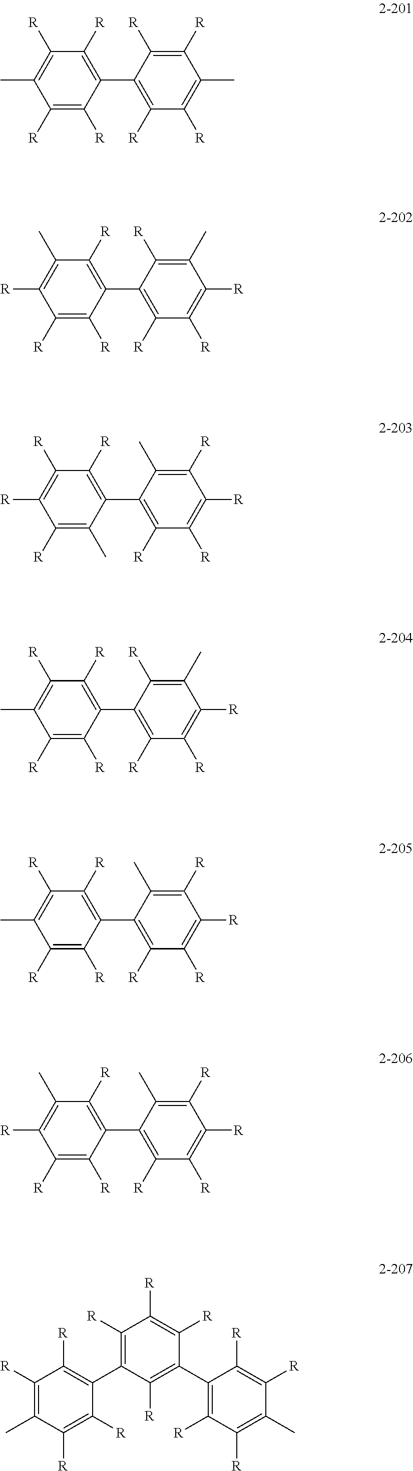

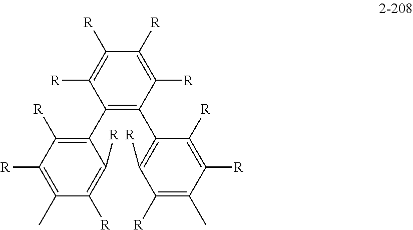

[in the formulae 2-201 to 2-208, R is the same as described above.].

Ar² and Ar⁴ represent preferably a 1,4-phenylene group (the formula 2-001), a fluorene-2,7-diyl group (the formula 2-009) or a divalent group represented by the formula 2-201, particularly preferably a 1,4-phenylene group (the formula 2-001), since then the stability of the polymer compound according to the present embodiment is excellent and the light emission efficiency of an organic light emitting device using the polymer compound is excellent.

The above-described R represents preferably a hydrogen atom, an alkyl group or an aryl group, more preferably a hydrogen atom or an alkyl group, and the above-described R^{a} represents preferably an alkyl group or an aryl group, in Ar² and Ar⁴, since then the stability of the polymer compound according to the present embodiment is excellent and the light emission efficiency of an organic light emitting device using the polymer compound is excellent.

The aryl group represented by Ar³, Ar⁵, Ar⁶ and Ar⁷ has a carbon atom number of preferably 6 to 48, more preferably 6 to 20, further preferably 6 to 14. This carbon atom number does not include the carbon atom number of a substituent. The above-described aryl group includes a phenyl group, a 1-naphthyl group, a 2-naphthyl group, a 1-anthracenyl group, a 2-anthracenyl group, a 9-anthracenyl group, a 1-tetracenyl group, a 2-tetracenyl group, a 5-tetracenyl group, a 1-pyrenyl group, a 2-pyrenyl group, a 4-pyrenyl group, a 2-perylenyl group, a 3-perylenyl group, a 2-fluorenyl group, a 3-fluorenyl group, a 4-fluorenyl group, a 2-phenanthrenyl group, a 9-phenanthrenyl group, a 6-chrysenyl group, a 1-coronenyl group and the like. In the above-described aryl group, part or all of hydrogen atoms may be substituted by an alkyl group, an aryl group, a monovalent aromatic heterocyclic group, a group represented by —O—R^{A}, a group represented by —S—R^{A}, a group represented by —C(═O)—R^{A}, a group represented by —C(═O)—O—R^{A}, a cyano group or a fluorine atom.

The monovalent aromatic heterocyclic group represented by Ar³, Ar⁵, Ar⁶ and Ar⁷ has a carbon atom number of usually 2 to 60, preferably 3 to 20. This carbon atom number does not include the carbon atom number of a substituent. The above-described monovalent aromatic heterocyclic group includes a 1,3,4-oxadiazol-2-yl group, a 1,3,4-thiadiazol-2-yl group, a 2-thiazolyl group, a 2-oxazolyl group, a 2-thienyl group, a 2-pyrrolyl group, a 2-furyl group, a 2-pyridyl group, a 3-pyridyl group, a 4-pyridyl group, a 2-pyrazinyl group, a 2-pyrimidinyl group, a 2-triazinyl group, a 3-pyridazinyl group, a 5-quinolyl group, a 5-isoquinolyl group, a 2-carbazolyl group, a 3-carbazolyl group, a 2-phenoxazinyl group, a 3-phenoxazinyl group, a 2-phenothiazinyl group, a 3-phenothiazinyl group and the like. In the above-described monovalent aromatic heterocyclic group, part or all of hydrogen atoms may be substituted by an alkyl group, an aryl group, a monovalent aromatic heterocyclic group, a group represented by —O—R^{A}, a group represented by —S—R^{A}, a group represented by —C(═O)—R^{A}, a group represented by —C(═O)—O—R^{A}, a cyano group or a fluorine atom.

The substituent optionally carried on Ar¹, Ar², Ar³, Ar⁴, Ar⁵, Ar⁶ and Ar⁷ in the above-described general formula (1) is preferably a hydrogen atom, an alkyl group or an aryl group, since then the stability of the polymer compound according to the present embodiment is excellent and the light emission efficiency of an organic light emitting device using the polymer compound is excellent.

Ar⁵ and Ar⁷ in the above-described general formula (1) represent preferably a group represented by the following formula (5), since then the stability of the polymer compound according to the present embodiment is excellent and the luminance stability in driving of an organic light emitting device using the polymer compound is excellent.

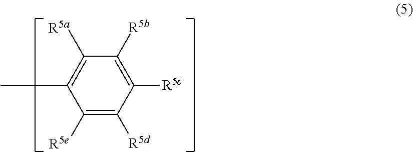

[in the formula, R^{5a} represents an alkyl group, R^{5b}, R^{5c} and R^{5d} each independently represent a hydrogen atom, an alkyl group or an aryl group, and R^{5e} represents a hydrogen atom or an alkyl group.].

In the above-described general formula (5), R^{5a} represents preferably a methyl group, an ethyl group, a propyl group or a butyl group, more preferably a methyl group.

In the above-described general formula (5), R^{5b} represents preferably a hydrogen atom, an alkyl group having 1 to 20 carbon atoms or a phenyl group optionally substituted by an alkyl group.

In the above-described general formula (5), R^{5c} represents preferably an alkyl group having 4 to 20 carbon atoms.

In the above-described general formula (5), R^{5d} represents preferably a hydrogen atom, an alkyl group having 4 to 20 carbon atoms or an aryl group having an alkyl group having 4 to 20 carbon atoms as a substituent.

In the above-described general formula (5), R^{5e} represents preferably a methyl group, an ethyl group, a propyl group or a butyl group, more preferably a methyl group.

The residue of the compound represented by the above-described general formula (1) indicates a 1 to 4-valent group obtained by substitution of connecting bonds for 1 to 4 hydrogen atoms selected from hydrogen atoms present on a perylene ring in the above-described general formula (1) or hydrogen atoms present on carbon atoms constituting an aromatic ring contained in the group represented by Ar¹, Ar², Ar³, Ar⁴, Ar⁵, Ar⁶ or Ar⁷. The residue of the compound represented by the above-described general formula (1) is preferably 1 to 3-valent (the number of connecting bonds is 1 to 3), and it is more preferable that the residue is 1-valent (the number of a connecting bond is 1) and present as a side chain or end of a polymer compound and that the residue is 2-valent (the number of connecting bonds is 2) and present as a constitutional unit constituting the main chain of a polymer compound. Here, the hydrogen atom to be removed from the compound represented by the above-described general formula (1) is preferably a hydrogen atom on a perylene ring or a hydrogen atom on an aromatic ring of an aryl group or a monovalent aromatic heterocyclic group represented by Ar³. The descriptions in this paragraph are applicable also to the formulae (1a) and (1b).

<Residue of Compound Represented by the Formulae (1a) and (1b)>

The polymer compound according to the present embodiment is preferably a polymer compound containing as a constitutional unit a residue of a compound represented by the above-described general formula (1a) or (1b). An organic light emitting device obtained by using this polymer compound is further excellent in light emission efficiency.

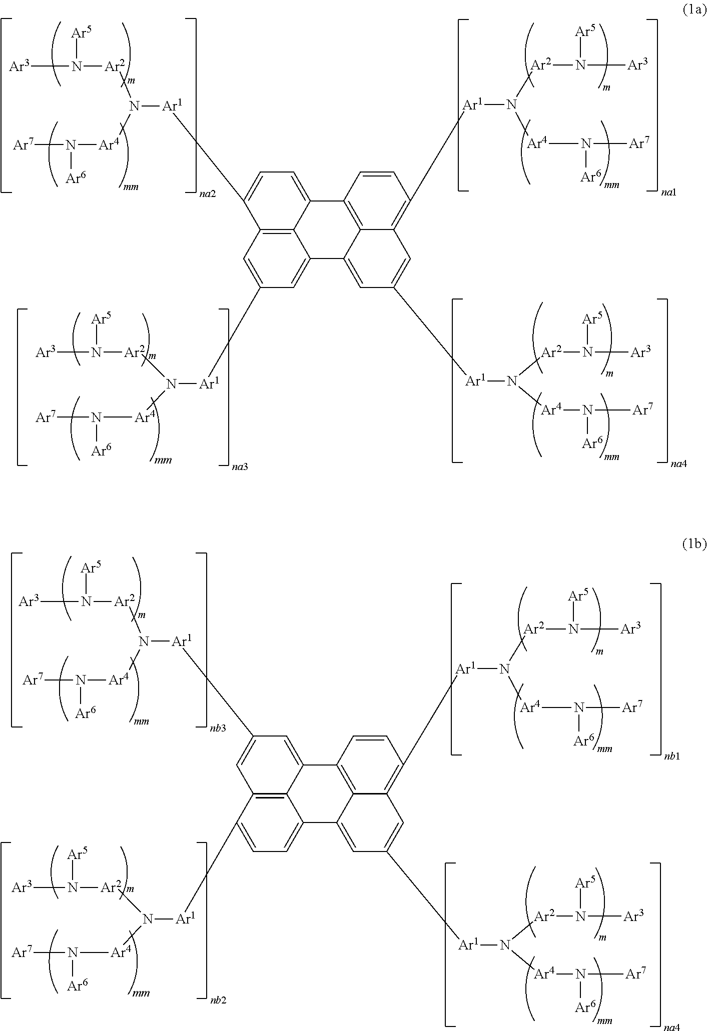

[in the formulae (1a) and (1b), m, mm, Ar¹, Ar², Ar³, Ar⁴, Ar⁵, Ar⁶ and Ar⁷ represent the same meaning as described above. na1, na2, na3, na4, nb1, nb2, nb3 and nb4 are each independently 0 or 1. Here, at least one of na1, na2, na3 and na4 is 1, and at least one of nb1, nb2, nb3 and nb4 is 1. When there are a plurality of ms, mms, Ar¹s, Ar²s, Ar³s, Ar⁴s, Ar⁵s, Ar⁶s and Ar⁷s, respective symbols may be the same or different.].

In the above-described general formulae (1a) and (1b), it is preferable that na1 and nb1 are 1, it is more preferable that na3, na4, nb3 and nb4 are 0, it is further preferable that na2 and nb2 are 0. When na1, na2, na3, na4, nb1, nb2, nb3 or nb4 is 0, the bracket portion attached with it denotes a hydrogen atom.

In the above-described general formulae (1a) and (1b), mm is preferably 0 and m is preferably 1.

### <Polymer Compound>

### [First Constitutional Unit]

The polymer compound according to the present embodiment is a polymer compound containing a residue of a compound represented by the above-described general formula (1), (1a) or (1b) as a constitutional unit (hereinafter, also referred to as “first constitutional unit”).

The following constitutional units are preferably listed as the constitutional unit composed of a residue of a compound represented by the above-described general formula (1a), among the above-described first constitutional units.

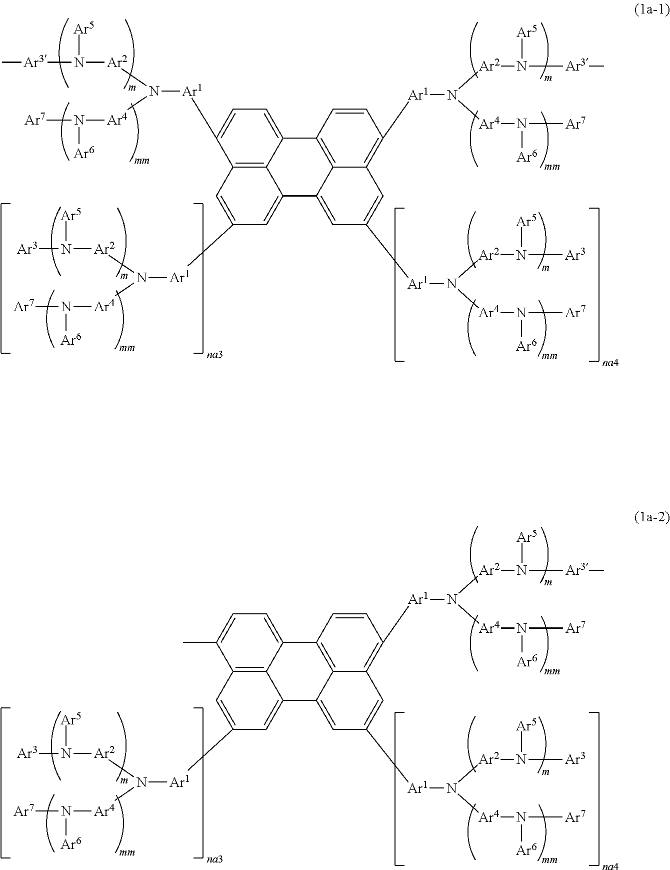

The following constitutional units are preferably listed as the constitutional unit composed of a residue of a compound represented by the above-described general formula (1b), among the above-described first constitutional units.

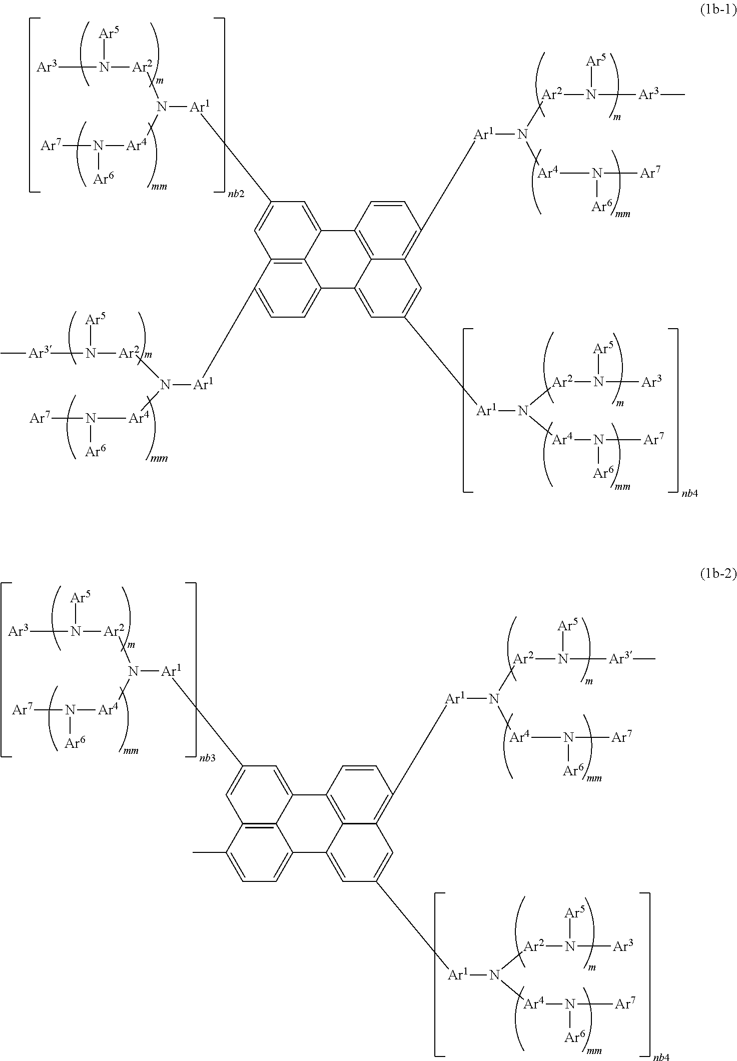

In the above-described formulae, m, mm, Ar¹, Ar², Ar³, Ar⁴, Ar⁵, Ar⁶ and Ar⁷ represent the same meaning as described above. Ar^{3′} is an arylene group or a divalent aromatic heterocyclic group obtained by removing one hydrogen atom from an aryl group or a monovalent aromatic heterocyclic group represented by Ar³. na3, na4, nb3 and nb4 are each independently 0 or 1. When there are a plurality of ms, mms, Ar¹s, Ar²s, Ar³s, Ar^{3′}s, Ar⁴s, Ar⁵s, Ar⁶s and Ar⁷s, respective symbols may be the same or different.

Specific examples and preferable examples of Ar¹, Ar², Ar³, Ar⁴, Ar⁵, Ar⁶, Ar⁷, m and mm in residues represented by the above-described general formulae (1a-1), (1a-2), (1b-1) and (1b-2) are the same as described above.

The definition, specific examples and preferable range of the divalent group represented by Ar^{3′} are the same as the definition, specific examples and preferable range of Ar²°.

In the formulae (1a-1) and (1a-2), na3 and na4 are more preferably 0.

In the formulae (1b-1) and (1b-2), nb3 and nb4 are more preferably 0.

Of (1a-1) and (1a-2), (1a-2) is more preferable, and of (1b-1) and (1b-2), (1b-2) is more preferable.

Of the above-described first constitutional units, preferable as the constitutional unit represented by the above-described general formula (1a) are, specifically, constitutional units represented by the following formulae 1a-001 to 1a-011, 1a-101 to 1a-104, 1a-201 to 1a-204, and preferable as the constitutional unit represented by the above-described general formula (1b) are constitutional units represented by the following formulae 1b-001 to 1b-011, 1b-101 to 1b-104, 1b-201 to 1b-204. As the above-described first constitutional unit, constitutional units represented by the following formulae 1a-001 to 1a-011, 1b-001 to 1b-011 are more preferable, constitutional units represented by the following formulae 1a-002, 1a-004, 1a-005, 1b-002, 1b-004 and 1b-005 are further preferable, since the luminance stability in driving of an organic light emitting device using the polymer compound according to the present embodiment is improved.

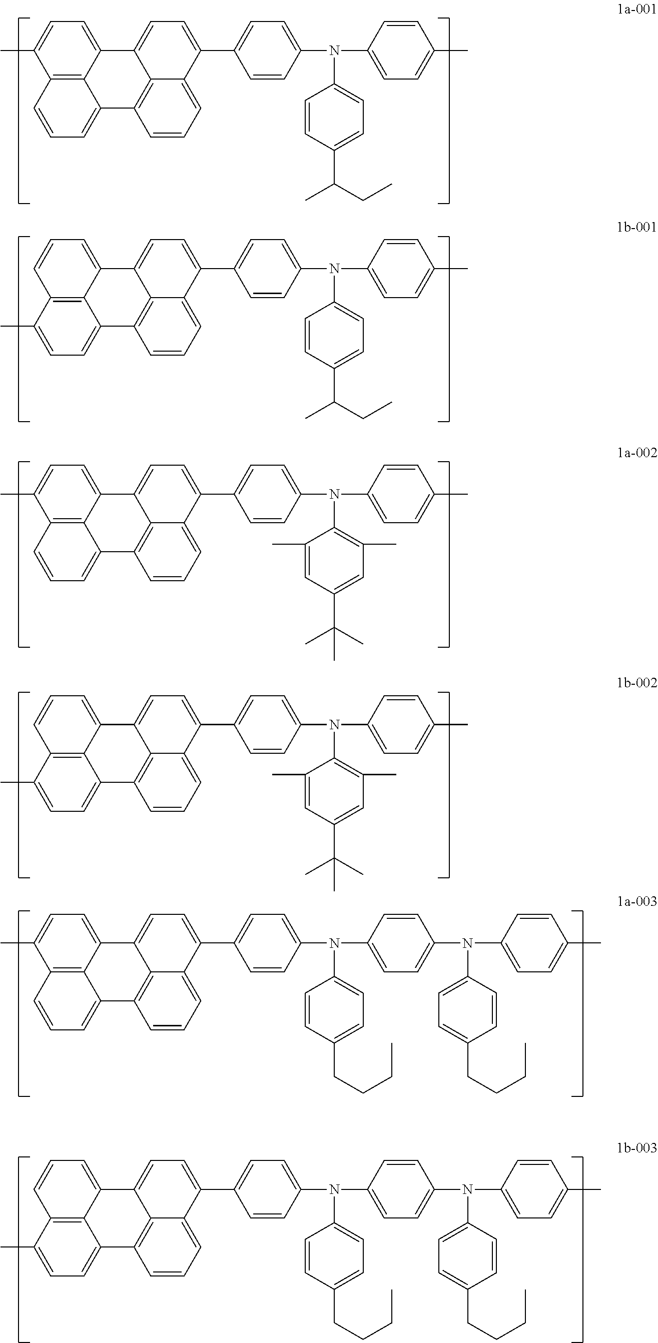

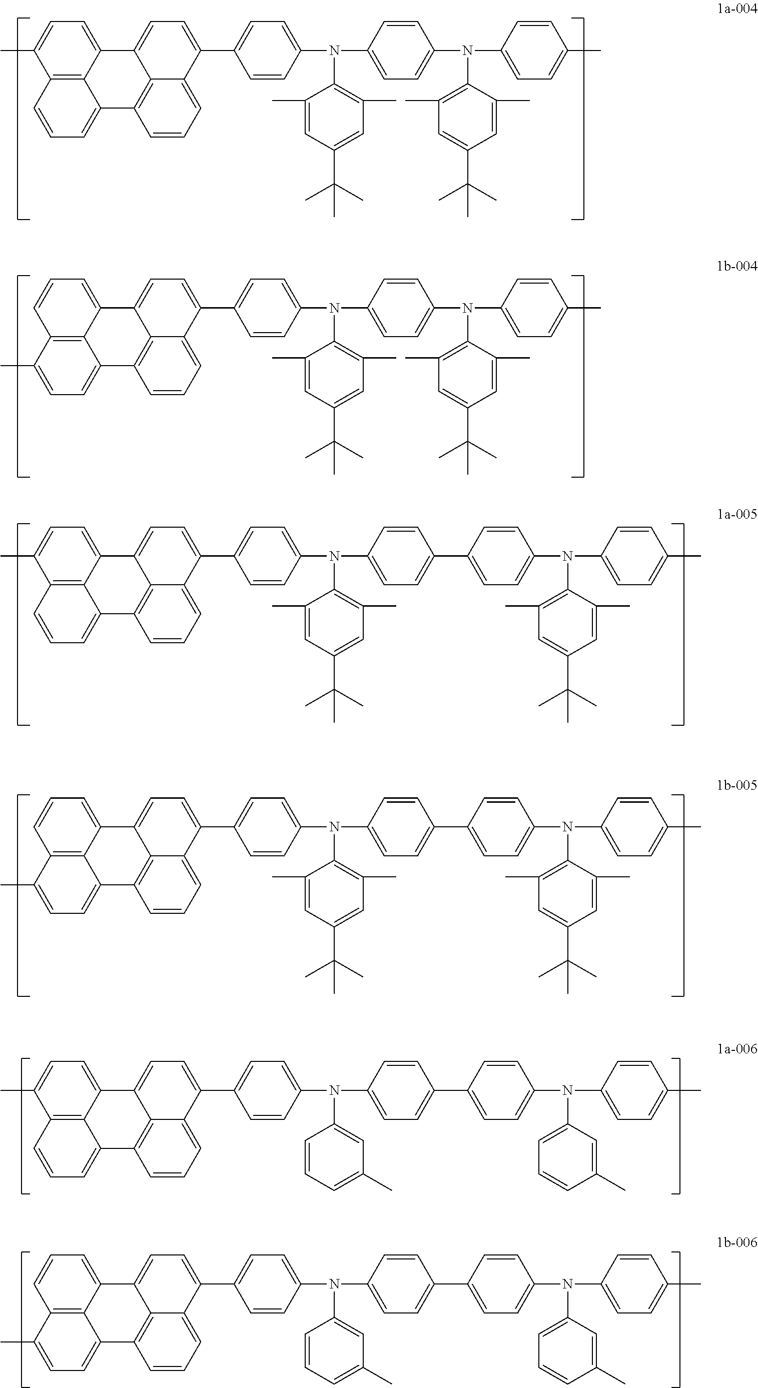

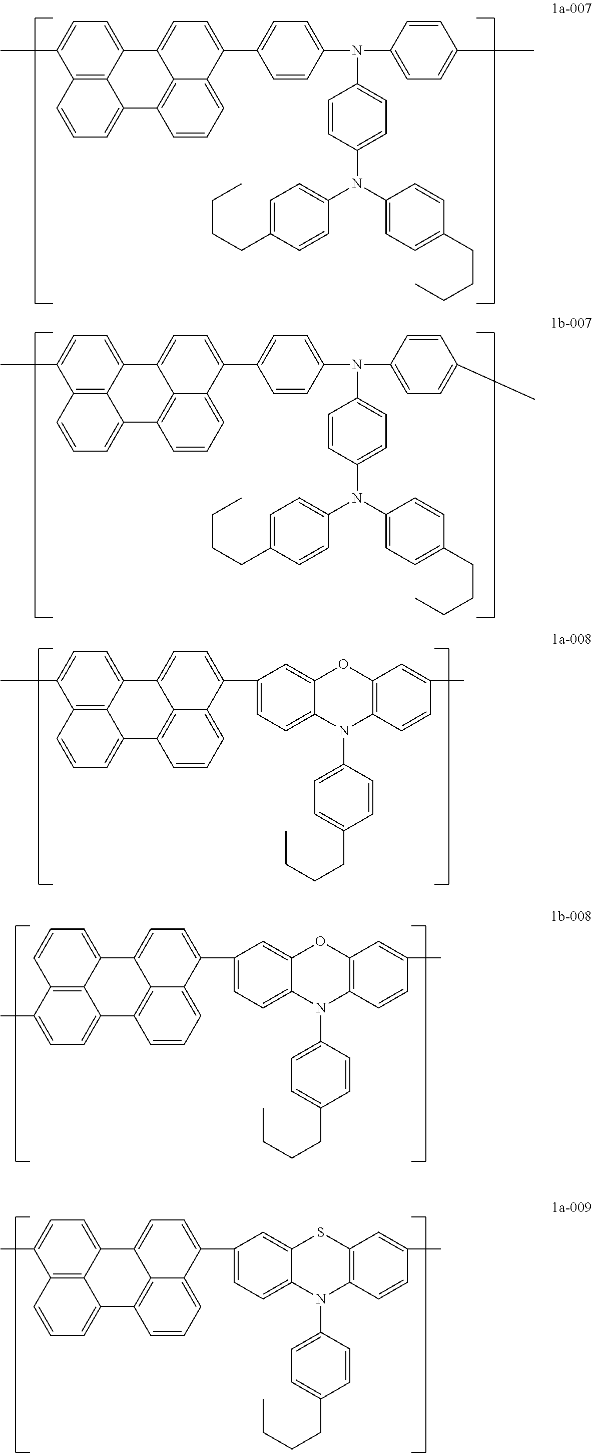

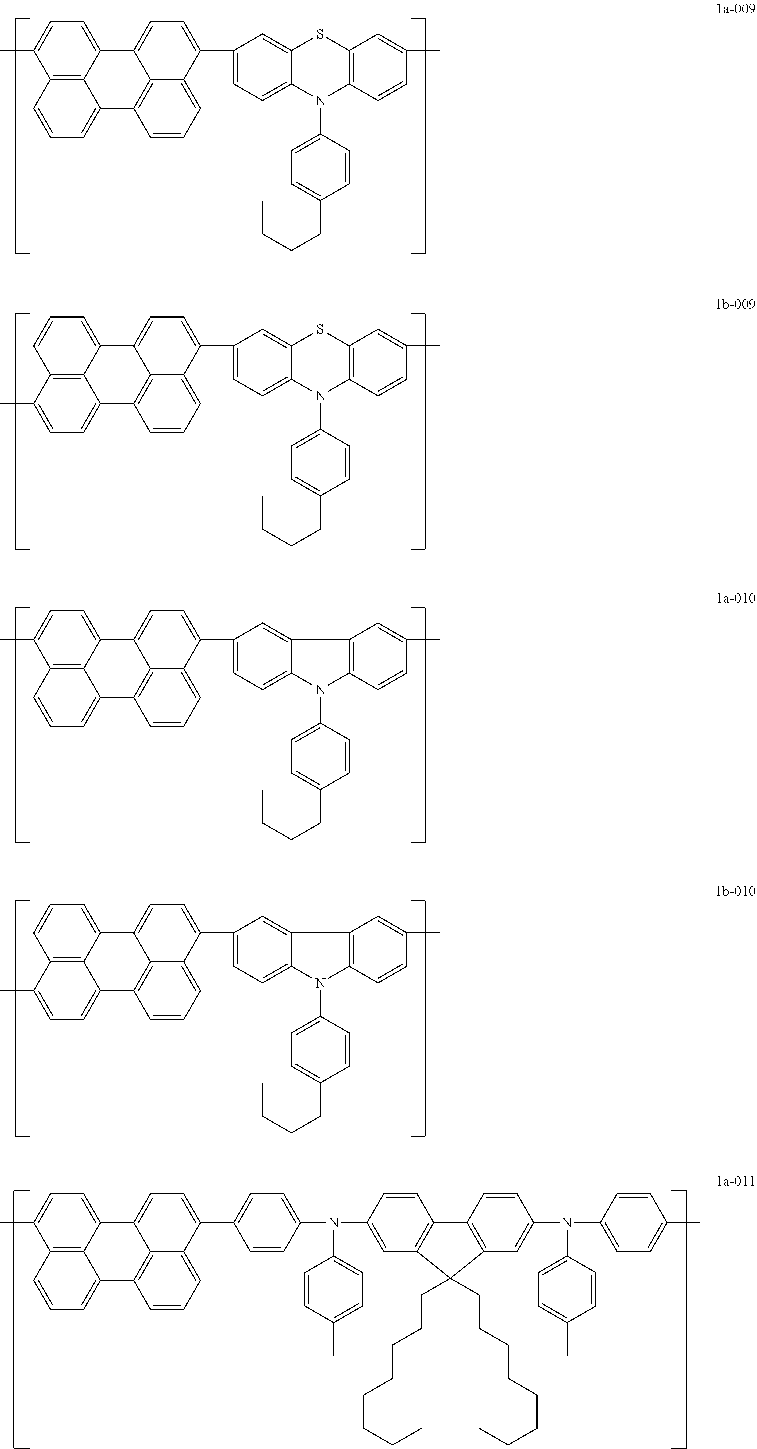

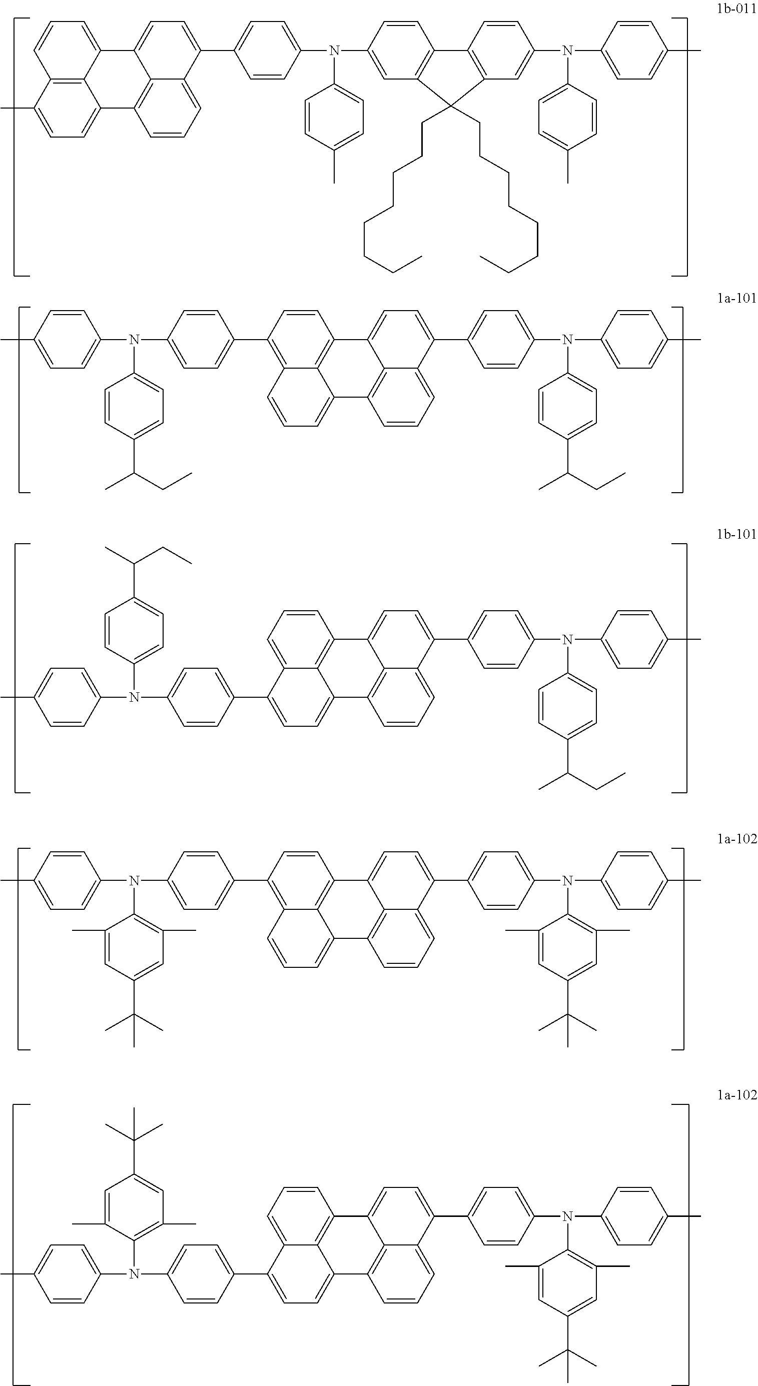

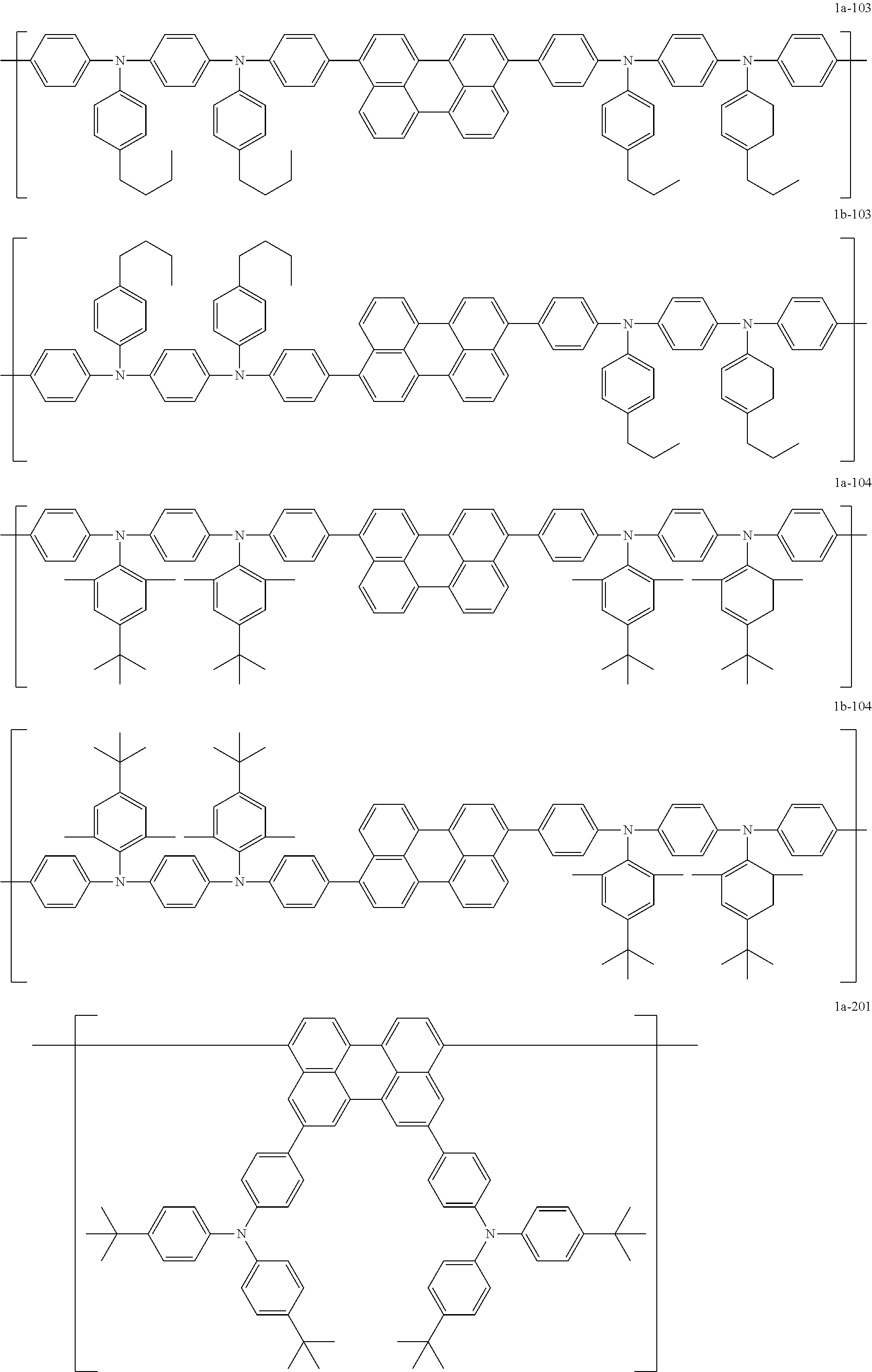

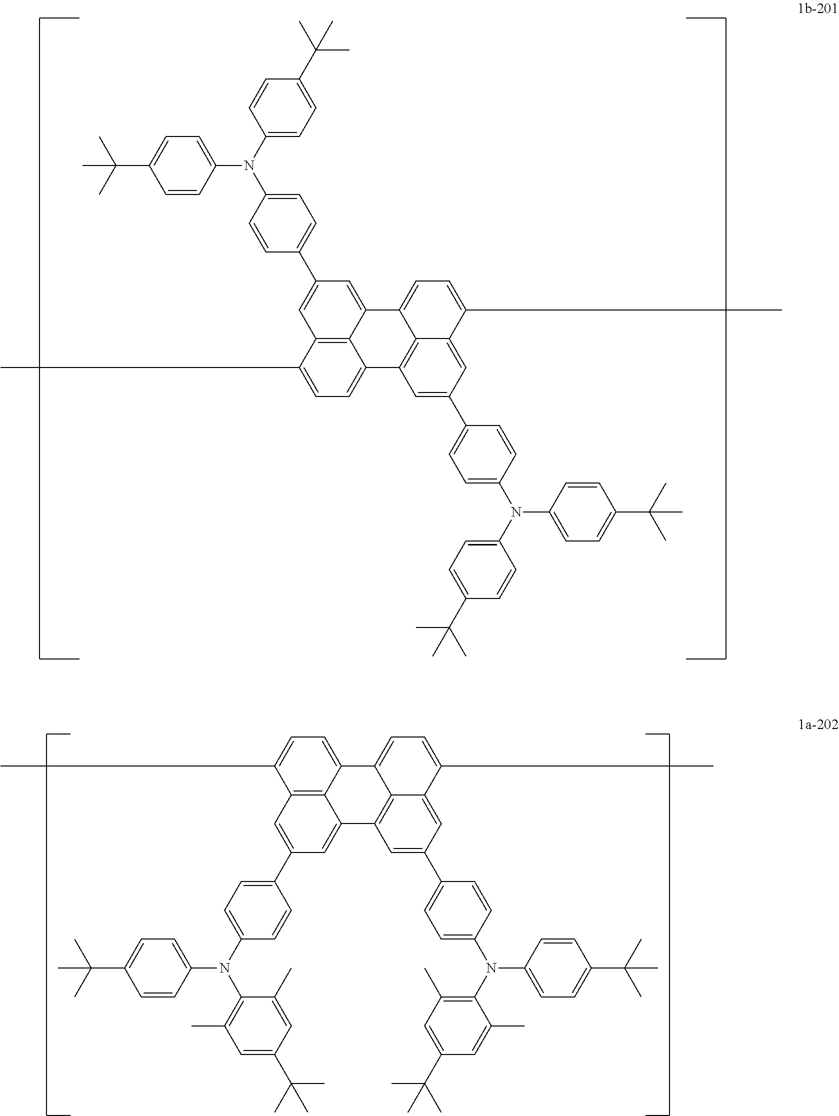

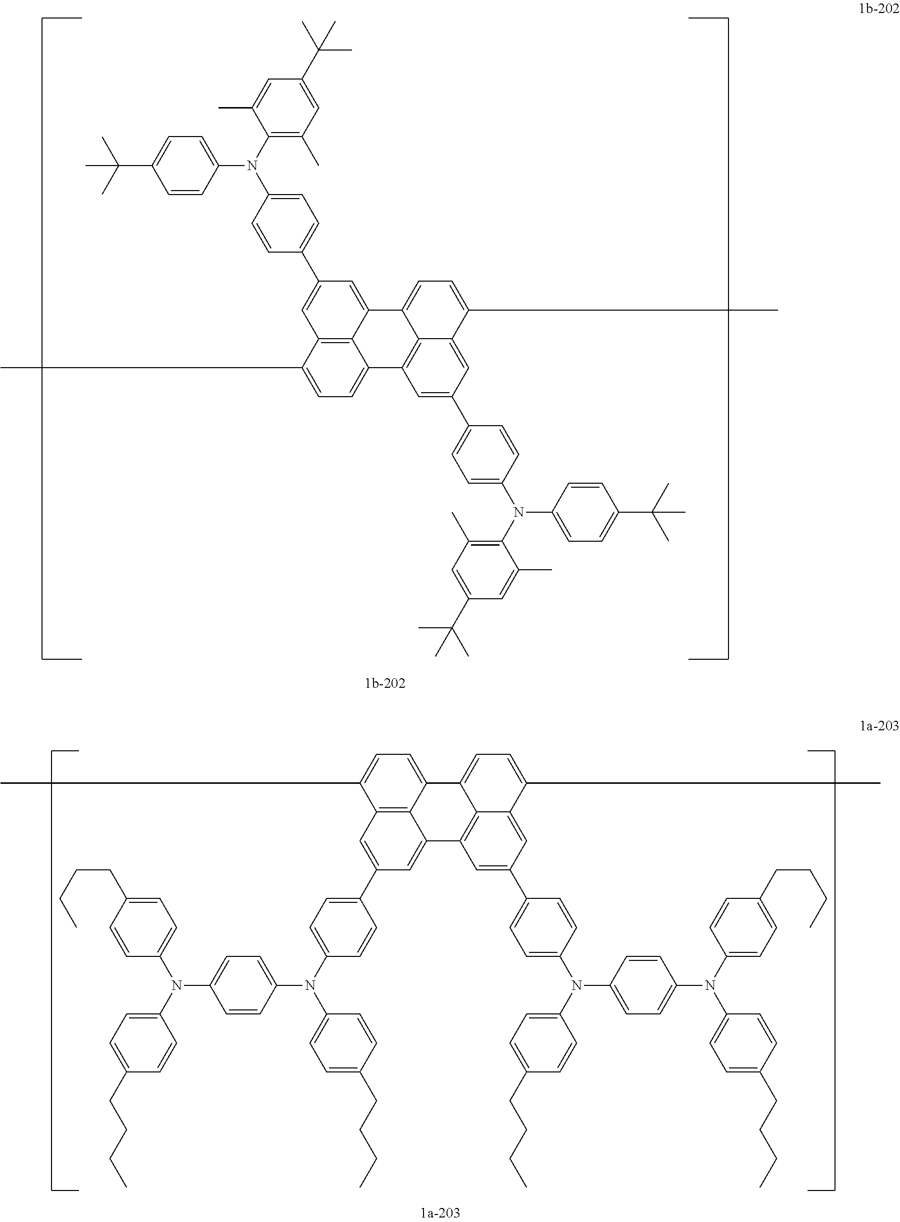

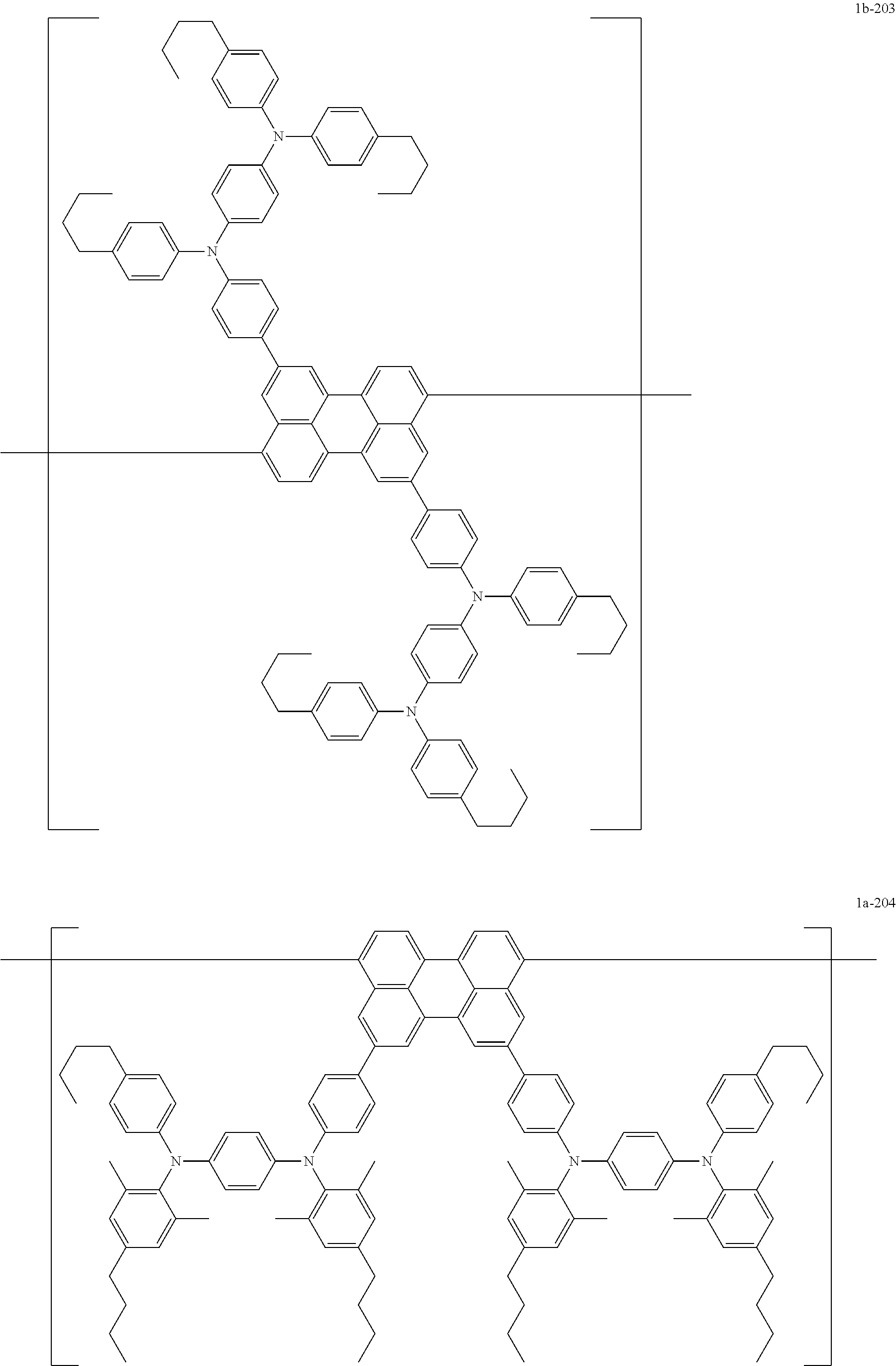

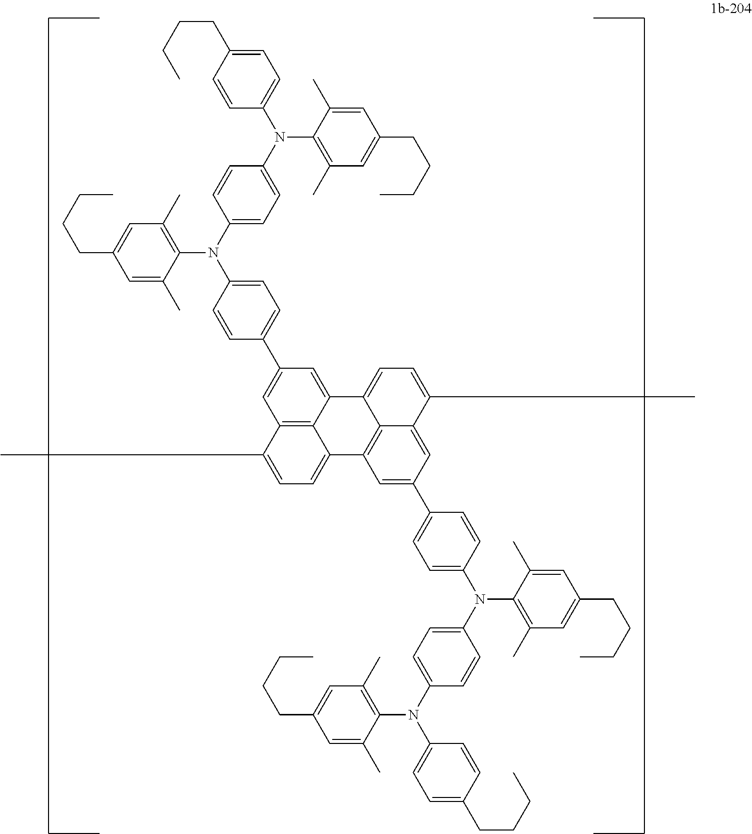

One or two or more constitutional units represented by the above-described general formula (1), (1a) or (1b) may be contained in the polymer compound according to the present embodiment.

### [Second Constitutional Unit]

The polymer compound according to the present embodiment is preferably a polymer compound containing a residue of a compound represented by the above-described general formula (1), (1a) or (1b) as a constitutional unit (first constitutional unit) and further containing a group represented by the following general formula (2) as a constitutional unit (hereinafter, also referred to as “second constitutional unit”). By use of this polymer compound, the resulting organic light emitting device gets excellent stability and excellent light emission efficiency.

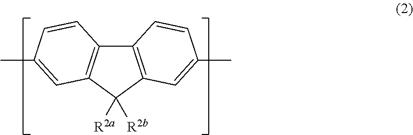

[in the formula (2),

R^{2a} and R^{2b} each independently represent an alkyl group, an aryl group or a monovalent aromatic heterocyclic group, alternatively R^{2a} and R^{2b} are mutually linked together to represent a divalent group.

The constitutional unit represented by the formula (2) may have one or several substituents selected from the group consisting of an alkyl group, an aryl group, a monovalent aromatic heterocyclic group, a group represented by —O—R^{A}, a group represented by —S—R^{A}, a group represented by —C(═O)—R^{A}, a group represented by —C(═O)—O—R^{A}, a group represented by —N(R^{A})₂, a cyano group and a fluorine atom. R^{A} represents the same meaning as described above.].

In the above-described general formula (2), the alkyl group, aryl group and monovalent aromatic heterocyclic group represented by R^{2a} and R^{2b} may have a substituent.

The alkyl group represented by R^{2a} and R^{2b} in the above-described general formula (2) includes a methyl group, an ethyl group, a propyl group, an isopropyl group, a butyl group, a sec-butyl group, an isobutyl group, a pentyl group, a 2-methylbutyl group, an isoamyl group, a hexyl group, a heptyl group, an octyl group, a 2-ethylhexyl group, a nonyl group, a decyl group, a 3,7-dimethyloctyl group, a dodecyl group and the like.

The aryl group represented by R^{2a} and R^{2b} in the above-described general formula (2) includes a phenyl group, a 1-naphthyl group, a 2-naphthyl group and the like.

The monovalent aromatic heterocyclic group represented by R^{2a} and R^{2b} in the above-described general formula (2) includes the same groups as the monovalent aromatic heterocyclic group represented by R^{a} described above.

R^{2a} and R^{2b} in the above-described general formula (2) represent preferably a substituted or unsubstituted aryl group or a substituted or unsubstituted alkyl group, more preferably an unsubstituted aryl group or an aryl group substituted by an alkyl group, an alkoxy group, an aryl group or a substituted amino group, or an unsubstituted alkyl group or an alkyl group substituted by an alkyl group, an alkoxy group, an aryl group or a substituted amino group, further preferably an aryl group substituted by an alkyl group or an aryl group, or an unsubstituted alkyl group, more further preferably a 4-tolyl group, a 4-butylphenyl group, a 4-tert-butylphenyl group, a 4-hexylphenyl group, a 4-octylphenyl group, a 4-(2-ethylhexyl)phenyl group, a 4-(3,7-dimethyloctyl)phenyl group, a 3-tolyl group, a 3-butylphenyl group, a 3-tert-butylphenyl group, a 3-hexylphenyl group, a 3-octylphenyl group, a 3-(2-ethylhexyl)phenyl group, a 3-(3,7-dimethyloctyl)phenyl group, a 3,5-dimethylphenyl group, a 3,5-di-(tert-butyl)phenyl group, a 3,5-dihexylphenyl group, a 3,5-dioctylphenyl group, a 3,4-dihexylphenyl group, a 3,4-dioctylphenyl group, a 4-hexyloxyphenyl group, a 4-octyloxyphenyl group, a 4-(2-ethoxy)ethoxyphenyl group, a 4-(4′-tert-butylbiphenylyl) group, a 9,9-dihexylfluorene-2-yl group, a 9,9-dioctylfluorene-2-yl group, a pentyl group, a hexyl group, a 2-ethylhexyl group, an octyl group or a 3,7-dimethyloctyl group, since then the heat resistance and solubility in an organic solvent of the polymer compound according to the present embodiment are excellent.

It is preferable that both R^{2a} and R^{2b} represent an aryl group substituted by an alkyl group or an aryl group or, R^{2a} represents an aryl group substituted by an alkyl group or an aryl group and R^{2b} represents an alkyl group having 1 to 8 carbon atoms, in the above-described general formula (2), from the standpoint of enhancing luminance stability in driving when the polymer compound according to the present embodiment is used in a light emitting device.

The constitutional unit represented by the above-described general formula (2) is preferably a constitutional unit represented by the following formulae 2-501 to 2-520.

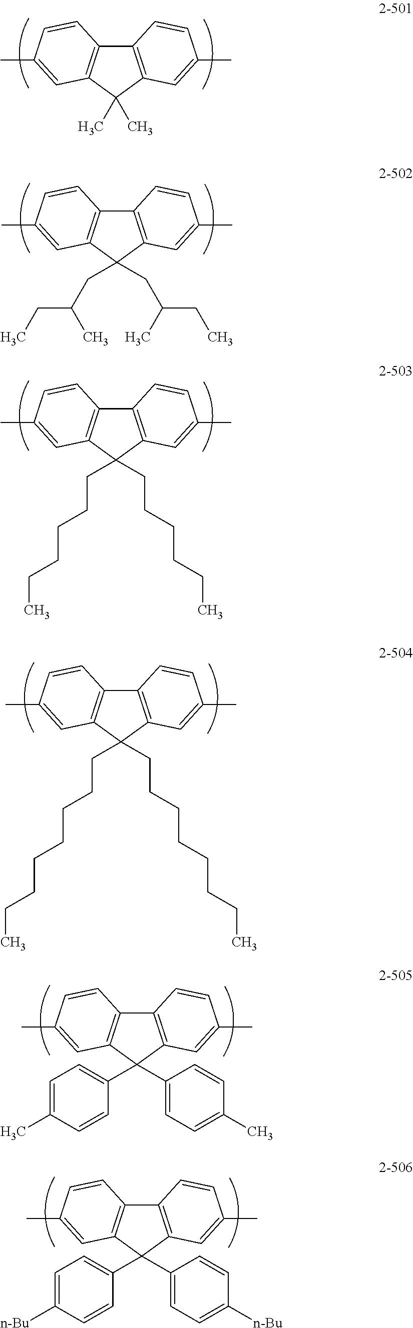

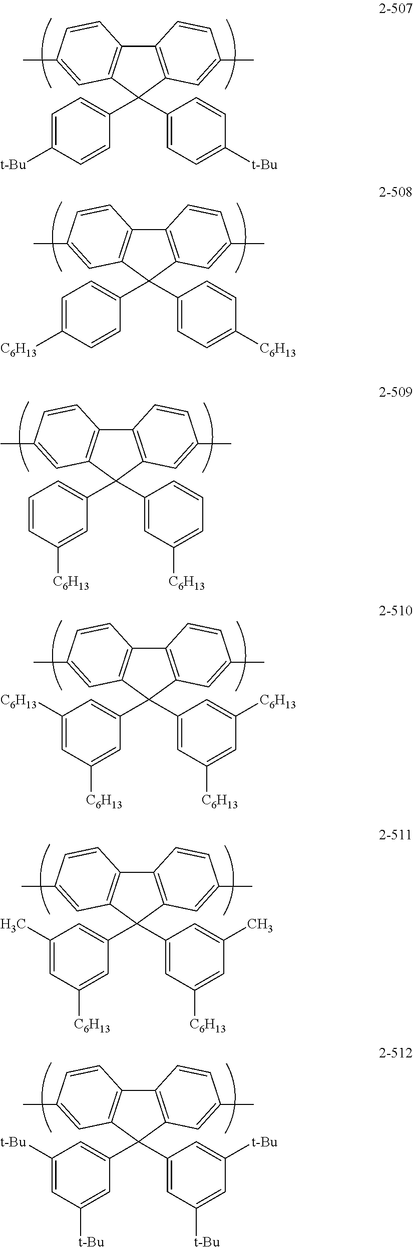

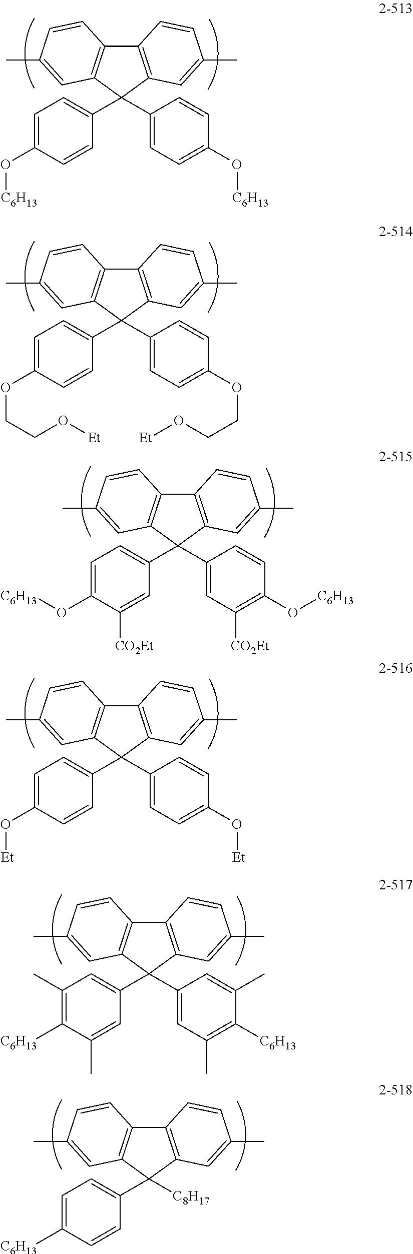

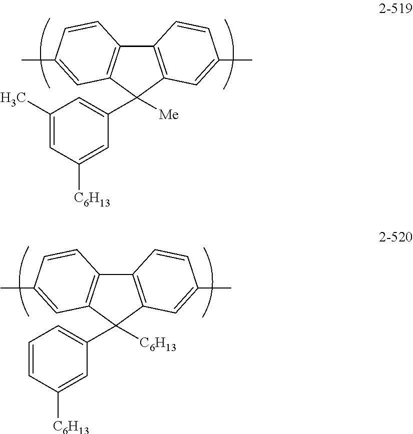

One or two or more constitutional units represented by the above-described general formula (2) may be contained in the polymer compound according to the present embodiment.

### [Third Constitutional Unit]

It is preferable that the polymer compound according to the present embodiment contains a constitutional unit represented by the following general formula (3) (hereinafter, also referred to as “third constitutional unit”), since then the light emission efficiency of the resultant organic light emitting device is more excellent and further, heat resistance thereof is improved.

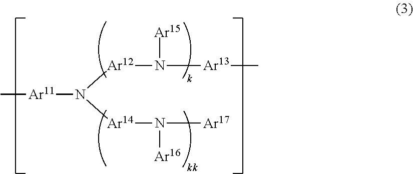

[in the formula (3),

k and kk are each independently 0 or 1,

Ar¹¹, Ar¹², Ar¹³ and Ar¹⁴ each independently represent an arylene group, a divalent aromatic heterocyclic group or a divalent group obtained by linking two or more identical or different groups selected from the group consisting of an arylene group and a divalent aromatic heterocyclic group,

Ar¹⁵, Ar¹⁶ and Ar¹⁷ each independently represent an aryl group or a monovalent aromatic heterocyclic group.

Ar¹¹, Ar¹², Ar¹³, Ar¹⁴, Ar¹⁵, Ar¹⁶ and Ar¹⁷ may have one or several substituents selected from the group consisting of an alkyl group, an aryl group, a monovalent aromatic heterocyclic group, a group represented by —O—R^{A}, a group represented by —S—R^{A}, a group represented by —C(═O)—R^{A}, a group represented by —C(═O)—O—R^{A}, a cyano group and a fluorine atom.

Of groups represented by Ar¹¹, Ar¹², Ar¹³, Ar¹⁴, Ar¹⁵, Ar¹⁶ and Ar¹⁷, groups linked to the same nitrogen atom may be mutually linked via a single bond or a group represented by —O—, —S—, —C(═O)—, —C(═O)—O—, —N(R^{A})—, —C(═O)—N(R^{A})— or —C(R^{A})(R^{A})—.

R^{A} represents the same meaning as described above.].

The arylene group represented by Ar¹¹, Ar¹², Ar¹³ and Ar¹⁴ in the above-described general formula (3) includes the same groups as the arylene group represented by Ar¹ described above.

The divalent aromatic heterocyclic group represented by Ar¹¹, Ar¹², Ar¹³ and Ar¹⁴ in the above-described general formula (3) includes the same groups as the divalent aromatic heterocyclic group represented by Ar¹ described above.

As “divalent group obtained by linking two or more identical or different groups selected from the group consisting of an arylene group and a divalent aromatic heterocyclic group” represented by Ar¹¹, Ar¹², Ar¹³ and Ar¹⁴ in the above-described general formula (3), the same groups as the group represented by Ar² and Ar⁴ described above are exemplified.

Ar¹¹, Ar¹², Ar¹³ and Ar¹⁴ represent preferably an arylene group, more preferably a 1,4-phenylene group (the formula 2-001) or a fluorene-2,7-diyl group (the formula 2-009), further preferably a 1,4-phenylene group (the formula 2-001), since then the stability of the polymer compound according to the present embodiment is excellent and the light emission efficiency of an organic light emitting device using the polymer compound is more excellent.

The aryl group and monovalent aromatic heterocyclic group represented by Ar¹⁵, Ar¹⁶ and Ar¹⁷ in the above-described general formula (3) include the same groups as the aryl group and the same groups as the monovalent aromatic heterocyclic group represented by Ar³, Ar⁵, Ar⁶ and Ar⁷ described above, respectively.

Of groups represented by Ar¹¹, Ar¹², Ar¹³, Ar¹⁴, Ar¹⁵, Ar¹⁶ and Ar¹⁷ in the above-described general formula (3), groups linked to the same nitrogen atom may be mutually linked via a single bond or a group represented by —O—, —S—, —C(═O)—, —C(═O)—O—, —N(R^{A})—, —C(═O)—N(R^{A})— or —C(R^{A})(R^{A})—. By this, a 5 to 7-membered ring is usually formed.

The constitutional unit represented by the above-described general formula (3) includes preferably constitutional units represented by the following formulae 3-001 to 3-006.

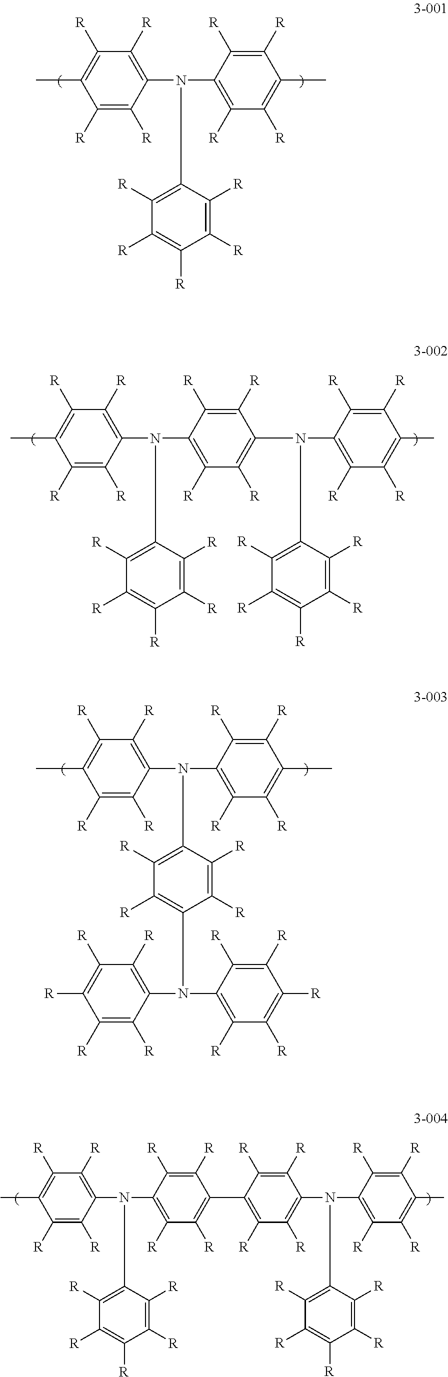

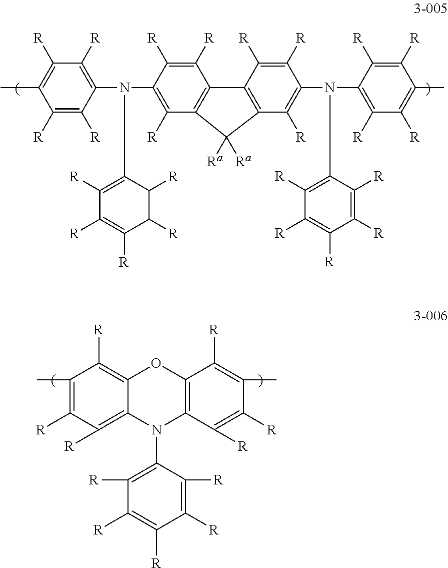

[in the formulae 3-001 to 3-006, R and R^{a} are the same as described above.].

As the constitutional unit represented by the above-described general formula (3), those represented by the above-described general formulae 3-001 to 3-006 in which R represents a hydrogen atom, an alkyl group, an aryl group or a monovalent aromatic heterocyclic group are preferable, and those in which R represents a hydrogen atom or an alkyl group are more preferable, and those represented by the above-described general formulae 3-001 to 3-006 in which R^{a} represents an alkyl group or an aryl group are preferable, since then the stability of the polymer compound according to the present embodiment is excellent and the light emission efficiency of an organic light emitting device using the polymer compound is further excellent.

Of them, constitutional units represented by the following formulae 3-101 to 3-106 are preferable as the constitutional unit represented by the above-described general formula (3), since then the stability of the polymer compound according to the present embodiment is excellent and the light emission efficiency of an organic light emitting device using the polymer compound is further excellent.

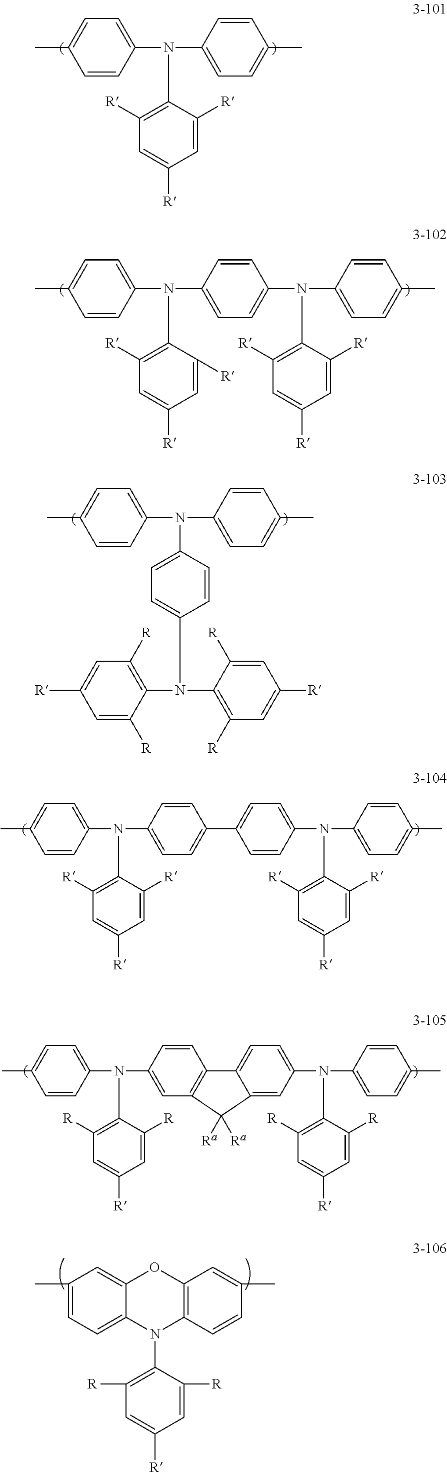

[in the formulae 3-101 to 3-106, R and R^{a} are the same as described above. R′ represents an alkyl group, an aryl group or a monovalent aromatic heterocyclic group. A plurality of R′s may be the same or different.]

One or two or more constitutional units represented by the above-described general formula (3) may be contained in the polymer compound according to the present embodiment.

### [Fourth Constitutional Unit]

The polymer compound according to the present embodiment may contain a constitutional unit represented by the following general formula (4) (this constitutional unit is different from the first constitutional unit, the second constitutional unit and the third constitutional unit, and hereinafter, also referred to as “fourth constitutional unit”).

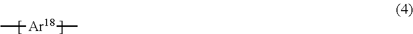

[in the formula (4), Ar¹⁸ represents an arylene group, a divalent aromatic heterocyclic group or a divalent group obtained by linking two or more identical or different groups selected from the group consisting of an arylene group and a divalent aromatic heterocyclic group. Ar¹⁸ may have one or several substituents selected from the group consisting of an alkyl group, an aryl group, a monovalent aromatic heterocyclic group, a group represented by —O—R^{A}, a group represented by —S—R^{A}, a group represented by —C(═O)—R^{A}, a group represented by —C(═O)—O—R^{A}, a cyano group and a fluorine atom. R^{A} represents the same meaning as described above.].

The arylene group represented by Ar¹⁸ in the above-described general formula (4) includes the same groups as the arylene group represented by Ar¹ described above.

The divalent aromatic heterocyclic group represented by Ar¹⁸ in the above-described general formula (4) includes the same groups as the divalent aromatic heterocyclic group represented by Ar¹ described above.

As the “divalent group obtained by linking two or more identical or different groups selected from the group consisting of an arylene group and a divalent aromatic heterocyclic group” represented by Ar¹⁸ in the above-described general formula (4), the same groups as “divalent group obtained by linking two or more identical or different groups selected from the group consisting of an arylene group and a divalent aromatic heterocyclic group” represented by Ar² and Ar⁴ described above are exemplified.

Ar¹⁸ represents preferably an arylene group, further preferably a 1,4-phenylene group (the formula 2-001), a naphthalene-2,6-diyl group (the formula 2-006), a 9,10-dihydrophenanthrene-2,7-diyl group (the formula 2-007), a benzofluorene diyl group represented by (the formula 2-010) to (the formula 2-012), an anthracene-2,6-diyl group (the formula 2-013) or an anthracene-9,10-diyl group (the formula 2-014), since then the stability of the polymer compound according to the present embodiment is excellent and the light emission efficiency of an organic light emitting device using the polymer compound is more excellent.

One or two or more constitutional units represented by the above-described general formula (4) (fourth constitutional unit) may be contained in the polymer compound according to the present embodiment.

In the polymer compound according to the present embodiment, the content of the first constitutional unit is preferably 0.1% by mol or more, more preferably 0.5% by mol or more with respect to the total content of the first constitutional unit and the second constitutional unit, since then the light emission efficiency of an organic light emitting device obtained using the polymer compound is further excellent. The above-described content is preferably 20% by mol or less, more preferably 10% by mol or less, further preferably 7% by mol or less, since then the light emission efficiency of an organic light emitting device obtained using the polymer compound is further excellent and the solubility in an organic solvent of the polymer compound is improved.

When the polymer compound according to the present embodiment contains the third constitutional unit, the content of the first constitutional unit is preferably 0.1% by mol or more, more preferably 0.5% by mol or more with respect to the total content of the first constitutional unit, the second constitutional unit and the third constitutional unit, since then the light emission efficiency of an organic light emitting device obtained using the polymer compound is further excellent. The above-described content is preferably 15% by mol or less, more preferably 10% by mol or less, further preferably 5% by mol or less, since then the light emission efficiency of an organic light emitting device obtained using the polymer compound is further excellent and the solubility in an organic solvent of the polymer compound is improved.

When the polymer compound according to the present embodiment contains the third constitutional unit, the total content of the first constitutional unit and the third constitutional unit is preferably 1% by mol or more, more preferably 2% by mol or more with respect to the total content of the first constitutional unit, the second constitutional unit and the third constitutional unit, since then the luminance stability in driving of an organic light emitting device obtained using the polymer compound is further excellent. The above-described content is preferably 20% by mol or less, more preferably 10% by mol or less, further preferably 8% by mol or less, since then the light emission efficiency of an organic light emitting device obtained using the polymer compound is further excellent and the solubility in an organic solvent of the polymer compound is improved.

In the polymer compound according to the present embodiment, the total content of the first constitutional unit and the second constitutional unit is preferably 80% by mass or more, more preferably 90% by mass or more based on the total amount of the polymer compound.

When the polymer compound according to the present embodiment contains the third constitutional unit, the total content of the first constitutional unit, the second constitutional unit and the third constitutional unit is preferably 80% by mass or more, more preferably 90% by mass or more based on the total amount of the polymer compound.

As the polymer compound according to the present embodiment, preferable are polymer compounds EP1 and EP2 containing a constitutional unit represented by the above-described general formula (1), (1a) or (1b) (first constitutional unit), a constitutional unit represented by the above-described general formula (2) (second constitutional unit), a constitutional unit represented by the above-described general formula (3) (third constitutional unit), a constitutional unit represented by the above-described general formula (4) (fourth constitutional unit) and other constitutional unit (different from phosphorescent constitutional unit described later) at ratios (% by mol) shown in Table 1 below. Here, “other constitutional unit” has one atomic group linking two constitutional units selected from the group consisting of the first constitutional unit, the second constitutional unit, the third constitutional unit and the fourth constitutional unit (namely, both ends of one atomic group are linked to one constitutional unit selected from the group consisting of the first constitutional unit, the second constitutional unit, the third constitutional unit and the fourth constitutional unit) as one constitutional unit. In the polymer compound according to the present embodiment, the total content of the constitutional units is 100% by mol.

Examples of the above-described other constitutional unit include a divalent group obtained by linking two constitutional units selected independently from the group consisting of the first constitutional unit, the second constitutional unit, the third constitutional unit and the fourth constitutional unit via a non-conjugated bond, and the like.

TABLE 1

| | Constitutional unit and ratio thereof (% by mol) | | | | |
|---|---|---|---|---|---|
| | | | third | fourth | |
| | first | second | consti- | consti- | |
| | constitutional | constitutional | tutional | tutional | |
| | unit | unit | unit | unit | other |
| EP1 | 0.1 to 20 | 60 to 99.9 | 0 | 0 to 10 | 0 to 10 |
| EP2 | 0.2 to 15 | 60 to 99 | 0.2 to 15 | 0 to 10 | 0 to 10 |

As the polymer compound according to the present embodiment, more preferable are polymer compounds EP3 and EP4 containing constitutional units at ratios (% by mol) shown in Table 2 below.

TABLE 2

| | Constitutional unit and ratio thereof (% by mol) | | | | |
|---|---|---|---|---|---|
| | | | third | fourth | |
| | first | second | consti- | consti- | |
| | constitutional | constitutional | tutional | tutional | |
| | unit | unit | unit | unit | other |
| EP3 | 0.5 to 10 | 70 to 99.5 | 0 | 0 to 10 | 0 to 10 |
| EP4 | 0.5 to 10 | 70 to 99 | 0.5 to 10 | 0 to 10 | 0 to 10 |

As the polymer compound according to the present embodiment, further preferable are polymer compounds EP5 and EP6 containing constitutional units at ratios (% by mol) shown in Table 3 below.

TABLE 3

| | Constitutional unit and ratio thereof (% by mol) | | | | |
|---|---|---|---|---|---|
| | | | third | fourth | |
| | first | second | consti- | consti- | |
| | constitutional | constitutional | tutional | tutional | |
| | unit | unit | unit | unit | other |
| EP5 | 0.5 to 7 | 93 to 99.5 | 0 | 0 | 0 |
| EP6 | 0.5 to 5 | 92 to 98 | 1.5 to 7.5 | 0 | 0 |

Suitable examples of the polymer compound EP5 are shown in Table 4. As examples of the polymer compound, the kinds of constitutional units constituting the compound and the ratios of constitutional units occupying the compound are shown in Table 4. As the polymer compound EP5, the following polymer compounds EP5-01 to EP5-06 are preferable.

TABLE 4

| | | first | | second | |
|---|---|---|---|---|---|
| | | constitutional | | constitutional | |
| | | unit | | unit | |
| EP5-01 | constitutional | formula | formula | formula 2-504 | |
| | unit | 1a-004 | 1b-004 | | |
| | ratio | 0.5 to 7% by mol | | 93 to 99.5% by mol | |
| | (% by mol) | in total | | | |
| EP5-02 | constitutional | formula | formula | formula 2-504 | |
| | unit | 1a-102 | 1b-102 | | |
| | ratio | 0.5 to 7% by mol | | 93 to 99.5% by mol | |
| | (% by mol) | in total | | | |
| EP5-03 | constitutional | formula | formula | formula 2-508 | |
| | unit | 1a-002 | 1b-002 | | |
| | ratio | 0.5 to 7% by mol | | 93 to 99.5% by mol | |
| | (% by mol) | in total | | | |
| EP5-04 | constitutional | formula | formula | formula 2-509 | |
| | unit | 1a-008 | 1b-008 | | |
| | ratio | 0.5 to 7% by mol | | 93 to 99.5% by mol | |
| | (% by mol) | in total | | | |
| EP5-05 | constitutional | formula | formula | formula | formula |
| | unit | 1a-004 | 1b-004 | 2-511 | 2-504 |
| | ratio | 0.5 to 7% by mol | | 93 to 99.5% by mol | |
| | (% by mol) | in total | | in total | |
| EP5-06 | constitutional | formula | formula | formula | formula |
| | unit | 1a-102 | 1b-102 | 2-509 | 2-505 |

| | | |
|---|---|---|
| ratio | 0.5 to 7% by mol | 93 to 99.5% by mol |
| (% by mol) | in total | in total |

[in the table, the ratio (% by mol) represents the content of each constitutional unit, and the total content is 100% by mol.]

Suitable examples of the polymer compound EP6 are shown in Tables 5 and 6 below. As examples of the polymer compound, the kinds of constitutional units constituting the compound and the ratios of constitutional units occupying the compound are shown in Tables 5 and 6. As the polymer compound EP6, the following polymer compounds EP6-01 to EP6-12 are preferable.

TABLE 5

| | | first | | second | | | third |
|---|---|---|---|---|---|---|---|
| | | constitutional | | constitutional | | | constitutional |
| | | unit | | unit | | | unit |
| EP6-01 | constitu- | formula | formula | formula | | | formula |
| | tional unit | 1a-004 | 1b-004 | 2-504 | | | 3-102 |
| | ratio | 0.5 to 5% | | 92 to 98% | | | 1.5 to 7.5% |
| | (% by mol) | by mol in total | | by mol | | | by mol |
| EP6-02 | constitu- | formula | formula | formula | | | formula |
| | tional unit | 1a-102 | 1b-102 | 2-504 | | | 3-101 |
| | ratio | 0.5 to 5% | | 92 to 98% | | | 1.5 to 7.5% |
| | (% by mol) | by mol in total | | by mol | | | by mol |
| EP6-03 | constitu- | formula | formula | formula | formula | | formula |
| | tional unit | 1a-002 | 1 b-002 | 2-508 | 2-503 | | 3-105 |
| | ratio | 0.5 to 5% | | 92 to 98% | | | 1.5 to 7.5% |
| | (% by mol) | by mol in total | | by mol in total | | | by mol |
| EP6-04 | constitu- | formula | formula | formula | formula | | formula |
| | tional unit | 1a-008 | 1 b-008 | 2-505 | 2-510 | | 3-106 |
| | ratio | 0.5 to 5% | | 92 to 98% | | | 1.5 to 7.5% |
| | (% by mol) | by mol in total | | by mol in total | | | by mol |
| EP6-05 | constitu- | formula | formula | formula | formula | formula | formula |
| | tional unit | 1a-102 | 1b-102 | 2-508 | 2-513 | 2-504 | 3-101 |
| | ratio | 0.5 to 5% | | 92 to 98% | | | 1.5 to 7.5% |
| | (% by mol) | by mol in total | | by mol in total | | | by mol |
| EP6-06 | constitu- | formula | formula | formula | formula | formula | formula |
| | tional unit | 1a-004 | 1b-004 | 2-505 | 2-511 | 2-504 | 3-102 |

| | | | |
|---|---|---|---|
| ratio | 0.5 to 5% | 92 to 98% | 1.5 to 7.5% |
| (% by mol) | by mol in total | by mol in total | by mol |

[in the table, the ratio (% by mol) represents the content of each constitutional unit, and the total content is 100% by mol.]

TABLE 6

| | | first | | second | | | third | |
|---|---|---|---|---|---|---|---|---|
| | | constitutional | | constitutional | | | constitutional | |
| | | unit | | unit | | | unit | |
| EP6-07 | constitu- | formula | formula | formula 2-512 | | | formula | formula |
| | tional unit | 1a-004 | 1b-004 | | | | 3-102 | 3-106 |
| | ratio | 0.5 to 5% by mol | | 92 to 98% by mol | | | 1.5 to 7.5% by mol | |
| | (% by mol) | in total | | | | | in total | |
| EP6-08 | constitu- | formula | formula | formula 2-509 | | | formula | formula |
| | tional unit | 1a-102 | 1b-102 | | | | 3-102 | 3-104 |
| | ratio | 0.5 to 5% by mol | | 92 to 98% by mol | | | 1.5 to 7.5% by mol | |
| | (% by mol) | in total | | | | | in total | |
| EP6-09 | constitu- | formula | formula | formula | formula | | formula | formula |
| | tional unit | 1a-002 | 1b-002 | 2-508 | 2-515 | | 3-105 | 3-101 |
| | ratio | 0.5 to 5% by mol | | 92 to 98% by mol | | | 1.5 to 7.5% by mol | |
| | (% by mol) | in total | | in total | | | in total | |
| EP6-10 | constitu- | formula | formula | formula | formula | | formula | formula |
| | tional unit | 1a-008 | 1b-008 | 2-508 | 2-504 | | 3-105 | 3-104 |
| | ratio | 0.5 to 5% by mol | | 92 to 98% by mol | | | 1.5 to 7.5% by mol | |
| | (% by mol) | in total | | in total | | | in total | |
| EP6-11 | constitu- | formula | formula | formula | formula | formula | formula | formula |
| | tional unit | 1a-102 | 1b-102 | 2-508 | 2-509 | 2-503 | 3-104 | 3-106 |
| | ratio | 0.5 to 5% by mol | | 92 to 98% by mol | | | 1.5 to 7.5% by mol | |
| | (% by mol) | in total | | in total | | | in total | |
| EP6-12 | constitu- | formula | formula | formula | formula | formula | formula | formula |
| | tional unit | 1a-004 | 1b-004 | 2-509 | 2-511 | 2-510 | 3-102 | 3-106 |

| | | | |
|---|---|---|---|
| ratio | 0.5 to 5% by mol | 92 to 98% by mol | 1.5 to 7.5% by mol |
| (% by mol) | in total | in total | in total |

[in the formula, the ratio (% by mol) represents the content of each constitutional unit, and the total content is 100% by mol.]

### [Phosphorescent Constitutional Unit]

The polymer compound according to the present embodiment may have a constitutional unit derived from a phosphorescent compound (hereinafter, referred to as phosphorescent constitutional unit).

The polymer compound according to the present embodiment is, for example, a polymer compound showing light emission in a light emission wavelength range from blue-green to red color, and becomes a compound which alone is capable of manifesting white light emission since the first constitutional unit is contained at a specific ratio and a constitutional unit derived from a phosphorescent compound is contained.

The phosphorescent constitutional unit includes a residue obtained by removing one hydrogen atom from a phosphorescent compound, an arylene group or divalent aromatic heterocyclic group having as a substituent a residue obtained by removing one hydrogen atom from a phosphorescent compound, a residue obtained by removing two hydrogen atoms from a phosphorescent compound, a residue obtained by removing three hydrogen atoms from a phosphorescent compound, and the like. When the phosphorescent constitutional unit is a residue obtained by removing three hydrogen atoms from a phosphorescent compound, the polymer compound has a structure branching at this constitutional unit.

For obtaining white light emission, preferable is a constitutional unit derived from a phosphorescent compound having mainly a red light emission wavelength (namely, showing light emission spectrum in a red region around 600 to 650 nm).

As the phosphorescent compound capable of forming a constitutional unit derived from the phosphorescent compound, the following compounds are exemplified. As the phosphorescent compound, known compounds such as a triplet light emitting complex and the like, compounds conventionally used as a phosphorescent material of an organic light emitting device, and the like can be applied.

The phosphorescent compound includes phosphorescent compounds described, for example, in Nature, (1998), 395, 151, Appl. Phys. Lett. (1999), 75(1), 4, Proc. SPIE-Int. Soc. Opt. Eng. (2001), 4105 (Organic Light-Emitting Materials and Devices IV), 119, J. Am. Chem. Soc., (2001), 123, 4304, Appl. Phys. Lett., (1997), 71(18), 2596, Syn. Met., (1998), 94(1), 103, Syn. Met., (1999), 99(2), 1361, Adv. Mater., (1999), 11(10), 852, Inorg. Chem., (2003), 42, 8609, Inorg. Chem., (2004), 43, 6513, Journal of the SID 11/1, 161 (2003), WO2002/066552, WO2004/020504, WO2004/020448, and the like.

It is preferable for the phosphorescent compound that, in highest occupied molecular orbital (HOMO) of a metal complex as a phosphorescent compound, the proportion of the sum of the squares of the orbital coefficients of the outermost d-orbitals of the central metal in the sum of the squares of all atomic orbital coefficients is ⅓ or more, from the standpoint of obtaining high light emission efficiency. Such a metal complex includes, for example, ortho metallized complexes in which the central metal is a transition metal belonging to the period 6, and the like.

The central metal of the metal complex as a phosphorescent compound includes, for example, metal atoms having an atomic number 50 or more, manifesting spin-orbital interaction with the complex and capable of causing intersystem crossing between the singlet state and the triplet state. The central metal is preferably gold, platinum, iridium, osmium, rhenium, tungsten, europium, terbium, thulium, dysprosium, samarium, praseodymium, gadolinium or ytterbium, more preferably gold, platinum, iridium, osmium or rhenium, further preferably gold, platinum, iridium or rhenium, particularly preferably platinum or iridium, especially preferably iridium.

The ligand of the metal complex as a phosphorescent compound in which the central metal is iridium includes a ligand of linking an iridium atom and a nitrogen atom and an oxygen atom by coordination bond or covalent bond such as 8-quinolinol and derivatives thereof, benzoquinolinol and derivatives thereof and the like, a ligand of linking an iridium atom and a nitrogen atom and a carbon atom by coordination bond or covalent bond such as 2-phenyl-pyridine and derivatives thereof, 1-phenylisoquinoline and derivatives thereof and the like, and a ligand of linking an iridium atom and an oxygen atom by coordination bond or covalent bond such as acetylacetone and derivatives thereof and the like.

Preferable are 2-phenylpyridine and derivatives thereof, 1-phenylisoquinoline and derivatives thereof, acetylacetone and derivatives thereof, further preferable are 2-phenylpyridine and derivatives thereof, 1-phenylisoquinoline and derivatives thereof.

The phosphorescent compound is preferably a compound having a substituent such as an alkyl group, an alkoxy group, an aryl group optionally having a substituent, a monovalent aromatic heterocyclic group optionally having a substituent and the like as a partial structure of the phosphorescent compound, particularly preferably a compound having a substituent as a partial structure of its ligand when the phosphorescent compound is a metal complex compound. In this substituent, the total number of atoms other than a hydrogen atom is preferably 3 or more, more preferably 5 or more, further preferably 7 or more, particularly preferably 10 or more. It is preferable that this substituent is present on every ligand. In this case, the kind of the substituent may be the same or different between ligands.

The phosphorescent compound includes, specifically, compounds represented by the following formulae EM01 to E017.

From the standpoint of obtaining white light emission described above, preferable are compounds having a phenylisoquinoline structure as a partial structure of a ligand (EM01 to EM03, EM08 to EM12, EM14 to EM17) and compound having a diaryltriazine-substituted phenylpyridine structure as a partial structure of a ligand (EM13 to EM17), and more preferable are compounds having both the structures (EM14 to EM17). In the following formulae (EM01 to EM17), bonds between an iridium atom and a ligand represented by a dashed line and a solid line represent coordination bond and covalent bond, respectively.

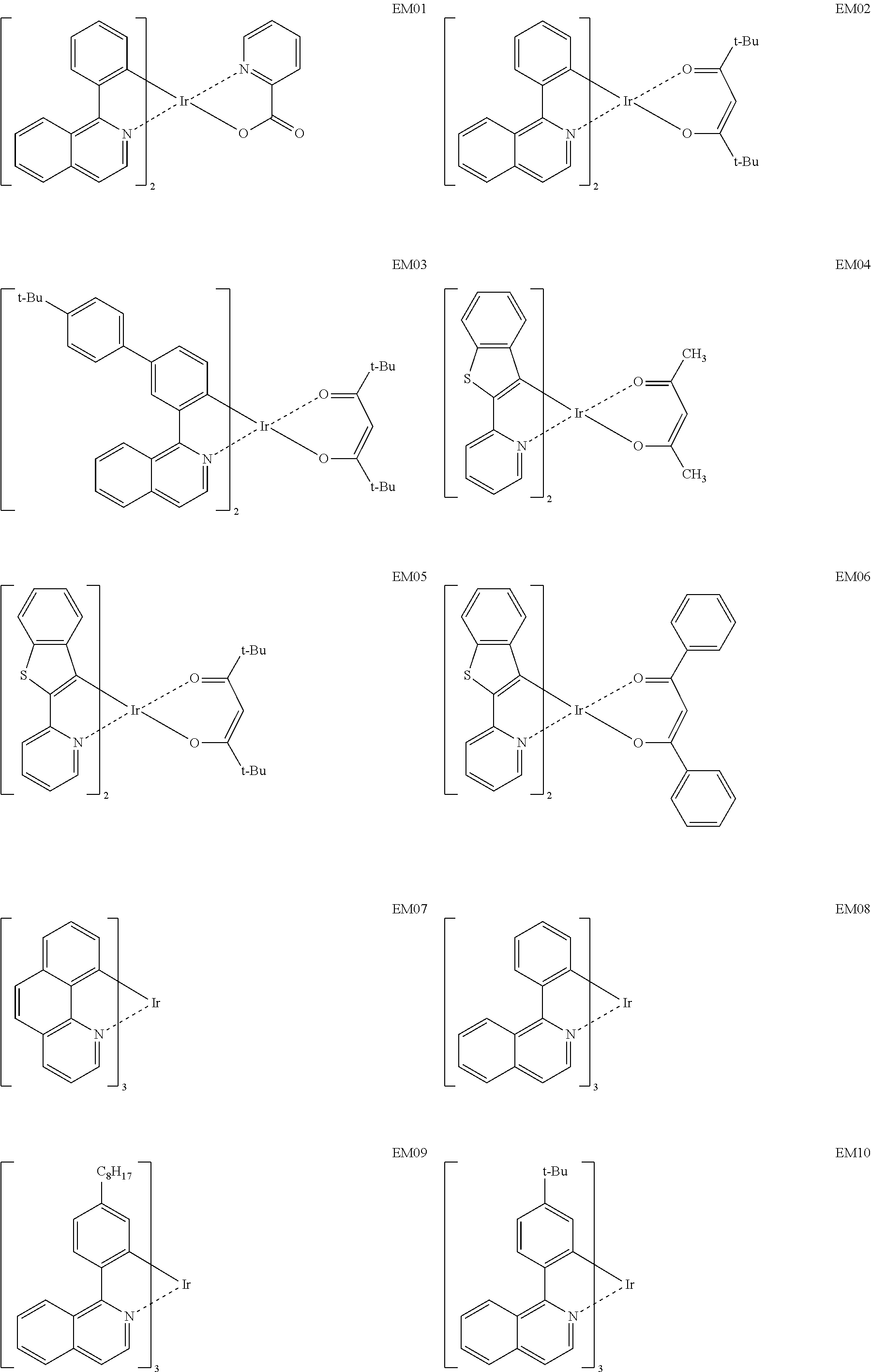

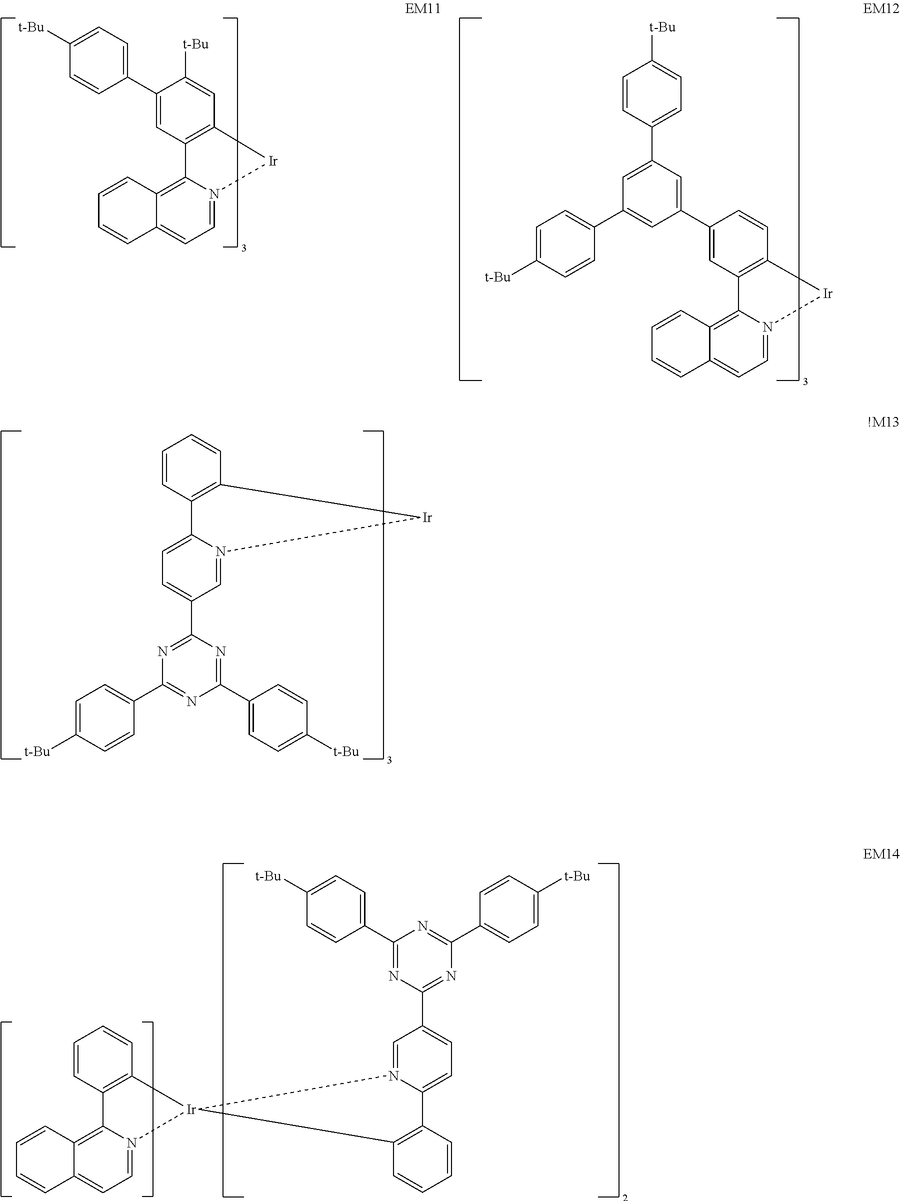

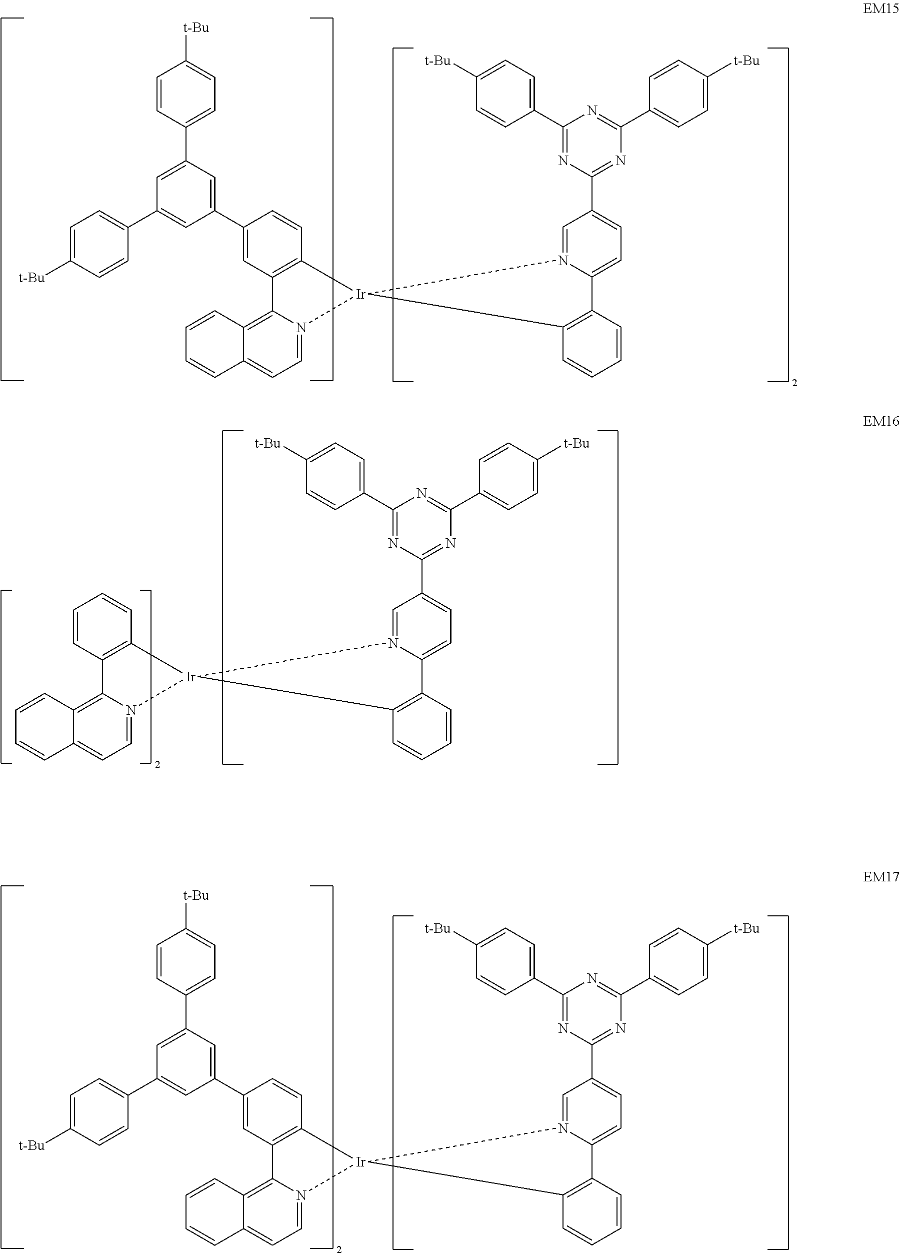

When the polymer compound according to the present embodiment contains a phosphorescent constitutional unit, preferable are polymer compounds EP7 and EP8 containing the above-described first constitutional unit, second constitutional unit, third constitutional unit, fourth constitutional unit, phosphorescent constitutional unit and other constitutional unit at ratios (% by mol) shown in Table 7 below, and EP is more preferable.

TABLE 7

| | Constitutional unit and ratio thereof (% by mol) | | | | | |
|---|---|---|---|---|---|---|
| | first | second | third | fourth | phosphorescent | |
| | constitu- | constitu- | constitu- | constitu- | constitu- | |
| | tional unit | tional unit | tional unit | tional unit | tional unit | other |
| EP7 | 0.01 to 1 | 63 to 99.98 | 0 to 15 | 0 to 10 | 0.01 to 1 | 0 to 10 |
| EP8 | 0.01 to 0.5 | 89 to 98.98 | 1 to 10 | 0 | 0.01 to 0.5 | 0 |

[in the table, the ratio (% by mol) represents the content of each constitutional unit, and the total content is 100% by mol.]

When a polymerization active group remains intact as an end group in the polymer compound according to the present embodiment, there is a possibility of a decrease in the light emitting property and life of an organic light emitting device produced using the polymer compound. Therefore, it is preferable that an end group is a stable group (for example, aryl group, monovalent aromatic heterocyclic group).

The polymer compound according to the present embodiment may have any shape such as a linear polymer, a branched polymer, a hyperbranched polymer, a cyclic polymer, a comb-shaped polymer, a star-shaped polymer, a network polymer or the like. The polymer compound according to the present embodiment may be a polymer having any composition and regularity such as a homo polymer, an alternate copolymer, a periodic copolymer, a random copolymer, a block copolymer, a graft copolymer and the like having any of the above-described shapes.

The polymer compound according to the present embodiment is useful as a light emitting material, a charge transporting material and the like, and in use, the compound may be used together with other compound and used in the form of a polymer composition.

The polymer compound according to the present embodiment has a polystyrene-equivalent number-average molecular weight (Mn) according to gel permeation chromatography (hereinafter, referred to as “GPC”) of usually 1×10³ to 1×10⁸, preferably 1×10⁴ to 1×10⁶. The polymer compound according to the present embodiment has a polystyrene-equivalent weight-average molecular weight (Mw) of usually 1×10³ to 1×10⁸, and preferably 1×10⁴ to 5×10⁶, more preferably 3×10⁴ to 1×10⁶, further preferably 5×10⁴ to 5×10⁵, since then film formability is excellent and the light emission efficiency of an organic light emitting device produced using the polymer compound is more excellent.

It is preferable that the glass transition temperature Tg of the polymer compound according to the present embodiment is 70° C. or higher, since then durability against various processes for producing an organic light emitting device becomes better and the heat resistance of the organic light emitting device is enhanced.

An organic light emitting device using the polymer compound according to the present embodiment is useful for a backlight of a liquid crystal display, a curved or surface light source for illumination, and displays such as a segment type display device, a dot matrix flat panel display and the like. The polymer compound according to the present embodiment is useful also as a dye for laser, an organic solar battery material, an organic semiconductor for an organic transistor, a material for a conductive film such as an electrically conductive film, an organic semiconductor film and the like, and a material of a luminous film emitting fluorescence or phosphorescence.

### <Production Method of Polymer Compound>

For production of the polymer compound according to the present embodiment, a compound represented by the following general formula (M-1) having a structure in which the first constitutional unit is introduced and a compound represented by the following general formula (M-2) having a structure in which the second constitutional unit is introduced are used, and when the third constitutional unit is contained, a compound represented by the following general formula (M-3) is further used, and when the fourth constitutional unit is contained, a compound represented by the following general formula (M-4) is further used, and if necessary, these are dissolved in an organic solvent, and condensation polymerization such as known aryl-aryl coupling using a compound acting as a ligand, an alkali, a catalyst and the like is performed, thereby producing the polymer compound.

The polymer compound containing a constitutional unit derived from the phosphorescent compound of the present invention can be produced by using as a monomer a compound represented by the following general formula (M-6) obtained by substitution of groups selected from the group consisting of the above-described substituent group A and the following substituent group B for two or three connecting bonds of constitutional units derived from a phosphorescent compound described above, in addition to compounds represented by the formulae (M-1), (M-2), (M-3) and (M-4), in synthesis of the polymer compound according to the present embodiment.

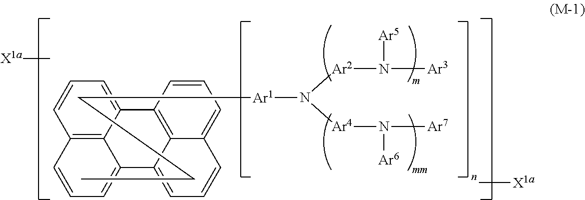

[in the formula (M-1),

Ar¹, Ar², Ar³, Ar⁴, Ar⁵, Ar⁶, Ar⁷, m, mm and n represent the same meaning as for Ar¹, Ar², Ar³, Ar⁴, Ar⁵, Ar⁶, Ar⁷, m, mm and n in the above-described general formula (1).

X^{1a} represents a group selected from the group consisting of the following substituent group A and the following substituent group B,

and denotes a hydrogen atom constituting a perylene ring, or, an arylene group or divalent aromatic heterocyclic group represented by Ar¹, an arylene group, a divalent aromatic heterocyclic group or a divalent group obtained by linking two or more identical or different groups selected from the group consisting of an arylene group and a divalent aromatic heterocyclic group represented by Ar² and Ar⁴, or a group to be substituted by two hydrogen atoms selected from hydrogen atoms constituting an aromatic ring of an aryl group or monovalent aromatic heterocyclic group represented by Ar³, Ar⁵, Ar⁶ and Ar⁷.

Two X^{1a}s may be the same or different.].

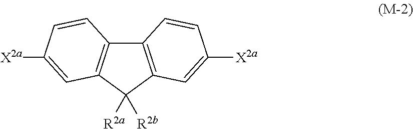

[in the formula (M-2), R^{2a} and R^{2b} represent the same meaning as for R^{2a} and R^{2b} in the above-described general formula (2). X^{2a} represents a group selected from the group consisting of the following substituent group A and the following substituent group B. Two X^{2a}s may be the same or different.].

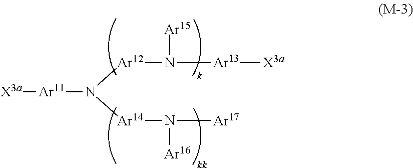

[in the formula (M-3), k, kk, Ar¹¹, Ar¹², Ar¹³, Ar¹⁴, Ar¹⁵, Ar¹⁶ and Ar¹⁷ represent the same meaning as for k, kk, Ar¹¹, Ar¹², Ar¹³, Ar¹⁴, Ar¹⁵, Ar¹⁶ and Ar¹⁷ in the above-described general formula (3). X^{3a} represents a group selected from the group consisting of the following substituent group A and the following substituent group B. Two X^{3a}s may be the same or different.].

X^{4a}—Ar¹⁸—X^{4a} (M-4)

[in the formula (M-4), Ar¹⁸ represents the same meaning as for Ar¹⁸ in the above-described general formula (4). X⁴s represents a group selected from the group consisting of the following substituent group A and the following substituent group B. Two X^{4a}s may be the same or different.].

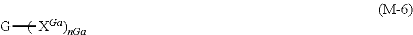

[in the formula (M-6) G represents a 2 or 3-valent group derived from the above-described phosphorescent compound, and include also the above-described arylene group or divalent aromatic heterocyclic group having as a substituent a monovalent group derived from a phosphorescent compound. X^{Ga} represents a group selected from the group consisting of the following substituent group A and the following substituent group B. nGa represents an integer of 2 or 3.].

### (Substituent Group A)

a chlorine atom, a bromine atom, an iodine atom and groups represented by —O—S(═O)₂R²⁰ (R²⁰ represents an alkyl group or an aryl group optionally substituted by an alkyl group, an alkoxy group, a nitro group, a fluorine atom or a cyano group).

### (Substituent Group B)

groups represented by —B(OR²¹)₂ (R²¹ represents a hydrogen atom or an alkyl group, two R²¹s may be the same or different, or may be mutually linked to form a ring.), groups represented by —BF₄Q¹ (Q¹ represents a 1-valent cation of lithium, sodium, potassium, rubidium or cesium), groups represented by —Sn(R²²)₃ (R²² represents a hydrogen atom or an alkyl group, three R²²s may be the same or different, or may be mutually linked to form a ring), groups represented by —MgY¹ (Y¹ represents a chlorine atom, a bromine atom or an iodine atom.), groups represented by —ZnY² (Y² represents a chlorine atom, a bromine atom or an iodine atom.).

The carbon atom number of the alkyl group represented by R²⁰, R²¹ and R²² in the above-described general formulae (M-1), (M-2), (M-3), (M-4) and (M-6) is usually 1 to 20, preferably 1 to 15, more preferably 1 to 10.

The aryl group represented by R²⁰ in the above-described general formulae (M-1), (M-2), (M-3), (M-4) and (M-6) is preferably a phenyl group, a 4-tolyl group, a 4-methoxyphenyl group, a 4-nitrophenyl group, a 3-nitrophenyl group, a 2-nitrophenyl group or a 4-trifluoromethylphenyl group, since then synthesis of the polymer compound of the present invention is easy and the reactivity in polymerization of the compound is excellent.

The group represented by —O—S(═O)₂R²⁰ in the above-described general formulae (M-1), (M-2), (M-3), (M-4) and (M-6) includes a methanesulfonyloxy group, a trifluoromethanesulfonyloxy group, a phenylsulfonyloxy group, a 4-methylphenylsulfonyloxy group, a 4-trifluoromethylphenylsulfonyloxy group and the like.

The group represented by —B(OR²¹)₂ in the above-described general formulae (M-1), (M-2), (M-3), (M-4) and (M-6) includes groups represented by the following formulae, and the like.

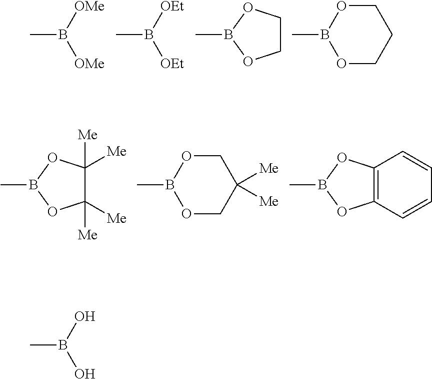

The group represented by —BF₄⁻Q¹ in the above-described general formulae (M-1), (M-2), (M-3), (M-4) and (M-6) includes groups represented by the following formulae, and the like.

—BF₄⁻K⁺

The group represented by —Sn(R²²)₃ in the above-described general formulae (M-1), (M-2), (M-3), (M-4) and (M-6) includes a trimethylstannanyl group, triethylstannanyl group, tributylstannanyl group and the like.

When the resulting polymer compound is used in an organic light emitting device, the purity of the compound represented by the above-described general formula (M-1), (M-2), (M-3), (M-4) or (M-6) exerts an influence on the performance of the light emitting device, therefore, it is preferable to purify the compound before polymerization by a method such as distillation, sublimation purification, re-crystallization and the like before performing condensation polymerization.

In the method of producing the polymer compound according to the present embodiment, it is preferable that the ratio of a compound represented by the above-described general formula (M-1) is 0.1 to 20% by mol with respect to the sum of a compound represented by the above-described general formula (M-1) and a compound represented by the above-described general formula (M-2). By this, a polymer compound in which the ratio of a constitutional unit represented by the above-described general formula (1) is 0.1 to 20% by mol with respect to the sum of a constitutional unit represented by the above-described general formula (1) and a constitutional unit represented by the above-described general formula (2) can be easily produced.

In the method of producing the polymer compound according to the present embodiment, it is preferable that the ratio of a compound represented by the above-described general formula (M-1) is 0.1 to 15% by mol with respect to the sum of a compound represented by the above-described general formula (M-1), a compound represented by the above-described general formula (M-2) and a compound represented by the above-described general formula (M-3). By this, a polymer compound in which the ratio of a constitutional unit represented by the above-described general formula (1) is 0.1 to 15% by mol with respect to the sum of a constitutional unit represented by the above-described general formula (1), a constitutional unit represented by the above-described general formula (2) and a constitutional unit represented by the above-described general formula (3) can be easily produced.

In the method of producing the polymer compound according to the present embodiment, it is preferable that the total ratio of a compound represented by the above-described general formula (M-1) and a compound represented by the above-described general formula (M-3) is 1 to 20% by mol with respect to the sum of a compound represented by the above-described general formula (M-1), a compound represented by the above-described general formula (M-2) and a compound represented by the above-described general formula (M-3). By this, a polymer compound in which the total ratio of a constitutional unit represented by the above-described general formula (1) and a constitutional unit represented by the above-described general formula (3) is 1 to 20% by mol with respect to the sum of a constitutional unit represented by the above-described general formula (1), a constitutional unit represented by the above-described general formula (2) and a constitutional unit represented by the above-described general formula (3) can be easily produced.

In production of the polymer compound, it is preferable that the total ratio of a compound represented by the above-described general formula (M-1) and a compound represented by the above-described general formula (M-2) excluding a group represented by X^{1a} in the formula (M-1) and a group represented by X^{2a} in the formula (M-2) is 80% by mass or more with respect to all monomer compounds. By this, a polymer compound in which the total ratio of a constitutional unit represented by the above-described general formula (1) and a constitutional unit represented by the above-described general formula (2) is 80% by mass or more with respect to all constitutional units constituting the compound can be easily synthesized.

In production of the polymer compound, it is preferable that the total ratio of a compound represented by the above-described general formula (M-1), a compound represented by the above-described general formula (M-2) and a compound represented by the above-described general formula (M-3) excluding a group represented by X^{1a} in the formula (M-1), a group represented by X^{2a} in the formula (M-2) and a group represented by X^{3a} in the formula (M-3) is 80% by mass or more with respect to all monomer compounds. By this, a polymer compound in which the total ratio of a constitutional unit represented by the above-described general formula (1), a constitutional unit represented by the above-described general formula (2) and a constitutional unit represented by the above-described general formula (3) is 80% by mass or more with respect to all constitutional units constituting the compound can be easily synthesized.

The above-described condensation polymerization includes a method of polymerization by the Suzuki coupling reaction (Chemical Reviews (Chem. Rev.), vol. 95, pp. 2457-2483 (1995)), a method of polymerization by the Grignard reaction (Bull. Chem. Soc. Jpn., vol. 51, p. 2091 (1978)), a method of polymerization with a Ni(0) catalyst (Progress in Polymer Science, vol. 17, pp. 1153 to 1205, 1992), a method using the Stille coupling reaction (European Polymer Journal, vol. 41, pp. 2923-2933 (2005)), and the like, and the method of polymerization by the Suzuki coupling reaction and the method of polymerization with a Ni(0) catalyst are preferable since a compound as a raw material can be easily synthesized and operation of the polymerization reaction is simple. From the standpoint of easiness of control of the structure of a polymer compound, methods of polymerization by a cross coupling reaction such as the Suzuki coupling reaction, the Grignard reaction, the Stille coupling reaction and the like are more preferable, and the reaction of polymerization by the Suzuki coupling reaction is particularly preferable.

As X^{1a}, X^{2a}, X^{3a}, X^{4a} and X^{Ga} in the above-described general formulae (M-1), (M-2), (M-3), (M-4) and (M-6), suitable groups may be selected depending on the kind of the polymerization reaction, and when the method of polymerization by the Suzuki coupling reaction is adopted, a bromine atom, an iodine atom, a chlorine atom and —B(OR²¹)₂ are preferable, a bromine atom and —B(OR²¹)₂ are more preferable, since then a compound represented by the above-described general formulae (M-1), (M-2), (M-3), (M-4) and (M-6) can be simply synthesized and easily handled.

The above-described condensation polymerization method includes methods in which compounds represented by the formulae (M-1), (M-2), (M-3), (M-4) and (M-6) having the above-described substituent group A and the above-described substituent group B as a polymerization reactive group are reacted, if necessary, together with a catalyst, a base and the like. In the case of adoption of a method of polymerization by a cross coupling reaction such as the Suzuki coupling reaction, the Grignard reaction, the Stille coupling reaction and the like, the total ratios of the molar amount of groups selected from the above-described substituent group A and the molar amount of groups selected from the above-described substituent group B contained in the whole compound may be advantageously controlled to obtain the desired molecular weight of the resulting polymer compound, and usually, the ratio of the total molar amount of groups selected from the above-described substituent group B to the total molar amount of groups selected from the above-described substituent group A is preferably 0.95 to 1.05, more preferably 0.98 to 1.02, further preferably 0.99 to 1.01.

In polymerization by the Suzuki coupling reaction, the above-described catalyst is a catalyst composed, for example, of a transition metal complex such as a palladium complex such as palladium[tetrakis(triphenylphosphine)], [tris(dibenzylideneacetone)]dipalladium, palladium acetate, dichlorobistriphenylphosphinepalladium and the like, and if necessary, of a ligand such as triphenylphosphine, tri(tert-butyl)phosphine, tris(o-methoxyphenyl)phosphine, tricyclohexylphosphine and the like.

Regarding these catalysts, those previously synthesized may be used or those prepared in the reaction system may be used as they are. These catalysts may be used singly or in combination.

When the above-described catalyst is used, the use amount thereof may be an amount effective as a catalyst, and the amount of the catalyst with respect to the total molar amount of compounds to be used is usually 0.00001 to 3 molar equivalents, preferably 0.00005 to 0.5 molar equivalents, more preferably 0.0001 to 0.2 molar equivalents in terms of a transition metal.

The base to be used in polymerization by the Suzuki coupling reaction include inorganic bases such as sodium carbonate, potassium carbonate, cesium carbonate, potassium fluoride, cesium fluoride, tripotassium phosphate and the like and organic bases such as tetrabutylammonium fluoride, tetrabutylammonium chloride, tetrabutylammonium bromide, tetraethylammonium hydroxide, tetrabutylammonium hydroxide and the like. These bases may also be used in the form of an aqueous solution.

When the above-described base is used, the use amount thereof is usually 0.5 to 20 molar equivalents, preferably 1 to 10 molar equivalents with respect to the total molar amount of compounds to be used.

The above-described condensation polymerization may be carried out in the absence of a solvent or in the presence of a solvent, and usually carried out in the presence of an organic solvent.

The above-described organic solvent includes toluene, xylene, mesitylene, tetrahydrofuran, 1,4-dioxane, dimethoxyethane, N,N-dimethylacetamide, N,N-dimethylformamide and the like. In general, it is desirable to conduct a deoxidation treatment for suppressing side reactions. The above-described organic solvents may be used singly or in combination.

The use amount of the above-described organic solvent is such that the total concentration of compounds is usually, 0.1 to 90% by weight, preferably 1 to 50% by weight, more preferably 2 to 30% by weight.

The reaction temperature of the above-described condensation polymerization is preferably 0 to 200° C., more preferably 20 to 150° C., further preferably 20 to 120° C.

The above-described reaction time is usually 0.5 hours or more, preferably 2 to 500 hours.

The above-described condensation polymerization is conducted under dehydration conditions when the group included in the above-described substituent group (b) is a group represented by —MgY¹.

To prevent remaining of a polymerization active group at the end of the polymer compound according to the present embodiment in the above-described condensation polymerization, a compound to modify the end of the polymer compound (hereinafter, referred to as “end-capping agent” in some cases) may be used. As the compound used as the end-capping agent, a compound represented by the following formula (M-5) is preferable. By this, a polymer compound of which end is substituted by an aryl group or a monovalent aromatic heterocyclic group can be obtained.

X^{19a}—Ar^{19a} (M-5)

[in the formula (M-5), Ar^{19a} represents an aryl group or a monovalent aromatic heterocyclic group. X^{19a} represents a group selected from the above-described substituent group A or a group selected from the above-described substituent group B.].

As the aryl group and monovalent aromatic heterocyclic group represented by Ar^{19a} in the above-described general formula (M-5), aryl groups are preferable, unsubstituted aryl groups or aryl groups substituted by an alkyl group, an aryl group, a monovalent aromatic heterocyclic group or a substituted amino group are more preferable, unsubstituted aryl groups or aryl groups substituted by an alkyl group or an aryl group are further preferable, an unsubstituted phenyl group or phenyl groups substituted by an alkyl group or an aryl group are particularly preferable.

As the group represented by X^{19a} in the above-described general formula (M-5), a bromine atom, an iodine atom, a chlorine atom and —B(OR²¹)₂ are preferable, a bromine atom and —B(OR²¹)₂ are more preferable, like for the above-described X^{1a}, X^{2a}, X^{3a}.

The end-capping agent represented by the above-described general formula (M-5) may be used singly or in combination, in condensation polymerization of the polymer compound according to the present embodiment.

The post treatment of the above-described condensation polymerization can be carried out by known methods, for example, by a method in which a reaction solution obtained in the above-described condensation polymerization is added to a lower alcohol such as methanol and the like to cause deposition of a precipitate which is then filtrated and dried.

When the purity of the polymer compound according to the present embodiment is low, the compound may advantageously be purified by a usual method such as re-crystallization, continuous extraction by a soxhlet extractor, column chromatography and the like, and when the polymer compound according to the present embodiment is used in an organic light emitting device, it is preferable to carry out a purification treatment such as re-precipitation, chromatography and the like after condensation polymerization since the purity thereof exerts an influence on the performance of a device such as a light emitting property and the like.

### <Compound as Monomer>

As the compound represented by the above-described general formula (M-1) which is useful for production of the polymer compound according to the present embodiment, preferable are compounds represented by the above-described general formula (Ma) or compounds represented by the above-described general formula (Mb), or compositions containing a compound represented by the above-described general formula (Ma) and a compound represented by the above-described general formula (Mb) (namely, low molecular weight composition).

The definitions and preferable ranges of m, mm, Ar¹, Ar², Ar³, Ar⁴, Ar⁵, Ar⁶, Ar⁷, na1, na2, na3, na4, nb1, nb2, nb3 and nb4 in the above-described general formula (Ma) and (Mb) are the same as those for m, mm, Ar¹, Ar², Ar³, Ar⁴, Ar⁵, Ar⁶, Ar⁷, na1, na2, na3, na4, nb1, nb2, nb3 and nb4 in the above-described general formula (1a) and (1b).

The definitions and preferable ranges of the arylene group and divalent aromatic heterocyclic group represented by Ar²⁰ in the above-described general formula (Ma) and (Mb) are the same as those for the arylene group and divalent aromatic heterocyclic group represented by Ar¹ described above.

### <High Molecular Weight Composition>

The first high molecular weight composition according to the present embodiment is a composition containing the polymer compound according to the present embodiment and at least one material selected from the group consisting of a hole transporting material, an electron transporting material and a light emitting material. The second high molecular weight composition according to the present embodiment includes a composition containing the polymer compound according to the present embodiment and a solvent, and a composition containing the polymer compound according to the present embodiment, a solvent and at least one material selected from the group consisting of a hole transporting material, an electron transporting material and a light emitting material.

The hole transporting material includes polyvinylcarbazole and derivatives thereof, polysilane and derivatives thereof, polysiloxane derivatives having an aromatic amine structure in a side chain or main chain, pyrazoline derivatives, arylamine derivatives, stilbene derivatives, polyaniline and derivatives thereof, polythiophene and derivatives thereof, polypyrrole and derivatives thereof, poly(p-phenylenevinylene) and derivatives thereof, poly(2,5-thienylenevinylene) and derivatives thereof, and the like. In addition to them, the hole transporting material includes also compounds described in JP-A No. 63-70257, JP-A No. 63-175860, JP-A No. 2-135359, JP-A No. 2-135361, JP-A No. 2-209988, JP-A No. 3-37992, JP-A No. 3-152184.

The content of the hole transporting material is preferably 1 to 500 parts by weight, more preferably 5 to 200 parts by weight with respect to 100 parts by weight of the polymer compound according to the present embodiment in the high molecular weight composition.

The electron transporting material includes oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, fluorenone derivatives, diphenyldicyanoethylene and derivatives thereof, diphenoquinone derivatives, metal complexes of 8-hydroxyquinoline and derivatives thereof, polyquinoline and derivatives thereof, polyquinoxaline and derivatives thereof, polyfluorene and derivatives thereof, and the like. In addition to them, the electron transporting material includes also compounds described in JP-A No. 63-70257, JP-A No. 63-175860, JP-A No. 2-135359, JP-A No. 2-135361, JP-A No. 2-209988, JP-A No. 3-37992, JP-A No. 3-152184.

The content of the electron transporting material is preferably 1 to 500 parts by weight, more preferably 5 to 200 parts by weight with respect to 100 parts by weight of the polymer compound according to the present embodiment in the high molecular weight composition.

As the light emitting material, low molecular weight fluorescent materials, low molecular weight or high molecular weight phosphorescent materials and the like are mentioned. The low molecular weight fluorescent material includes naphthalene derivatives, anthracene and derivatives thereof, perylene and derivatives thereof, aromatic amines, tetraphenylcyclopentadiene and derivatives thereof, tetraphenylbutadiene and derivatives thereof, stilbene derivatives and the like (low molecular weight fluorescent compounds); dyes such as polymethine dyes, xanthene dyes, coumarin dyes, cyanine dyes and the like; fluorescent metal complexes having 8-hydroxyquinoline as a ligand, fluorescent metal complexes having a 8-hydroxyquinoline derivative as a ligand, other fluorescent metal complexes and the like. As the low molecular weight or high molecular weight phosphorescent material, triplet light emitting complexes such as an iridium complex, a platinum complex and the like, and polymer compounds having as a constitutional unit a residue obtained by removing a hydrogen atom from the triplet light emitting complex, and the like, are mentioned, more specifically, phosphorescent compounds described as the phosphorescent compound capable forming the above-described phosphorescent constitutional unit are mentioned.

The content of the light emitting material is preferably 1 to 500 parts by weight, more preferably 5 to 200 parts by weight with respect to 100 parts by weight of the polymer compound according to the present embodiment in the high molecular weight composition.

The second high molecular weight composition according to the present embodiment is one in which a solid component in the composition is dissolved or dispersed in a solvent (including dispersing medium) to give a solution or dispersing medium, and in general, called an ink, liquid composition or the like. It is referred to simply as “solution”, hereinafter.

Here, examples of the solvent include organic solvents such as chlorine-based solvents such as chloroform, methylene chloride, 1,2-dichloroethane, 1,1,2-trichloroethane, chlorobenzene, o-dichlorobenzene and the like; ether solvents such as tetrahydrofuran, dioxane and the like; aromatic hydrocarbon solvents such as toluene, xylene, trimethylbenzene, mesitylene and the like; aliphatic hydrocarbon solvents such as cyclohexane, methylcyclohexane, n-pentane, n-hexane, n-heptane, n-octane, n-nonane, n-decane and the like; ketone solvents such as acetone, methyl ethyl ketone, cyclohexanone and the like; ester solvents such as ethyl acetate, butyl acetate, methyl benzoate, ethylcellosolve acetate and the like; polyhydric alcohols and derivatives thereof such as ethylene glycol, ethylene glycol monobutyl ether, ethylene glycol monoethyl ether, ethylene glycol monomethyl ether, dimethoxyethane, propylene glycol, diethoxymethane, triethylene glycol monoethyl ether, glycerin, 1,2-hexanediol and the like; alcohol solvents such as methanol, ethanol, propanol, isopropanol, cyclohexanol and the like; sulfoxide solvents such as dimethyl sulfoxide and the like; amide solvents such as N-methyl-2-pyrrolidone, N, N-dimethylformamide and the like; etc. These solvents may be used singly or in combination. Of these solvents, an organic solvent having a structure containing a benzene ring and having a melting point of 0° C. or lower and the boiling point of 100° C. or higher is preferably contained since then viscosity and film formability are excellent.

According to the above-described solution, an organic film containing the polymer compound according to the present embodiment or an organic film containing the first high molecular weight composition according to the present embodiment can be produced easily. Specifically, an organic film containing the polymer compound according to the present embodiment is obtained by coating the above-described solution on a substrate and distilling an organic solvent off by heating, pressure reduction and the like. For distillation off of an organic solvent, the conditions can be altered depending on the organic solvent to be used, and for example, the distillation off can be carried out by heating at about 50 to 150° C. under a reduced pressure of about 10⁻³ Pa.

For coating, coating methods can be used such as a spin coat method, a casting method, a microgravure method, a gravure coat method, a bar coat method, a roll coat method, a wire bar coat method, a dip coat method, a slit coat method, a capillary coat method, a spray coat method, a screen printing method, a flexo printing method, an offset printing method, an inkjet print method, a nozzle coat method and the like.

The suitable viscosity of the above-described solution is preferably 0.5 to 500 mPa·s at 25° C. though it varies depending on the printing method. When the above-described solution passes via a discharge apparatus such as in an inkjet print method, the viscosity at 25° C. is preferably 0.5 to 20 mPa·s for preventing clogging and curved flying in discharging. In the second high molecular weight composition according to the present embodiment, the content of the solvent may advantageously be regulated so that the composition gets the above-described viscosity.

### <Organic Film>

The organic film according to the present embodiment is obtained by containing the polymer compound according to the present embodiment or using the high molecular weight composition according to the present embodiment.

The organic film according to the present embodiment contains the polymer compound according to the present embodiment or the first high molecular weight composition according to the present embodiment. The organic film according to the present embodiment can be produced easily from the above-described solution as described above.

The organic film according to the present embodiment can be suitably used as a light emitting layer in an organic light emitting device described later. The organic film according to the present embodiment can be suitably used also in an organic semiconductor device. Since the organic film according to the present embodiment contains the above-described polymer compound, if it is used as a light emitting layer of an organic light emitting device, the light emission efficiency of the organic light emitting device is very excellent.

### <Organic Semiconductor Device>

The organic semiconductor device according to the present embodiment has the above-described organic film. As the organic semiconductor device, organic film solar batteries and field effect organic transistors are exemplified, and for production thereof, the polymer compound and the organic film according to the present embodiment can be suitably used. Specifically, a field effect organic transistor can be fabricated by forming the above-described organic film on a Si substrate on which an insulation film made of SiO₂ and the like and a gate electrode have been formed, and forming a source electrode and a drain electrode with Au and the like.

### <Organic Light Emitting Device>

The organic light emitting device according to the present embodiment has the above-described organic film. In typical examples of the organic light emitting device according to the present embodiment, the organic light emitting device has an anode and a cathode, and a layer containing the above-described polymer compound disposed between the anode and the cathode. Here, the layer containing the polymer compound is preferably a layer composed of the above-described organic film, and it is preferable that this layer functions as a light emitting layer. Cases in which the layer containing the polymer compound functions as a light emitting layer will be exemplified as preferable embodiments, below.

The constitution of the organic light emitting device according to the present embodiment includes structures of the following (a) to (d). “/” means that layers around this are adjacently laminated (for example, “anode/light emitting layer” indicates that an anode and a light emitting layer are adjacently laminated.).

(a) anode/light emitting layer/cathode
(b) anode/hole transporting layer/light emitting layer/cathode
(c) anode/light emitting layer/electron transporting layer/cathode
(d) anode/hole transporting layer/light emitting layer/electron transporting layer/cathode

Here, the light emitting layer is a layer having a function of emitting light, the hole transporting layer is a layer having a function of transporting holes, and the electron transporting layer is a layer having a function of transporting electrons. The hole transporting layer and the electron transporting layer are collectively called a charge transporting layer in some cases. The hole transporting layer adjacent to the light emitting layer is called an interlayer layer in some cases.

Lamination and film formation of each layer can be carried out using a solution containing constituent components of the layer. For lamination and film formation from a solution, use can be made of coating methods such as a spin coat method, a casting method, a microgravure coat method, a gravure coat method, a bar coat method, a roll coat method, a wire bar coat method, a dip coat method, a slit coat method, a capillary coat method, a spray coat method, a screen printing method, a flexo printing method, an offset printing method, an inkjet print method, a nozzle coat method and the like.

The thickness of the light emitting layer may be advantageously selected so that the driving voltage and the light emission efficiency show suitable values, and is usually 1 nm to 1 μm, preferably 2 nm to 500 nm, further preferably 5 nm to 200 nm.

It is preferable that the hole transporting layer contains the hole transporting material described above. When the hole transporting material is a polymer compound, it is preferable that the hole transporting layer is film-formed from a solution containing the hole transporting material, and when the hole transporting material is a low molecular weight compound, it is preferable that the hole transporting layer is film-formed from a mixed solution containing a polymer binder and the hole transporting material. As the film formation method, the same methods as the above-described coating method can be used.

It is preferable that the above-described polymer binder does not extremely disturb charge transportation and shows no strong absorption against visible light. The polymer binder includes polycarbonate, polyacrylate, polymethyl acrylate, polymethyl methacrylate, polystyrene, polyvinyl chloride, polysiloxane and the like.

The thickness of the hole transporting layer may advantageously be selected so that the driving voltage and the light emission efficiency show suitable values, and is usually 1 nm to 1 μm, preferably 2 nm to 500 nm, further preferably 5 nm to 200 nm.

It is preferable that the electron transporting layer contains the electron transporting material described above. When the electron transporting material is a polymer compound, a method of film formation from a solution containing the electron transporting material, a method of melting the electron transporting material and forming a film with the melted material, and the like are preferable for film formation of the electron transporting layer. When the electron transporting material is a low molecular weight compound, a method of film formation by a vacuum vapor deposition method using a powder of the electron transporting material, a method of film formation from a solution containing the electron transporting material, a method of melting the electron transporting material and forming a film with the melted material, and the like are preferable. As the method of film formation from a solution containing the electron transporting material, the same methods as the above-described coating method are exemplified. The solution may contain a polymer binder.

It is preferable that the above-described polymer binder does not extremely disturb charge transportation and shows no strong absorption against visible light. The polymer binder includes poly(N-vinylcarbazole), polyaniline and derivatives thereof, polythiophene and derivatives thereof, poly(p-phenylenevinylene) and derivatives thereof, poly(2,5-thienylenevinylene) and derivatives thereof, polycarbonate, polyacrylate, polymethyl acrylate, polymethyl methacrylate, polystyrene, polyvinyl chloride, polysiloxane and the like.

The thickness of the electron transporting layer may advantageously be selected so that the driving voltage and the light emission efficiency show suitable values, and is usually 1 nm to 1 μm, preferably 2 nm to 500 nm, further preferably 5 nm to 200 nm.

Among charge transporting layers disposed adjacent to an electrode, those having a function of improving charge injection efficiency from an electrode and having an effect of lowering the driving voltage of a device are called particularly a charge injection layer (hole injection layer, electron injection layer) in some cases. For enhancing adherence with an electrode and for improving charge injection from an electrode, the above-described charge injection layer or insulating layer may be disposed adjacent to an electrode, and for enhancing adherence of an interface and for prevention mixing thereof, a thin buffer layer may be inserted into an interface of a charge transporting layer and a light emitting layer. The order and number of layers to be laminated and the thickness of each layer may advantageously be selected in view of light emission efficiency and device life.

The organic light emitting device having a charge injection layer includes those having structures of the following (e) to (p).

(e) anode/charge injection layer/light emitting layer/cathode
(f) anode/light emitting layer/charge injection layer/cathode
(g) anode/charge injection layer/light emitting layer/charge injection layer/cathode
(h) anode/charge injection layer/hole transporting layer/light emitting layer/cathode
(i) anode/hole transporting layer/light emitting layer/charge injection layer/cathode
(j) anode/charge injection layer/hole transporting layer/light emitting layer/charge injection layer/cathode
(k) anode/charge injection layer/light emitting layer/charge transporting layer/cathode
(l) anode/light emitting layer/electron transporting layer/charge injection layer/cathode
(m) anode/charge injection layer/light emitting layer/electron transporting layer/charge injection layer/cathode
(n) anode/charge injection layer/hole transporting layer/light emitting layer/charge transporting layer/cathode
(o) anode/hole transporting layer/light emitting layer/electron transporting layer/charge injection layer/cathode
(p) anode/charge injection layer/hole transporting layer/light emitting layer/electron transporting layer/charge injection layer/cathode

The charge injection layer includes

(I) a layer containing an electrically conductive polymer,

(II) a layer disposed between an anode and a hole transporting layer and containing a material having ionization potential of a value between that of an anode material in an anode and that of a hole transporting material in a hole transporting layer,

(III) a layer disposed between a cathode and an electron transporting layer and containing a material having electron affinity of a value between that of a cathode material in a cathode and that of an electron transporting material in an electron transporting layer,

and the like.

When the charge injection layer is (I) a layer containing an electrically conductive polymer, the electric conductivity of the electrically conductive polymer is preferably 10⁻⁵ S/cm to 10³ S/cm, more preferably 10⁻⁵ S/cm to 10² S/cm, particularly preferably 10⁻⁵ S/cm to 10¹ S/cm, since then leak current between light emitting picture elements is smaller. For satisfying this range, the electrically conductive polymer may be doped with a suitable amount of ions.

The kind of the ion to be doped is an anion in the case of a hole injection layer and is a cation in the case of an electron injection layer.

The anion includes a polystyrenesulfonate ion, an alkylbenzenesulfonate ion, a camphorsulfonate ion and the like.

The cation includes a lithium ion, a sodium ion, a potassium ion, a tetrabutylammonium ion and the like.

The thickness of the charge injection layer is preferably 1 to 100 nm, more preferably 2 to 50 nm.

The electrically conductive polymer may be advantageously selected depending on the relation with the material of an electrode and an adjacent layer, and includes electrically conductive polymers such as polyaniline and derivatives thereof, polythiophene and derivatives thereof, polypyrrole and derivatives thereof, polyphenylenevinylene and derivatives thereof, polythienylenevinylene and derivatives thereof, polyquinoline and derivatives thereof, polyquinoxaline and derivatives thereof, polymers containing an aromatic amine structure in the main chain or side chain, and the like. The charge injection layer includes also layers containing metal phthalocyanines (copper phthalocyanine and the like), carbon and the like.

The insulating layer has a function of facilitating charge injection. The thickness of this insulating layer is usually 0.1 to 20 nm, preferably 0.5 to 10 nm, more preferably 1 to 5 nm. The material used for the insulating layer includes metal fluorides, metal oxides, organic insulation materials and the like.

The organic light emitting device having the insulating layer includes those having structures of the following (q) to (ab).

(q) anode/insulating layer/light emitting layer/cathode
(r) anode/light emitting layer/insulating layer/cathode
(s) anode/insulating layer/light emitting layer/insulating layer/cathode
(t) anode/insulating layer/hole transporting layer/light emitting layer/cathode
(u) anode/hole transporting layer/light emitting layer/insulating layer/cathode
(v) anode/insulating layer/hole transporting layer/light emitting layer/insulating layer/cathode
(w) anode/insulating layer/light emitting layer/electron transporting layer/cathode
(x) anode/light emitting layer/electron transporting layer/insulating layer/cathode
(y) anode/insulating layer/light emitting layer/electron transporting layer/insulating layer/cathode
(z) anode/insulating layer/hole transporting layer/light emitting layer/electron transporting layer/cathode
(aa) anode/hole transporting layer/light emitting layer/electron transporting layer/insulating layer/cathode
(ab) anode/insulating layer/hole transporting layer/light emitting layer/electron transporting layer/insulating layer/cathode

It is preferable that the organic light emitting device according to the present embodiment has a substrate adjacent to an anode or a cathode. As the substrate, those showing no change of shape and characteristics in fabricating an electrode and layers are preferable, and substrates made of glass, plastics, polymer films, silicon and the like are listed. In the case of an opaque substrate, it is preferable that the opposite electrode to an electrode in contact with the substrate is transparent or semi-transparent.

In the organic light emitting device according to the present embodiment, it is preferable that usually at least one of electrodes consisting of an anode and a cathode is transparent or semi-transparent and an anode is transparent or semi-transparent.

As the anode material, electrically conductive metal oxide films, semi-transparent metal films, and the like are used. Specifically, films fabricated by using an electrically conductive inorganic compound such as indium oxide, zinc oxide, tin oxide, a composite oxide composed of indium•tin•oxide (ITO), a composite oxide composed of indium•zinc•oxide and the like; NESA and the like; and additionally, gold, platinum, silver, copper and the like are used. As the anode, organic transparent conductive films composed of polyaniline and derivatives thereof, polythiophene and derivatives thereof and the like may be used. For facilitating charge injection, a layer composed of a phthalocyanine derivative, an electrically conductive polymer, carbon and the like or a layer composed of a metal oxide, a metal fluoride, an organic insulation material and the like may also be provided on the anode.

As the anode fabrication method, a vacuum vapor deposition method, a sputtering method, an ion plating method, a plating method and the like are listed.

The thickness of the anode may be advantageously selected in view of light permeability and electric conductivity, and is usually 10 nm to 10 μm, preferably 20 nm to 1 μm, further preferably 40 nm to 500 nm.

As the material of the cathode, materials having a small work function are preferable and metals such as lithium, sodium, potassium, rubidium, cesium, beryllium, magnesium, calcium, strontium, barium, aluminum, scandium, vanadium, zinc, yttrium, indium, cerium, samarium, europium, terbium, ytterbium and the like, alloys containing two or more of the above-described metals, alloys containing at least one of the above-described metals and at least one of gold, silver, platinum, copper, manganese, titanium, cobalt, nickel, tungsten and tin, graphite or graphite intercalation compounds, and the like are used.

As the cathode fabrication method, a vacuum vapor deposition method, a sputtering method, a lamination method of thermally compression-bonding a metal film, and the like are used.

The thickness of the cathode may advantageously be selected in view of electric conductivity and durability, and is usually 10 nm to 10 μm, preferably 20 nm to 1 μm, further preferably 50 nm to 500 nm.

A layer composed of an electrically conductive polymer or a layer composed of a metal oxide, a metal fluoride, an organic insulation material and the like may be disposed between a cathode and a light emitting layer or a cathode and an electron transporting layer, and a protective layer for protecting an organic light emitting device may be mounted after fabrication of a cathode. For use of an organic light emitting device stably for a long period of time, it is preferable to mount a protective layer and/or a protective cover for the purpose of protecting a device from exterior environments.

For the protective layer, resins, metal oxides, metal fluorides, metal borides and the like can be used. As the protective cover, use can be made of a glass plate, a plastic plate having a surface on which a treatment of lowering hydraulic permeability has been performed, and the like, and a method of pasting the protective cover to a device substrate with a thermo-setting resin or a photo-curable resin to attain sealing is preferably used. When a space is maintained using a spacer, blemishing of a device can be prevented easily. If an inert gas such as nitrogen, argon and the like is filled in this space, oxidation of a cathode can be prevented, and further, by placing a desiccant such as barium oxide and the like in the space, it becomes easy to suppress moisture adsorbed in a production process from imparting damages to the device.

An organic light emitting device containing the polymer compound according to the present embodiment or the high molecular weight composition according to the present embodiment is useful also as surface light sources such as a curved light source, a flat light source and the like (for example, illumination); displays such as segment displays (for example, segment type display), dot matrix displays (for example, dot matrix flat display), liquid crystal displays (for example, liquid crystal display, backlight of liquid crystal display) and the like; dyes for laser, materials of organic solar batteries, materials for conductive films such as organic semiconductors for organic transistors, electrically conductive films, organic semiconductor films and the like, materials of luminous films emitting fluorescence, materials of field effect transistors, and the like.

For obtaining surface light emission using the organic light emitting device according to the present embodiment, a planar anode and a planar cathode may advantageously be placed so as to overlap. For obtaining light emission in the form of pattern, there are a method in which a mask having a window in the form of pattern is placed on the surface of the above-described planar organic light emitting device, and a method in which either an anode or a cathode, or both electrodes are formed in the form of pattern. By forming a pattern by any of these methods, and placing several electrodes so that on/off is independently possible, a display of segment type is obtained which can display digits, letters, simple marks and the like. For providing a dot matrix device, it may be advantageous that both an anode and a cathode are formed in the form of stripe, and placed so as to cross. By using a method in which several polymer compounds showing different emission colors are painted separately or a method in which a color filter or a fluorescence conversion filter is used, partial color display and multi-color display are made possible. In the case of a dot matrix device, passive driving is possible, and active driving may also be carried out in combination with TFT and the like. These display devices can be used as a display of a computer, a television, a portable terminal, a cellular telephone, a car navigation, a view finder of a video camera, and the like.

### EXAMPLES

The present invention will be illustrated further in detail by examples below, but the present invention is not limited to them.

The polystyrene-equivalent number-average molecular weight and weight-average molecular weight of the polymer compound were measured by using size exclusion chromatography (SEC) (manufactured by Shimadzu Corp.: LC-10Avp) under the following measurement conditions.

### [Measurement Conditions]

The polymer compound to be measured was dissolved in tetrahydrofuran so as to give a concentration of about 0.05% by weight, and injected in an amount of 10 μL into SEC. As the mobile phase of SEC, tetrahydrofuran was used and allowed to flow at a flow rate of 2.0 mL/min. As the column, PLgel MIXED-B (manufactured by Polymer Laboratories) was used. As the detector, UV-VIS detector (manufactured by Shimadzu Corp.: SPD-10Avp) was used.

Unless otherwise stated, 5 to 20 mg of a measurement sample was dissolved in about 0.5 mL of deuterated chloroform, and NMR measurement was carried out using NMR (manufactured by Varian, Inc., trade name: MERCURY 300).

### (High Performance Liquid Chromatography (HPLC))

As the index for the purity of a compound, the value of the HPLC area percentage was used. This value is a value at 254 nm by high performance liquid chromatography (HPLC, manufactured by Shimadzu Corp., trade name: LC-20A), unless otherwise state. In this procedure, the compound to be measured was dissolved in tetrahydrofuran or chloroform so as to give a concentration of 0.01 to 0.2% by weight, and injected in an amount of 1 to 10 μL depending on the concentration into HPLC. As the mobile phase of HPLC, acetonitrile and tetrahydrofuran were used, and allowed to flow in gradient analysis of acetonitrile/tetrahydrofuran=100/0 to 0/100 (volume ratio) at a flow rate of 1 mL/minute. As the column, Kaseisorb LC ODS 2000 (manufactured by Tokyo Chemical Industry Co., Ltd.) was used. As the detector, Photo Diode Array detector (manufactured by Shimadzu Corp., trade name: SPD-M20A) was used.

### (Measurement of Glass Transition Temperature)

Measurement of glass transition temperature was carried out by DSC (manufactured by TA Instruments, trade name: DSC2920). Each polymer compound (sample, copolymer and polymer) was heated up to 200° C., then, quenched down to −50° C. and kept for 30 minutes. After raising temperature up to 30° C., measurement thereof was carried out at a temperature rising rate of 10° C. per minute until 300° C.

### Synthesis Example 1

### Synthesis of Mixture of 3,10-dibromoperylene (Compound CM1a) and 3,9-dibromoperylene (Compound CM1b)

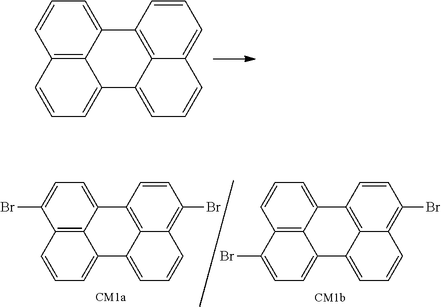

Under a nitrogen gas atmosphere, perylene (Manufactured by Aldrich, sublimation-purified grade, >99.5% product) (25.23 g, 100 mmol) and nitrobenzene (800 ml) were mixed in a 1000 ml flask, then, the mixture was heated at 125° C. and the whole amount of perylene was dissolved in nitrobenzene. Thereafter, a solution prepared by diluting bromine (32.9 g, 206 mmol) with nitrobenzene (85 ml) was dropped into this over a period of 1 hour under light shielding. After completion of dropping, the reaction solution was stirred at the same temperature for 5 hours, then, cooled down to room temperature.

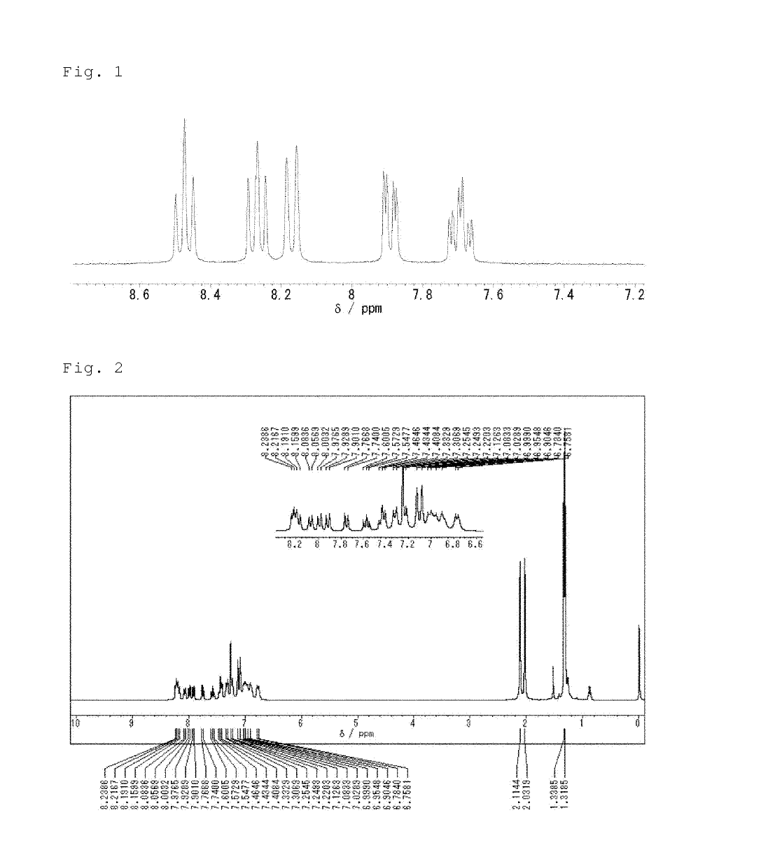

Next, the content (deposited solid and solution) in the 1000 ml flask was transferred into a separately prepared 2000 ml flask, methanol (500 ml) was added to this while stirring, the mixture was filtrated under reduced pressure, washed with methanol (1000 ml) and dried while reducing pressure, to obtain a yellow crystal (37.9 g). To this was added xylene (1350 ml), and the mixture was stirred for 5 hours under reflux with heating. The mixture was cooled down to room temperature, filtrated under reduced pressure, washed with methanol (four times with 100 ml) and dried while reducing pressure, to obtain a yellow crystal (30.2 g). Again, to this was added xylene (1000 ml), and the mixture was stirred for 5 hours under reflux with heating. The resultant solution was cooled down to room temperature, filtrated under reduced pressure, washed with methanol (four time with 100 ml) and dried while reducing pressure, to obtain a yellow crystal (24.6 g). The purity calculated from the HPLC area percentage value was 99.82%. It was confirmed by ¹H-NMR analysis that this yellow crystal contained 3,10-dibromoperylene (compound CM1a) and 3,9-dibromoperylene (compound CM1b) at a molar ratio of about 50/50. The ¹H-NMR spectrum (300 MHz, THF-d₈) of the resultant yellow crystal is shown in FIG. 1.

### Example 1

### Synthesis of Mixture of Compound M1a and Compound M1b

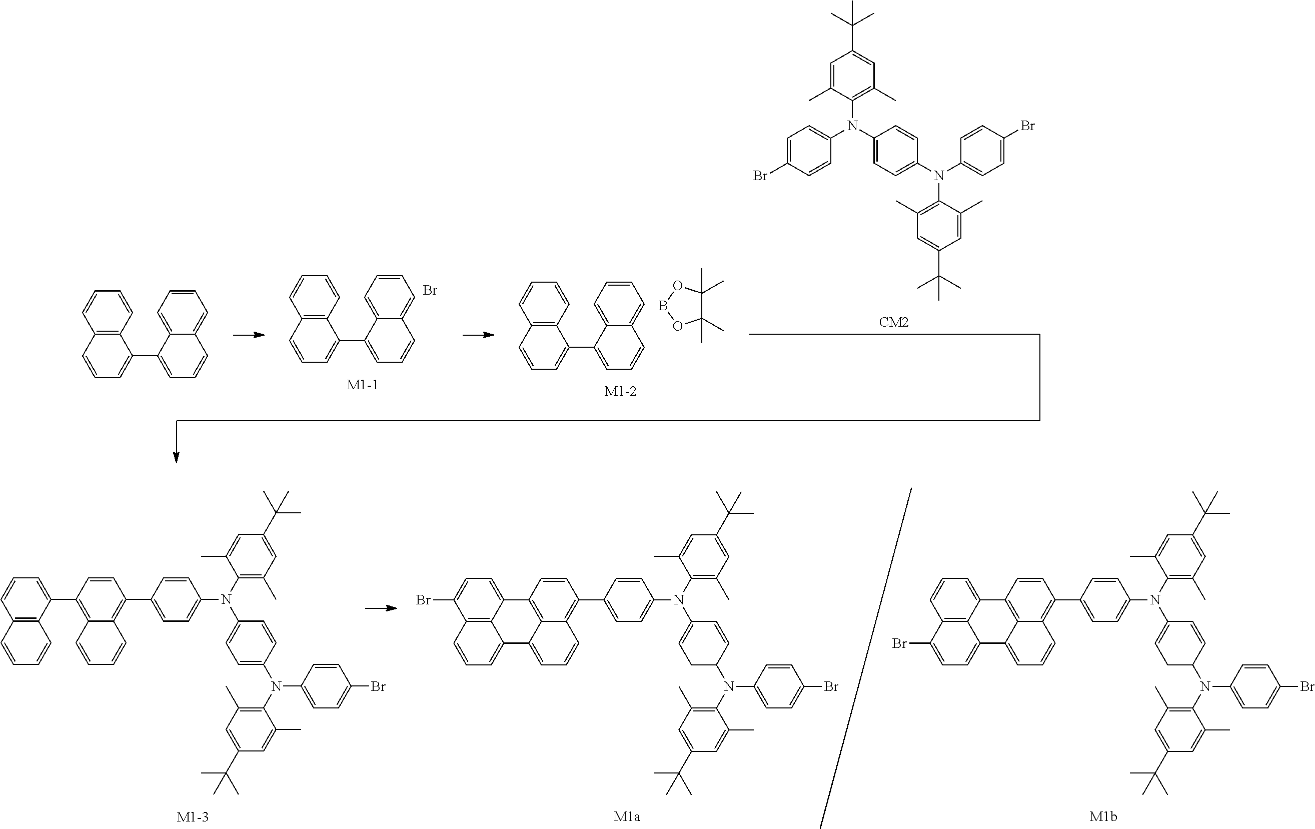

Under an argon gas atmosphere, perylene (manufactured by Aldrich, sublimation-purified grade, 7.57 g, 30 mmol) and N,N-dimethylformamide (1350 ml) were mixed in a 2000 ml flask, heated at 85° C. to cause completion dissolution thereof, then, the resultant perylenesolution was cooled down to room temperature. In this operation, deposition was not observed. Next, a solution prepared by dissolving N-bromosuccinimide (5.33 g, 30 mmol) in N,N-dimethylformamide (250 ml) was dropped into the above-described perylenesolution under light shielding over a period of 2 hours. After completion of dropping, the mixture was stirred for 4 hours at room temperature, then, the reaction solution was slowly added to methanol (3300 mL) to find deposition of a solid. This solid was filtrated, washed with methanol and dried while reducing pressure, to obtain 6.89 g of an orange powder. This orange powder was dissolved in toluene (276 ml) with heating, and cooled down to room temperature while stirring, to cause crystallization thereof. The deposited solid was filtrated, washed with hexane (276 ml) and dried while reducing pressure, to obtain an intermediate M1-1 (5.42 g) as an orange powder (yield 54.5%).

¹H-NMR (300 MHz, THF-d₈) δ (ppm)=8.37 (m, 3H), 8.18 (d, 1H), 8.08 (d, 1H), 7.82 (m, 1H), 7.73 (d, 2H), 7.62 (t, 1H), 7.50 (m, 2H).

Under an argon gas atmosphere, the intermediate M1-1 (5.30 g, 16 mmol), bis(pinacolato)diboron (7.11 g, 28 mmol), bis(diphenylphosphino)ferrocene (0.18 g, 0.32 mmol), potassium acetate (9.4 g, 96 mmol) and 1,4-dioxane (dehydrated product, 480 ml) were mixed in a 1000 ml flask, an argon gas was bubbled through the mixture, then, heated in an oil bath, and when the inner temperature of the 1000 ml flask reached 70° C., tris(dibenzylideneacetone)dipalladium(0) (0.15 g, 0.16 mmol) was added, and the mixture was stirred for 17 hours further with heating. The reaction solution was cooled down to room temperature, insoluble substances were removed by filtration through celite, the solution was concentrated and allowed to pass through a silica gel short column (30 g-SiO₂, 450 ml-chloroform), and the resultant solution was concentrated. Thereafter, chloroform (55 g) was added to obtain a solution, then, the solution was stirred well, then, methanol (200 ml) was added, find deposition of a solid. This solid was filtrated and dried while reducing pressure, to obtain 5.29 g of an orange solid. This orange solid was purified by medium pressure column chromatography (silica gel 1000 cc, hexane/chloroform=100/0 to 50/50) to obtain an intermediate M1-2 (3.33 g) with a yield of 55%. The purity calculated from the HPLC area percentage value was 81.3%, and in addition to this, it was confirmed from the HPLC area percentage value that 18.6% of perylene was contained.

¹H-NMR (300 MHz, THF-d₈) δ (ppm)=8.73 (d, 1H), 8.36 (d, 1H), 8.29 (t, 3H), 8.08 (d, 1H), 7.72 (t, 2H), 7.50 (m, 3H), 1.44 (s, 12H).

Under an argon gas atmosphere, N,N′-bis(4-bromophenyl)-N,N′-bis(2,6-dimethyl-4-tert-butylphenyl)-1,4-phenylenediamine (compound CM2, 1.477 g, 2.00 mmol) and toluene (dehydrated product, 20 ml) were mixed, an argon gas was bubbled through the mixture, then, bis(triphenylphosphine)dichloropalladium(II) (7 mg, 0.01 mmol) and a tetraethylammonium hydroxide aqueous solution (20% by weight, 3.7 g, 5 mmol) were added, and the mixture was heated and stirred for 30 minutes under reflux. Bis(triphenylphosphine)dichloropalladium (II) (7 mg, 0.01 mmol) was additionally added to the reaction solution. A solution prepared by dissolving a separately prepared intermediate M1-2 (0.467 g, 1.00 mmol) in toluene (dehydrated product, 20 ml) was dropped slowly into the reaction solution under reflux over a period of 2.5 porus. The reaction solution was cooled down to room temperature, then, diluted with toluene and tetrahydrofuran, and allowed to pass through a silica gel pad to remove insoluble substances. The filtrate was concentrated, then, chloroform (9 g) was added, and methanol (7.5 ml) was added under reflux with heating, and the mixture was cooled down to room temperature, to find deposition of a solid. This solid was filtrated, dissolved in toluene (25 g), and hexane (150 ml) was added to cause crystallization, obtaining a yellow solid (0.43 g). This yellow solid was dissolved in toluene (40 ml), allowed to pass through a silica gel short column, and re-crystallized from toluene-hexane, to obtain an intermediate M1-3 (0.42 g) with a yield of 46% as a yellow solid. The purity calculated from the HPLC area percentage value was 97.3%.

¹H-NMR (300 MHz, THF-d₈) δ (ppm)=8.30 (m, 4H), 7.89 (d, 1H), 7.70 (d, 2H), 7.46 (m, 4H), 7.36 (d, 2H), 7.24 (m, 6H), 7.03 (m, 4H), 6.95 (d, 2H), 6.79 (d, 2H), 2.14 (s, 6H), 2.07 (s, 6H), 1.36 (s, 9H), 1.34 (s, 9H).

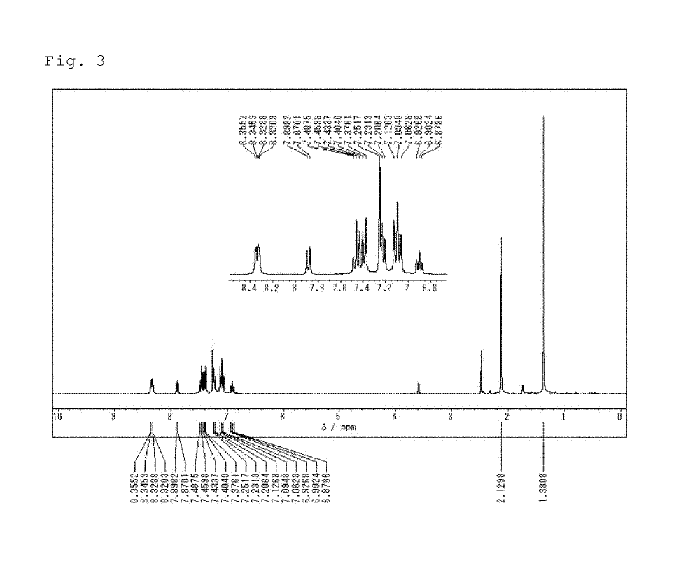

Under an argon gas atmosphere, the intermediate M1-3 (0.364 g, 0.40 mmol) and chloroform (30 ml) were mixed in a 50 ml flask, and after complete dissolution of the solid, the resultant solution was cooled down to 0° C. To this was added N-bromosuccinimide (0.071 g, 0.40 mmol) in the form of solid, the mixture was stirred for 4 hours at 0° C., then, the mixture was further stirred at room temperature for 2 hours. Since the reaction solution revealed stay of the intermediate M1-3, N-bromosuccinimide (4.3 mg) was added and the mixture was stirred at room temperature for 1 hour, and again, N-bromosuccinimide (4.3 mg) was added and the mixture was stirred at room temperature for 1 hour. To the reaction solution was added at 10 wt % sodium sulfite aqueous solution (5 g), and the mixture was allowed to cause separation while stirring, then, the resultant organic layer was washed with ion exchanged water twice and with saturated saline once, and dehydrated over sodium sulfate and concentrated. The concentrate was re-crystallized from chloroform (2 g)-methanol (50 ml), and the resultant crystal was taken out by filtration. To this crystal was added hexane (50 ml), the mixture was stirred well, then, a solid remaining without dissolution was taken out by filtration, and this operation was repeated twice, to obtain an orange solid (0.175 g). This solid was purified by medium pressure column chromatography (120 g-SiO₂, toluene), to obtain an orange solid (0.15 g, with a yield of 38%). The purity calculated from the HPLC area percentage value was 97.3%. It was confirmed by ¹H-NMR analysis that this orange solid was a mixture of the compound M1a and the compound M1b. The ¹H-NMR spectrum (300 MHz, CDCl₃) of this orange solid is shown in FIG. 2.

### Synthesis Example 2

### Synthesis of Mixture of Compound M2a and Compound M2b

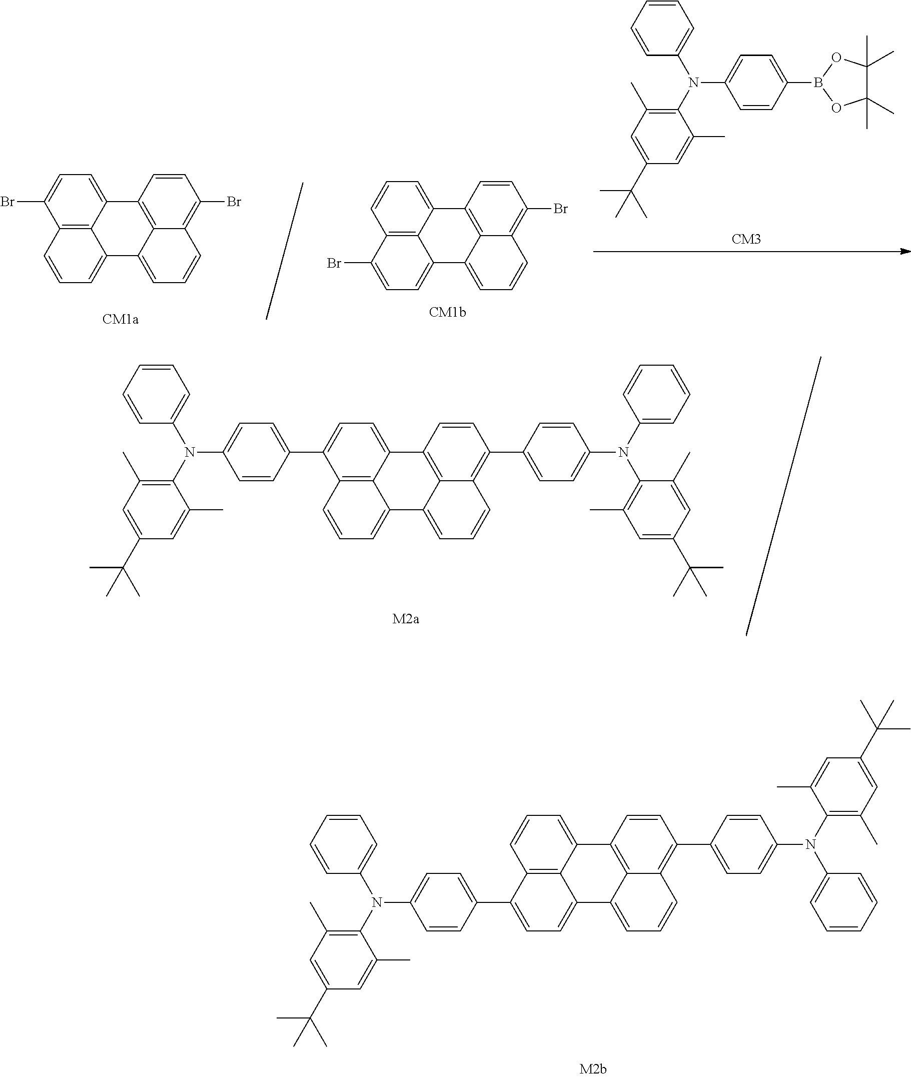

Under an argon gas atmosphere, the mixture of the compounds CM1a and CM1b synthesized in Synthesis Example 1 (1.025 g, 2.5 mmol), 4-(4, 4, 5, 5-tetramethyl-1,3,2-dioxaborolan-2-yl) phenyl-N-(4′-tert-butylphenyl)-N-phenylaniline (compound CM3, 2.334 g, 5.125 mmol) and dehydrated toluene (50 ml) were mixed in a 200 ml flask, then, the resultant solution was heated at 80° C., and to this was added bis(triphenylphosphine)dichloropalladium (35 mg, 0.05 mmol). Into the resultant solution, a tetraethylammonium hydroxide aqueous solution (20% by weight, 9.2 ml, 12.5 mmol) was dropped over a period of 10 minutes while heating at 100° C., then, the mixture was heated at 110° C., and stirred under reflux with heating for about 6 hours. After completion of the reaction, to this was added toluene (500 ml) and the mixture was cooled down to room temperature. The aqueous layer was removed from the reaction solution, then, washing with ion exchanged water (200 ml) was conducted twice, and the resultant organic layer was dried over anhydrous sodium sulfate (15 g), then, allowed to pass through a silica gel short column, and the solvent was distilled off by an evaporator, to obtain an orange solid. This solid was dissolved into toluene (about 30 ml) while heating, then, the solution was slowly added to methanol (180 ml) while cooling down to room temperature, to find deposition of a solid. This solid was filtrated and dried while reducing pressure, to obtain 2.06 g of an orange solid. This was purified by medium pressure silica gel column chromatography (120 g-SiO₂, chloroform), and re-crystallized (toluene-methanol), to obtain a yellow crystal (0.93 g, with a yield of 41%). The purity calculated from the HPLC area percentage value was 99.3%. It was confirmed from ¹H-NMR analysis that this yellow crystal was a mixture of the compound M2a and the compound M2b. The ¹H-NMR spectrum (300 MHz, THF-d₈) of this yellow crystal is shown in FIG. 3.

### Example 2

### Synthesis of Mixture of Compound M1a and Compound M3b

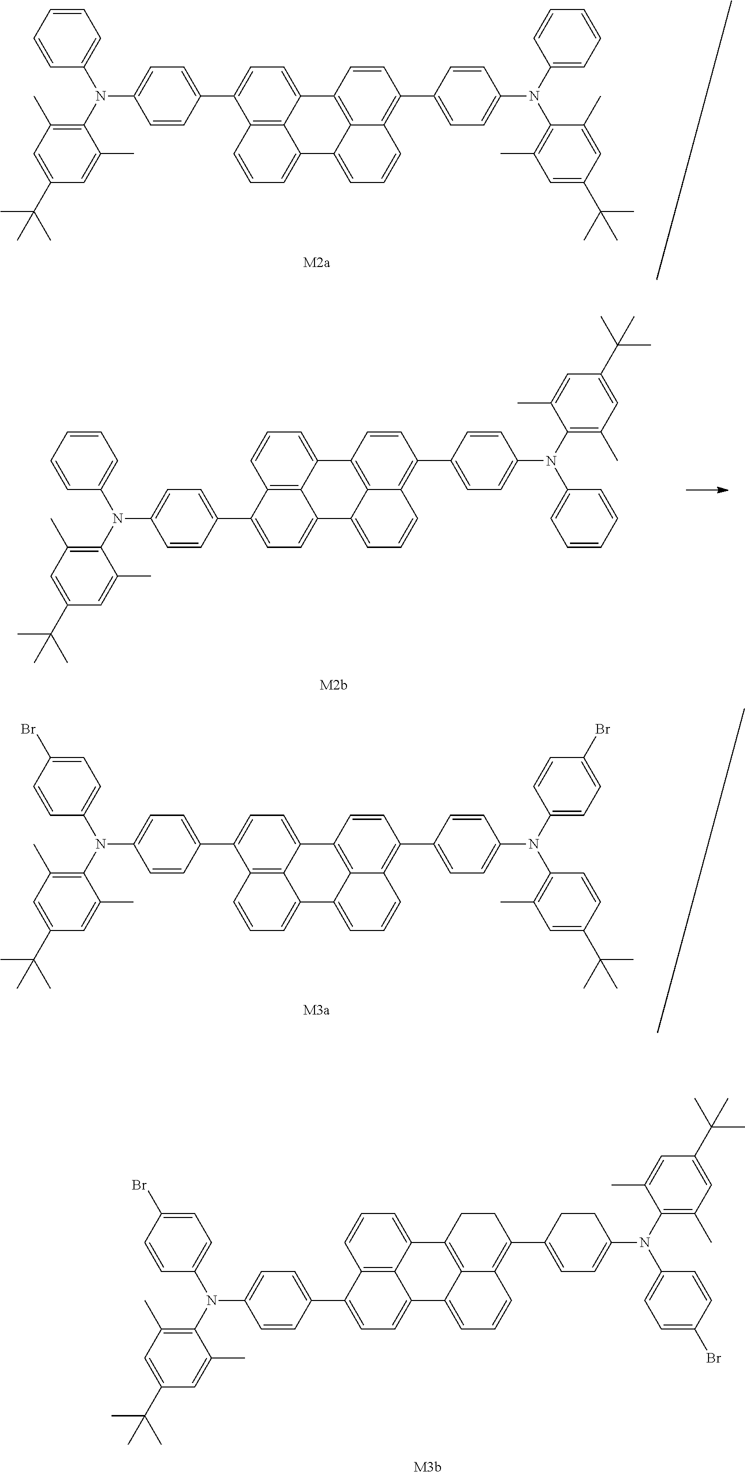

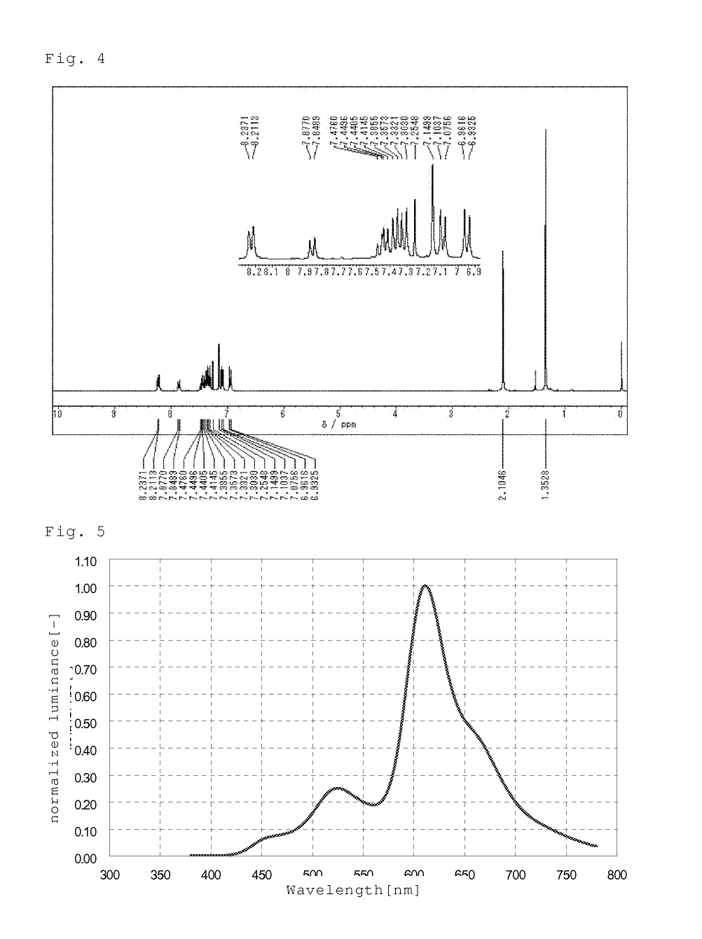

Under an argon gas atmosphere, the mixture of the compound M2a and the compound M2b synthesized in Synthesis Example 2 (0.771 g, 0.85 mmol) was dissolved in chloroform (25 ml) at room temperature in a 100 ml flask. To the resultant solution was added N-bromosuccinimide (0.303 g, 1.70 mmol), and the mixture was stirred for 4 hours at room temperature to cause reaction thereof. After completion of the reaction, the reaction solution was added to methanol (200 ml), to find deposition of a solid. This solid was filtrated, then, purified by medium pressure silica gel column chromatography (120 g-SiO₂, toluene), re-crystallized (toluene methanol), and further, dispersed with hexane three times and stirred and filtrated, and further re-crystallized (toluene-hexane), to obtain a yellow crystal (0.51 g, yield: 56%). The purity calculated from the ¹HPLC area percentage value was 99.4%. It was confirmed from ¹H-NMR analysis that this yellow crystal was a mixture of the compound Mia and the compound M3b. The ¹H-NMR spectrum (300 MHz, CDCl₂) of this yellow crystal is shown in FIG. 4.

### Example 3

### Synthesis of Polymer Compound P1

2,7-bis(4,4,5,5-tetramethyl-1,3,2-dioxaborolan-2-yl)-9,9-dioctylfluorene (0.4832 g, 0.75 mmol), 9,9-dioctyl-2,7-dibromofluorene (0.3813 g, 0.67 mmol), N,N′-bis(4-bromophenyl)-N,N′-bis(2,6-dimethyl-4-tert-butylphenyl)-1,4-phenylenediamine (0.0443 g, 0.06 mmol), the mixture of the compound M1a and the compound M1b synthesized in Example 1 (0.0149 g, 0.01 mmol) and toluene (16 mL) were mixed to prepare a monomer solution. Under a nitrogen gas atmosphere, the monomer solution was heated, bistriphenylphosphinepalladium dichloride (1.1 mg) was added, then, a 20 wt % tetraethylammonium hydroxide aqueous solution (2.5 mL) was dropped at 100° C. over a period of about 30 minutes. The mixture was stirred at 100° C. for 4 hours from initiation of dropping of the tetraethylammonium hydroxide aqueous solution. Next, to the resultant solution were added phenylboronic acid (9.3 mg), bistriphenylphosphinepalladium dichloride (1.1 mg) and a 20 wt %, tetraethylammonium hydroxide aqueous solution (2.5 mL), and the mixture was further stirred for 17 hours.

The aqueous layer was removed from the reaction solution, then, to this were added sodium N,N-diethyldithiocarbamate trihydrate (0.42 g) and ion exchanged water (8 mL) and the mixture was stirred at 85° C. for 2 hours. In the resultant solution, the organic layer was separated from the aqueous layer, then, the organic layer was washed with ion exchanged water (twice), with a 3 wt % acetic acid aqueous solution (twice) and with ion exchanged water (twice) in this order.

The organic layer was dropped into methanol, to find precipitation of a solid. This solid was filtrated, then, dried to obtain a solid. This solid was dissolved in toluene, the solution was allowed to pass through a silica gel/alumina column through which toluene had previously passed and the passed eluate was dropped into methanol, to find precipitation of a solid. This solid was filtrated, then, dried. This solid (hereinafter, referred to as “polymer compound P1”) showed a yield of 0.517 g. The polymer compound P1 had a polystyrene-equivalent number-average molecular weight of 1.1×10⁵, a polystyrene-equivalent weight-average molecular weight of 3.6×10⁵ and a glass transition temperature Tg of 82° C.

It is guessed from the structures and charging ratios of raw materials that the polymer compound P1 is a polymer composed of constitutional units having structures and ratios (molar ratio) shown in Table 8.

TABLE 8

| | first constitutional unit | second constitutional unit |
|---|---|---|
| structure | 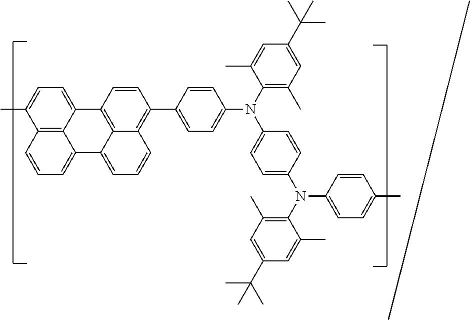 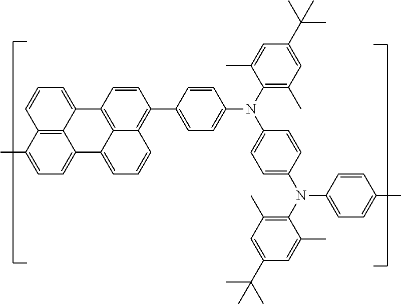 | 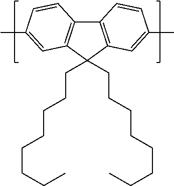 |
| ratio | 1 | 95 |
| (% by mol) | | |

| | third constitutional unit |
|---|---|
| structure | 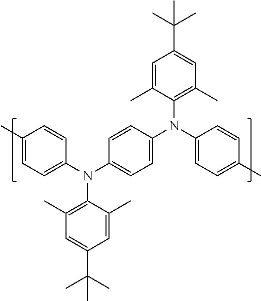 |
| ratio | 4 |
| (% by mol) | |

### Example 4

### Synthesis of Polymer Compound P2

2,7-bis(4,4,5,5-tetramethyl-1,3,2-dioxaborolan-2-yl)-9,9-dioctylfluorene (0.4715 g, 0.73 mmol), 9,9-dioctyl-2,7-dibromofluorene (0.3721 g, 0.66 mmol), the mixture of the compound M1a and the compound M1b synthesized in Example 1 (0.0733 g, 0.07 mmol) and toluene (16 mL) were mixed to prepare a monomer solution. Under a nitrogen gas atmosphere, the monomer solution was heated, bistriphenylphosphinepalladium dichloride (1.0 mg) was added, then, a 20 wt % tetraethylammonium hydroxide aqueous solution (2.5 mL) was dropped at 100° C. over a period of about 30 minutes. The mixture was stirred at 100° C. for 4 hours from initiation of dropping of the tetraethylammonium hydroxide aqueous solution. Next, to the resultant solution were additionally added phenylboronic acid (9.0 mg), bistriphenylphosphinepalladium dichloride (1.0 mg) and a 20 wt % tetraethylammonium hydroxide aqueous solution (2.5 mL) and the mixture was further stirred for 17 hours.

The aqueous layer was removed from the reaction solution, then, sodium N,N-diethyldithiocarbamate trihydrate (0.41 g) and ion exchanged water (8 mL) were added and the mixture was stirred at 85° C. for 2 hours. In the resultant solution, the organic layer was separated from the aqueous layer, then, the organic layer was washed with ion exchanged water (twice), with a 3 wt % acetic acid aqueous solution (twice) and with ion exchanged water (twice) in this order.

The organic layer was dropped into methanol, to find precipitation of a solid. This solid was filtrated, then, dried to obtain a solid. This solid was dissolved in toluene, the solution was allowed to pass through a silica gel/alumina column through which toluene had previously passed and the passed eluate was dropped into methanol, to find precipitation of a solid. This solid was filtrated, then, dried. This solid (hereinafter, referred to as “polymer compound P2”) showed a yield of 0.538 g. The polymer compound P2 had a polystyrene-equivalent number-average molecular weight of 1.2×10⁵, a polystyrene-equivalent weight-average molecular weight of 3.9×10⁵ and a glass transition temperature Tg of 95° C.

It is guessed from the structures and charging ratios of raw materials that the polymer compound P2 is a polymer composed of constitutional units having structures and ratios (molar ratios) shown in Table 9.

TABLE 9

| | first constitutional unit | second constitutional unit |
|---|---|---|
| structure | 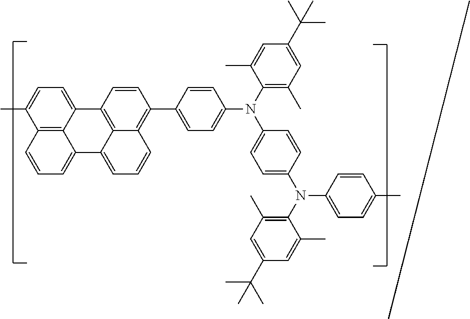 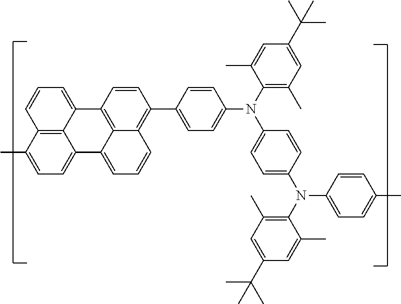 | 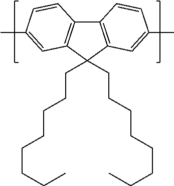 |
| ratio | 5 | 95 |
| (% by mol) | | |

### Example 5

### Synthesis of Polymer Compound P3

2,7-bis(4,4,5,5-tetramethyl-1,3,2-dioxaborolan-2-yl)-9,9-dioctylfluorene (1.6469 g, 2.55 mmol), 9,9-dioctyl-2,7-dibromofluorene (1.3285 g, 2.35 mmol), N,N-bis(4-bromophenyl)-N-(2,6-dimethyl-4-tert-butylphenyl)-amine (0.746 g, 0.15 mmol), the mixture of the compound Mia and the compound M3b synthesized in Example 2 (0.0566 g, 0.05 mmol) and toluene (44 mL) were mixed to prepare a monomer solution. Under a nitrogen gas atmosphere, this monomer solution was heated, to this was added bistriphenylphosphinepalladium dichloride (1.9 mg), then, a 20 wt % tetraethylammonium hydroxide aqueous solution (8.7 mL) was dropped at 100° C. over a period of about 60 minutes. The mixture was stirred at 100° C. for 5 hours from initiation of dropping of the tetraethylammonium hydroxide aqueous solution. Next, to the resultant solution were additionally added phenylboronic acid (31.5 mg), bistriphenylphosphinepalladium dichloride (1.9 mg) and a 20 wt % tetraethylammonium hydroxide aqueous solution (8.7 mL) and the mixture was further stirred for 17 hours.

The aqueous layer was removed from the reaction solution, then, to this were added sodium N,N-diethyldithiocarbamate trihydrate (1.42 g) and ion exchanged water (28 mL) and the mixture was stirred at 85° C. for 2 hours. In the resultant solution, the organic layer was separated from the aqueous layer, then, the organic layer was washed with ion exchanged water (twice), with a 3 wt % acetic acid aqueous solution (twice) and with ion exchanged water (twice) in this order.

The organic layer was dropped into methanol, to find precipitation of a solid. This solid was filtrated, then, dried to obtain a solid. This solid was dissolved in toluene, the solution was allowed to pass through a silica gel/alumina column through which toluene had previously passed and the passed eluate was dropped into methanol, to find precipitation of a solid. This solid was filtrated, then, dried. This solid (hereinafter, referred to as “polymer compound P3”) showed a yield of 1.854 g. The polymer compound P3 had a polystyrene-equivalent number-average molecular weight of 2.2×10⁵, a polystyrene-equivalent weight-average molecular weight of 7.2×10⁵ and a glass transition temperature Tg of 86° C.

It is guessed from the structures and charging ratios of raw materials that the polymer compound P3 is a polymer composed of constitutional units having structures and ratios (molar ratios) shown in Table 10.

TABLE 10

| | first constitutional unit | second constitutional unit |
|---|---|---|
| structure | 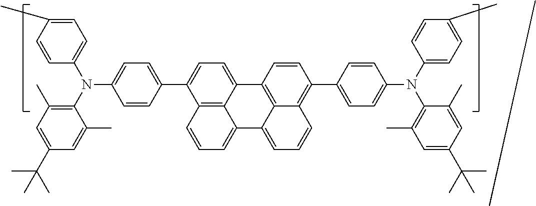 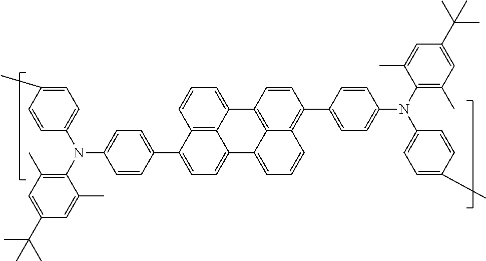 | 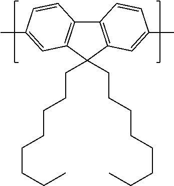 |
| ratio | 1 | 96 |
| (% by mol) | | |

| | third constitutional unit |
|---|---|
| structure | 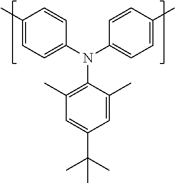 |
| ratio | 3 |
| (% by mol) | |

### Example 6

### Synthesis of Polymer Compound P4

2,7-bis(4,4,5,5-tetramethyl-1,3,2-dioxaborolan-2-yl)-9,9-dioctylfluorene (1.2056 g, 1.87 mmol), 9,9-dioctyl-2,7-dibromofluorene (1.0043 g, 1.77 mmol), the mixture of the compound Mia and the compound M3b synthesized in Example 3 (0.1035 g, 0.09 mmol) and toluene (39 mL) were mixed to prepare a monomer solution. Under a nitrogen gas atmosphere, this monomer solution was heated, bistriphenylphosphinepalladium dichloride (1.3 mg) was added, then, a 20 wt % tetraethylammonium hydroxide aqueous solution (6.3 mL) was dropped at 100° C. over a period of about 60 minutes. The mixture was stirred at 100° C. for 5 hours from initiation of base dropping of the tetraethylammonium hydroxide aqueous solution. Next, to the resultant solution were additionally added phenylboronic acid (23 mg), bistriphenylphosphinepalladium dichloride (1.3 mg) and a 20 wt % tetraethylammonium hydroxide aqueous solution (6.3 mL) and the mixture was further stirred for 18 hours.

The aqueous layer was removed from the reaction solution, then, sodium N,N-diethyldithiocarbamate trihydrate (1.04 g) and ion exchanged water (21 mL) were added and the mixture was stirred at 85° C. for 2 hours. In the resultant solution, the organic layer was separated from the aqueous layer, then, the organic layer was washed with ion exchanged water (twice), with a 3 wt % acetic acid aqueous solution (twice) and with ion exchanged water (twice) in this order.

The organic layer was dropped into methanol, to find precipitation of a solid. This solid was filtrated, then, dried to obtain a solid. This solid was dissolved in toluene, the solution was allowed to pass through a silica gel/alumina column through which toluene had previously passed and the passed eluate was dropped into methanol, to find precipitation of a solid. This solid was filtrated, then, dried. This solid (hereinafter, referred to as “polymer compound P4”) showed a yield of 1.367 g. The polymer compound P4 had a polystyrene-equivalent number-average molecular weight of 1.8×10⁵, a polystyrene-equivalent weight-average molecular weight of 5.3×10⁵ and a glass transition temperature Tg of 86° C.

It is guessed from the structures and charging ratios of raw materials that the polymer compound P4 is a polymer composed of constitutional units having structures and ratios (molar ratios) shown in Table 11.

TABLE 11

| | first constitutional unit | second constitutional unit |
|---|---|---|
| structure | 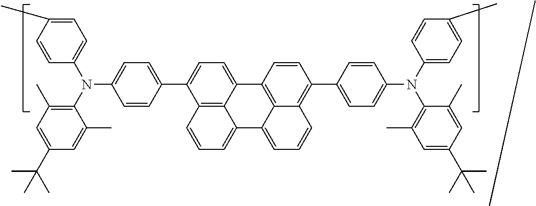 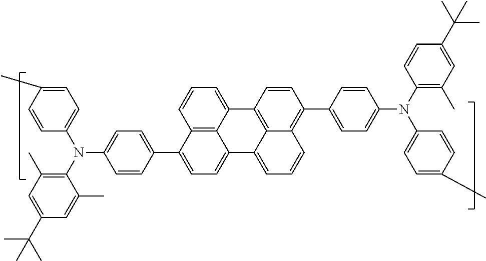 | 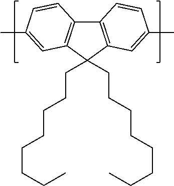 |
| ratio | 2.5 | 97.5 |
| (% by mol) | | |

### Synthesis Example 3

### Synthesis of Polymer Compound CP1

Under a nitrogen gas atmosphere, 2,7-bis(1,3,2-dioxaborolan-2-yl)-9,9-dioctylfluorene (5.20 g, 9.80 mmol), N,N-bis(4-bromophenyl)-N-(4-sec-butylphenyl)-amine (4.50 g, 9.80 mmol), palladium acetate (2.2 mg), tris(2-methylphenyl)phosphine (15.1 mg), trioctylmethylammonium chloride (trade name: Aliquat (registered trademark) 336, manufactured by Aldrich) (0.91 g) and toluene (70 mL) were mixed and the mixture was heated at 105° C. Into the resultant solution, a 2M sodium carbonate aqueous solution (19 mL) was dropped, and the mixture was refluxed for 4 hours. Thereafter, to this was added phenylboronic acid (121 mg), and the mixture was further refluxed for 3 hours. Next, a sodium diethyldithiacarbamate aqueous solution was added, and the mixture was stirred at 80° C. for 4 hours. After cooling, the mixture was washed with water (60 mL) three times, with a 3 wt % acetic acid aqueous solution (60 ml) three times and with water (60 mL) three times, and purified by passing through an alumina column and a silica gel column sequentially. The resultant toluene solution was dropped into methanol (3000 mL), the mixture was stirred for 3 hours, then, the resultant solid was taken out and dried. This solid (hereinafter, referred to as “polymer compound CP1”) showed a yield of 5.25 g. The polymer compound CP1 had a polystyrene-equivalent number-average molecular weight of 8.1×10⁴ and a polystyrene-equivalent weight-average molecular weight of 3.4×10⁵.

It is estimated from the structures and charging ratios of raw materials that the polymer compound CP1 is an alternate polymer composed of constitutional units having structures and ratios (molar ratios) shown in Table 12.

TABLE 12

| | constitutional unit (1) | constitutional unit (2) |
|---|---|---|
| structure | 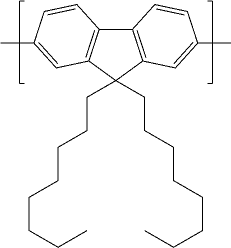 | 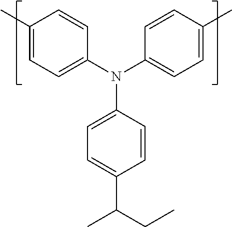 |
| ratio | 50 | 50 |
| (% by mol) | | |

### Synthesis Example 4

### Synthesis of Polymer Compound CP2

2,7-bis(4,4,5,5-tetramethyl-1,3,2-dioxaborolan-2-yl)-9,9-dioctylfluorene (2.267 g, 3.529 mmol), 9,9-dioctyl-2,7-dibromofluorene (1.703 g, 3.105 mmol), N,N′-bis(4-bromophenyl)-N,N′-bis(2,6-dimethyl-4-tert-butylphenyl)-1,4-phenylenediamine (0.261 g, 0.353 mmol), the mixture of the compound CM1a and the compound CMb1 synthesized in Synthesis Example 1 (0.029 g, 0.071 mmol) and toluene (61 mL) were mixed to prepare a monomer solution. Under a nitrogen gas atmosphere, this monomer solution was heated, bistriphenylphosphinepalladium dichloride (2.5 mg) was added, then, a 20 wt % tetraethylammonium hydroxide aqueous solution (12 mL) was dropped at 100° C. over a period of 60 minutes. The mixture was stirred at 100° C. for 4 hours from initiation of dropping of the tetraethylammonium hydroxide aqueous solution. Next, to the resultant solution were added phenylboronic acid (43.5 mg), bistriphenylphosphinepalladium dichloride (2.6 mg) and a 20 wt % tetraethylammonium hydroxide aqueous solution (12 mL), and the mixture was further stirred for 19.5 hours.

The aqueous layer was removed from the reaction solution, then, sodium N,N-diethyldithiocarbamate trihydrate (1.96 g) and ion exchanged water (39 mL) were added and the mixture was stirred at 85° C. for 2.5 hours. In the resultant solution, the organic layer was separated from the aqueous layer, then, the organic layer was washed with ion exchanged water (twice), with a 3 wt % acetic acid aqueous solution (twice) and with ion exchanged water (twice) in this order.

The organic layer was dropped into methanol, to find precipitation of a solid. This solid was filtrated, then, dried to obtain a solid. This solid was dissolved in toluene, the solution was allowed to pass through a silica gel/alumina column through which toluene had previously passed and the passed eluate was dropped into methanol, to find precipitation of a solid. This solid was filtrated, then, dried. This solid (hereinafter, referred to as “polymer compound CP2”) showed a yield of 2.578 g. The polymer compound CP2 had a polystyrene-equivalent number-average molecular weight of 2.0×10⁵, a polystyrene-equivalent weight-average molecular weight of 6.4×10⁵ and a glass transition temperature Tg of 85° C.

It is guessed from the structures and charging ratios of raw materials that the polymer compound CP2 is a polymer composed of constitutional units having structures and ratios (molar ratios) shown in Table 13.

TABLE 13

| | constitutional unit (1) | constitutional unit (2) | constitutional unit (3) |
|---|---|---|---|
| structure | 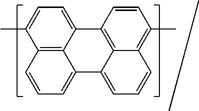 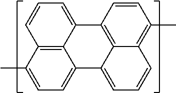 | 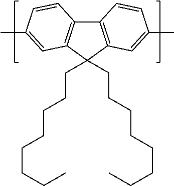 | 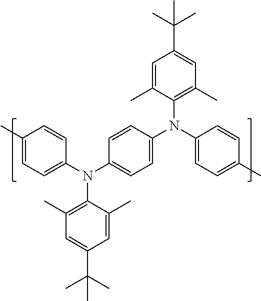 |
| ratio | 1 | 94 | 5 |
| (% by mol) | | | |

### Synthesis Example 5

### Synthesis of Polymer Compound CP3

2,7-bis(4,4,5,5-tetramethyl-1,3,2-dioxaborolan-2-yl)-9,9-dioctylfluorene (2.342 g, 3.644 mmol), 9,9-dioctyl-2,7-dibromofluorene (1.759 g, 3.207 mmol), N,N-bis(4-bromophenyl)-N-(2,6-dimethyl-4-tert-butylphenyl)-amine (0.178 g, 0.364 mmol), the mixture of the compound CM1a and the compound CMb1 synthesized in Synthesis Example 1 (0.030 g, 0.073 mmol) and toluene (61 mL) were mixed to prepare a monomer solution. Under a nitrogen gas atmosphere, this monomer solution was heated, bistriphenylphosphinepalladium dichloride (2.6 mg) was added, then, a 20 wt % tetraethylammonium hydroxide aqueous solution (12.4 mL) was dropped at 100° C. over a period of 60 minutes. The mixture was stirred at 100° C. for 4.5 hours from initiation of dropping of the tetraethylammonium hydroxide aqueous solution. Next, to the resultant solution were added phenylboronic acid (44.9 mg), bistriphenylphosphinepalladium dichloride (2.6 mg) and a 20 wt % tetraethylammonium hydroxide aqueous solution (12.4 mL), and the mixture was further stirred for 17.5 hours.

The aqueous layer was removed from the reaction solution, then, sodium N,N-diethyldithiocarbamate trihydrate (2.02 g) and ion exchanged water (40 mL) were added and the mixture was stirred at 85° C. for 2 hours. In the resultant solution, the organic layer was separated from the aqueous layer, then, the organic layer was washed with ion exchanged water (twice), with 3% by weight acetic acid aqueous solution (twice) and with ion exchanged water (twice) in this order.

The organic layer was dropped into methanol, to find precipitation of a solid. This solid was filtrated, then, dried to obtain a solid. This solid was dissolved in toluene, the solution was allowed to pass through a silica gel/alumina column through which toluene had previously passed and the passed eluate was dropped into methanol, to find precipitation of a solid. This solid was filtrated, then, dried. This solid (hereinafter, referred to as “polymer compound CP3”) showed a yield of 2.592 g. The polymer compound CP3 had a polystyrene-equivalent number-average molecular weight of 2.2×10⁵, a polystyrene-equivalent weight-average molecular weight of 6.8×10⁵ and a glass transition temperature Tg of 83° C.

It is guessed from the structures and charging ratios of raw materials that the polymer compound CP3 is a polymer composed of constitutional units having structures and ratios (molar ratios) shown in Table 14.

TABLE 14

| | constitutional unit (1) | constitutional unit (2) | constitutional unit (3) |
|---|---|---|---|
| structure | 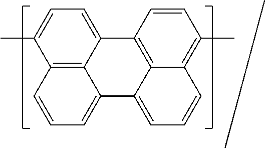 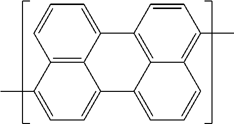 | 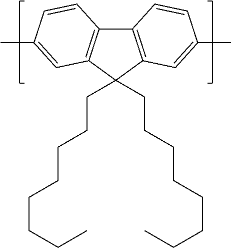 | 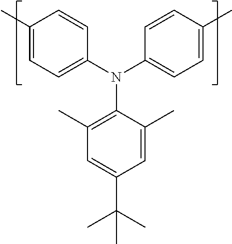 |
| ratio | 1 | 94 | 5 |
| (% by mol) | | | |

### Example 7

### Fabrication of Organic Light Emitting Device DP1

On a glass substrate carrying thereon an ITO film with a thickness of 45 nm formed by a sputtering method, a solution of poly(ethylenedioxythiophene)/polystyrenesulfonic acid (H. C. Starck, CL EVIOS P) was spin-coated to form a film with a thickness of about 65 nm, which was then dried on a hot plate at 200° C. for 10 minutes. Next, the polymer compound CP1 was dissolved in xylene (manufactured by Kanto Chemical Co., Inc., for electronic industry (EL grade)) at a concentration of 0.7% by weight. The resultant xylene solution was spin-coated on the above-described film to form a film of the polymer compound CP1 with a thickness of 20 nm, then, the film was dried at 180° C. for 60 minutes under a nitrogen atmosphere in which both the oxygen concentration and the moisture concentration were 10 ppm or less (by weight). Next, a 1.4 wt % xylene solution of the polymer compound P1 was prepared. This xylene solution was spin-coated to form a film with a thickness of about 80 nm on the film of the polymer compound CP1, then, the film was dried at 130° C. for 10 minutes under a nitrogen atmosphere in which both the oxygen concentration and the moisture concentration were 10 ppm or less (by weight), to give a light emitting layer. After pressure reduction to 1.0×10⁻⁴ Pa or less, barium was vapor-deposited with a thickness of about 5 nm on the film of the polymer compound P1, then, aluminum was vapor-deposited with a thickness of about 72 nm on the barium layer, as a cathode. After vapor deposition, it was sealed using a glass plate to fabricate an organic light emitting device (hereinafter, referred to as “organic light emitting device DP1”). A voltage was applied from 0 V to 12 Von the organic light emitting device DP1 using OLED TEST SYSTEM manufactured by Tokyo Systems Development Co., Ltd. to cause light emission of the device, and light-emission luminance, efficiency and chromaticity thereof were measured, to find that the driving voltage was 6.2 V, the light emission efficiency was 18.2 cd/A and the CIE chromaticity coordinate was (0.34, 0.61) at a luminance of 1000 cd/m², showing excellent green light emission. The initial luminance was set at 8000 cd/m² and the device was driven under constant current, to find that the time necessary for 50% reduction of luminance, that is, the luminance half life was 496 hours. These results are shown in Table 15.

### Example 8

### Fabrication of Organic Light Emitting Device DP2

An organic light emitting device was fabricated in the same manner as in Example 7, excepting that a 1.3 wt % xylene solution of the polymer compound P2 was used instead of the 1.4 wt % xylene solution of the polymer compound P1 (hereinafter, referred to as “organic light emitting device DP2”). For the organic light emitting device DP2, light-emission luminance, efficiency, voltage and chromaticity thereof were measured in the same manner as in Example 7, to find that the driving voltage was 6.2 V, the light emission efficiency was 15.5 cd/A and the CIE chromaticity coordinate was (0.38, 0.60) at a luminance of 1000 cd/m², showing excellent green light emission. The luminance half life at an initial luminance of 8000 cd/m² was 486 hours. These results are shown in Table 15.

### Comparative Example 1

### Fabrication of Organic Light Emitting Device DCP2

An organic light emitting device was fabricated in the same manner as in Example 7, excepting that a 1.1 wt % xylene solution of the polymer compound CP2 was used instead of the 1.4 wt % xylene solution of the polymer compound P1 (hereinafter, referred to as “organic light emitting device DCP2”). For the organic light emitting device DCP2, light-emission luminance, efficiency, voltage and chromaticity thereof were measured in the same manner as in Example 7, to find that the driving voltage was 7.1 V, the light emission efficiency was 13.7 cd/A and the CIE chromaticity coordinate was (0.25, 0.62) at a luminance of 1000 cd/m², showing excellent green light emission. The luminance half life at an initial luminance of 8000 cd/m² was 403 hours. These results are shown in Table 15.

TABLE 15

| | | At luminance of | | luminance |
|---|---|---|---|---|
| | | 1000 [cd/m²] | | half life |
| | | light emission | driving | [hr] at initial |
| | | efficiency | voltage | luminance of |
| | | [cd/A] | [V] | 8000 cd/m² |
| Example 7 | organic light | 18.2 | 6.2 | 496 |
| | emitting | | | |
| | device DPI | | | |
| Example 8 | organic light | 15.5 | 6.2 | 486 |
| | emitting | | | |
| | device DP2 | | | |
| Comparative | organic light | 13.7 | 7.1 | 403 |
| Example 1 | emitting | | | |
| | device DCP2 | | | |

The polymer compound P1 and the polymer compound P2 are polymer compounds having as the first constitutional unit a constitution chain directly linking the constitutional unit (1) and the constitutional unit (3) in the polymer compound CP2. As shown in Table 15, the organic light emitting device DP1 using the polymer compound P1 and the organic light emitting device DP2 using the polymer compound P2 are light emitting devices showing higher light emission efficiency, better luminance stability in driving, and lower driving voltage, owing to the presence of the first constitutional unit, as compared with the organic light emitting device DCP2 using the polymer compound CP2. Further, the organic light emitting device DP1 using the polymer compound P1 containing the third constitutional unit gave higher light emission efficiency as compared with the organic light emitting device DP2.

### Example 9

### Fabrication of Organic Light Emitting Device DP3

An organic light emitting device was fabricated in the same manner as in Example 7, excepting that a 1.0 wt % xylene solution of the polymer compound P3 was used instead of the 1.4 wt % xylene solution of the polymer compound P1 (hereinafter, referred to as “organic light emitting device DP3”). For the organic light emitting device DP3, light-emission luminance, efficiency, voltage and chromaticity thereof were measured in the same manner as in Example 7, to find that the driving voltage was 5.8 V, the light emission efficiency was 7.5 cd/A and the CIE chromaticity coordinate was (0.29, 0.64) at a luminance of 1000 cd/m², showing excellent green light emission. These results are shown in Table 16.

### Example 10

### Fabrication of Organic Light Emitting Device DP4

An organic light emitting device was fabricated in the same manner as in Example 7, excepting that a 1.2 wt % xylene solution of the polymer compound P4 was used instead of the 1.4 wt % xylene solution of the polymer compound P1 (hereinafter, referred to as “organic light emitting device DP4”). For the organic light emitting device DP4, light-emission luminance, efficiency, voltage and chromaticity thereof were measured in the same manner as in Example 7, to find that the driving voltage was 5.9 V, the light emission efficiency was 11.8 cd/A and the CIE chromaticity coordinate was (0.31, 0.63) at a luminance of 1000 cd/m², showing excellent green light emission. These results are shown in Table 16.

### Comparative Example 2

### Fabrication of Organic Light Emitting Device DCP3

An organic light emitting device was fabricated in the same manner as in Example 7, excepting that a 1.0 wt % xylene solution of the polymer compound CP3 was used instead of the 1.4 wt % xylene solution of the polymer compound P1 (hereinafter, referred to as “organic light emitting device DCP3”). For the organic light emitting device DCP3, light-emission luminance, efficiency, voltage and chromaticity thereof were measured in the same manner as in Example 7, to find that the driving voltage was 6.7 V, the light emission efficiency was 2.1 cd/A and the CIE chromaticity coordinate was (0.26, 0.63) at a luminance of 1000 cd/m², showing excellent green light emission. These results are shown in Table 16.

TABLE 16

At luminance of
1000 [cd/m²]

| | | light emission | driving |
|---|---|---|---|
| | | efficiency | voltage |
| | | [cd/A] | [V] |
| Example 9 | organic light | 7.5 | 5.8 |
| | emitting device | | |
| | DP3 | | |
| Example 10 | organic light | 11.8 | 5.9 |
| | emitting device | | |
| | DP4 | | |
| Comparative | organic light | 2.1 | 6.7 |
| Example 2 | emitting device | | |
| | DCP3 | | |

The polymer compound P3 and the polymer compound P4 are polymer compounds having as the first constitutional unit a constitution chain directly linking the constitutional unit (1) and the constitutional unit (3) in the polymer compound CP3. As shown in Table 16, it is understood that the organic light emitting device DP3 using the polymer compound P3 and the organic light emitting device DP4 using the polymer compound P4 are light emitting devices showing higher light emission efficiency and lower driving voltage, owing to the presence of the first constitutional unit, as compared with the organic light emitting device DCP3 using the polymer compound CP3.

### Example 11

### Synthesis of Polymer Compound P6

2,7-bis(4,4,5,5-tetramethyl-1,3,2-dioxaborolan-2-yl)-9,9-bis(4-n-hexylphenyl)fluorine (1.5630 g, 2.12 mmol), 2,7-bis(4,4,5,5-tetramethyl-1,3,2-dioxaborolan-2-yl)-9,9-dioctylfluorene (0.5288 g, 0.82 mmol), 9,9-bis(3-n-hexylphenyl)-2,7-dibromofluorene (1.7048 g, 2.64 mmol), N,N′-bis(4-bromophenyl)-N,N′-bis(2,6-dimethyl-4-tert-butylphenyl)-1,4-phenylenediamine (0.1737 g, 0.24 mmol), the mixture of the compound M1a and the compound M1b synthesized in Example 1 (0.0581 g, 0.06 mmol) and toluene (64 mL) were mixed to prepare a monomer solution. Under a nitrogen gas atmosphere, the monomer solution was heated, bistriphenylphosphinepalladium dichloride (2.1 mg) was added, then, a 20 wt % tetraethylammonium hydroxide aqueous solution (10.0 mL) was dropped at 100° C. over a period of about 60 minutes. The mixture was stirred at 100° C. for 4.5 hours from initiation of dropping of the tetraethylammonium hydroxide aqueous solution. Next, to the resultant solution were additionally added phenylboronic acid (36.3 mg), bistriphenylphosphinepalladium dichloride (1.1 mg) and a 20 wt % tetraethylammonium hydroxide aqueous solution (10.0 mL), and the mixture was further stirred for 24 hours.

The aqueous layer was removed from the reaction solution, then, sodium N,N-diethyldithiocarbamate trihydrate (1.63 g) and ion exchanged water (33 mL) were added and the mixture was stirred at 85° C. for 2 hours. In the resultant solution, the organic layer was separated from the aqueous layer, then, the organic layer was washed with ion exchanged water (three times), with a 3 wt % acetic acid aqueous solution (three times) and with ion exchanged water (three times) in this order.

The organic layer was dropped into methanol, to find precipitation of a solid. This solid was filtrated, then, dried to obtain a solid. This solid was dissolved in toluene, the solution was allowed to pass through a silica gel/alumina column through which toluene had previously passed and the passed eluate was dropped into methanol, to find precipitation of a solid. This solid was filtrated, then, dried. This solid (hereinafter, referred to as “polymer compound P6”) showed a yield of 2.480 g. The polymer compound P6 had a polystyrene-equivalent number-average molecular weight of 9.9×10⁴, a polystyrene-equivalent weight-average molecular weight of 3.0×10⁵ and a glass transition temperature Tg of 129° C.

It is guessed from the structures and charging ratios of raw materials that the polymer compound P6 is a polymer composed of constitutional units having structures and ratios (molar ratios) shown in Table 17.

TABLE 17

| | first constitutional unit | | second constitutional unit |
|---|---|---|---|
| structure | 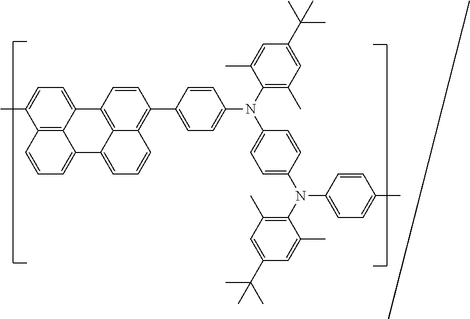 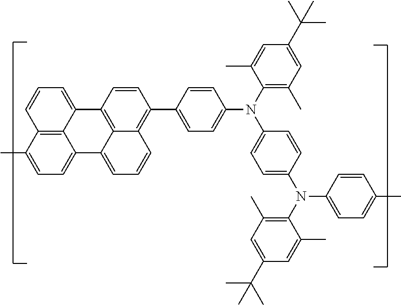 | | 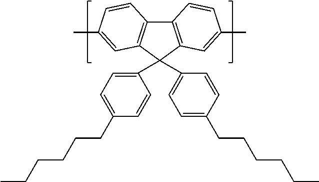 |
| ratio | 1 | | 36 |
| (% by mol) | | | |
| | second constitutional unit | | third constitutional unit |
| structure | 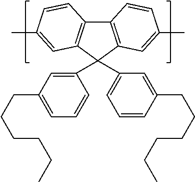 | 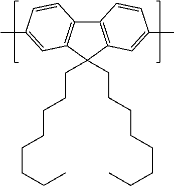 | 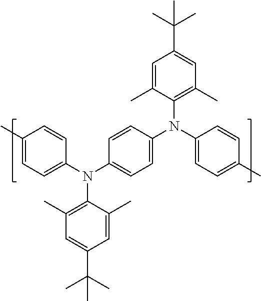 |
| ratio | 45 | 14 | 4 |
| (% by mol) | | | |

### Synthesis Example 6

### Synthesis of Polymer Compound CP4

2,7-bis(4,4,5,5-tetramethyl-1,3,2-dioxaborolan-2-yl)-9,9-bis(4-n-hexylphenyl)fluorine (1.7965 g, 2.43 mmol), 2,7-bis(1,3,2-dioxaborolan-2-yl)-9,9-dioctylfluorene (0.5016 g, 0.95 mmol), 9,9-bis(3-n-hexylphenyl)-2,7-dibromofluorene (1.9159 g, 2.97 mmol), N,N′-bis(4-bromophenyl)-bis(2,6-dimethyl-4-tert-butylphenyl)-1,4-phenylenediamine (0.2495 g, 0.34 mmol), the mixture of the compound CM1a and the compound CM1b synthesized in Synthesis Example 1 (0.0277 g, 0.07 mmol) and toluene (73 mL) were mixed to prepare a monomer solution. Under an argon gas atmosphere, this monomer solution was heated, to this was added bistriphenylphosphinepalladium dichloride (2.4 mg), then, a 20 wt % tetraethylammonium hydroxide aqueous solution (10.9 mL) was dropped at 100° C. over a period of about 60 minutes. The mixture was stirred at 100° C. for 3 hours from initiation of dropping of the tetraethylammonium hydroxide aqueous solution. Next, to the resultant solution were additionally added phenylboronic acid (41.6 mg), bistriphenylphosphinepalladium dichloride (1.3 mg) and a 20 wt tetraethylammonium hydroxide aqueous solution (11.5 mL), and the mixture was further stirred for 16.5 hours.

The aqueous layer was removed from the reaction solution, then, to this were added sodium N,N-diethyldithiocarbamate trihydrate (1.88 g) and ion exchanged water (38 mL) and the mixture was stirred at 85° C. for 2 hours. In the resultant solution, the organic layer was separated from the aqueous layer, then, the organic layer was washed with ion exchanged water (three times), with a 3 wt % acetic acid aqueous solution (three times) and with ion exchanged water (three times) in this order.

The organic layer was dropped into methanol, to find precipitation of a solid. This solid was filtrated, then, dried to obtain a solid. This solid was dissolved in toluene, the solution was allowed to pass through a silica gel/alumina column through which toluene had previously passed and the passed eluate was dropped into methanol, to find precipitation of a solid. This solid was filtrated, then, dried. This solid (hereinafter, referred to as “polymer compound CP4”) showed a yield of 2.326 g. The polymer compound CP4 had a polystyrene-equivalent number-average molecular weight of 1.1×10⁵, a polystyrene-equivalent weight-average molecular weight of 2.5×10⁵ and a glass transition temperature Tg of 132° C.

It is guessed from the structures and charging ratios of raw materials that the polymer compound CP4 is a polymer composed of constitutional units having structures and ratios (molar ratios) shown in Table 18.

TABLE 18

| | first constitutional unit | second constitutional unit | |
|---|---|---|---|
| structure | 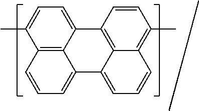 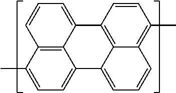 | 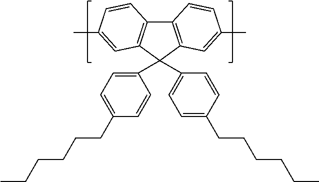 | 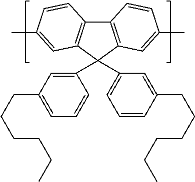 |
| ratio | 1 | 36 | 45 |
| (% by mol) | | | |

| structure | second constitutional unit | third constitutional unit |
|---|---|---|
| | 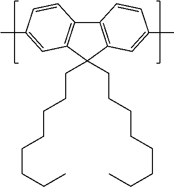 | 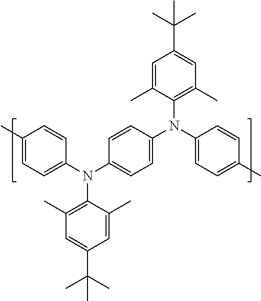 |
| ratio | 14 | 4 |
| (% by mol) | | |

### Synthesis Example 7

### Synthesis of Polymer Compound CP5

Under a nitrogen atmosphere, a mixture of 2, 7-bis(1,3,2-dioxaborolan-2-yl)-9,9-dioctylfluorene (21.218 g, 40.01 mmol), 2,7-dibromo-9,9-dioctylfluorene (5.487 g, 10.00 mmol), N,N-bis(4-bromophenyl)-N′,N′-bis(4-butylphenyl)-1,4-benzenediamine (16.377 g, 23.99 mmol), N,N-bis(4-bromophenyl)-bicyclo[4.2.0]octa-1,3,5-triene-3-amine (2.575 g, 6.00 mmol), methyltrioctylammonium chloride (trade name: Aliquat (registered trademark) 336, manufactured by Aldrich) (5.17 g) and toluene (400 mL) as a solvent was heated at about 80° C., then, bistriphenylphosphinepalladium dichloride (56.2 mg) and a 17.5 wt % sodium carbonate aqueous solution (109 ml) were added, and the mixture was stirred for about 6 hours under reflux while further heating in an oil bath.

Next, benzeneboronic acid (0.49 g) was added, and the mixture was stirred for about 2 hours under reflux while further heating in an oil bath.

The aqueous layer was removed by liquid-separation, then, a solution prepared by dissolving sodium N,N-diethyldithiocarbamate trihydrate (24.3 g) in ion exchanged water (240 mL) was added, and the mixture was stirred for 2 hours while heating at 85° C.

The organic layer was separated from the aqueous layer, then, the organic layer was washed with ion exchanged water (about 520 mL) twice, with a 3 wt % acetic acid aqueous solution (about 52 mL) twice and with ion exchanged water (about 520 mL) twice sequentially. The organic layer was dropped into methanol, to cause precipitation of the polymer compound, which was filtrated and dried, to obtain a solid. This solid was dissolved in toluene (about 1240 mL), the solution was allowed to pass through a silica gel column and an alumina column through which toluene had previously passed, and the resultant solution was dropped into methanol (about 6200 mL) to cause precipitation of the polymer compound, which was filtrated and dried, to obtain a polymer compound CP5 (26.23 g).

The polymer compound CP5 had a polystyrene-equivalent number-average molecular weight (Mn) and a weight-average molecular weight (Mw) of Mn=7.8×10⁴ and Mw=2.6×10⁵, respectively, and a glass transition temperature of 115° C. It is guessed from the structures and charging ratios of raw materials that this polymer compound CP5 is a polymer composed of constitutional units having structures and ratios (molar ratios) shown in Table 19.

TABLE 19

| | | | | |
|---|---|---|---|---|
| CP3 | 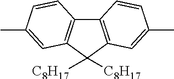 | 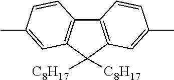 | 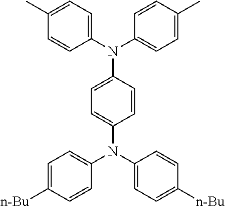 | 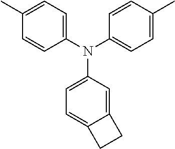 |
| constitutional | 50 | 12.5 | 30 | 7.5 |
| unit ratio | | | | |

### Example 12

### Fabrication of Organic Light Emitting Device DP6

On a glass substrate carrying thereon an ITO film with a thickness of 45 nm formed by a sputtering method, AQ-1200 (manufactured by Plextronics) which is a polythiophene•sulfonic acid type hole injecting agent was spin-coated to form a film with a thickness of about 65 nm, which was then dried on a hot plate at 170° C. for 15 minutes. Next, the polymer compound CP5 was dissolved in xylene (manufactured by Kanto Chemical Co., Inc., for electronic industry (EL grade)) at a concentration of 0.7% by weight. The resultant xylene solution was spin-coated at a rotating speed of 1890 rpm on the above-described film to form a film of the polymer compound CP5 with a thickness of 20 nm, then, the film was dried at 180° C. for 60 minutes under a nitrogen atmosphere in which both the oxygen concentration and the moisture concentration were 10 ppm or less (by weight). Next, a 1.6 wt % xylene solution of the polymer compound P6 was prepared. This xylene solution was spin-coated at a rotating speed of 2800 rpm to form a film with a thickness of about 80 nm on the film of the polymer compound CP5, then, the film was dried at 130° C. for 10 minutes under a nitrogen atmosphere in which both the oxygen concentration and the moisture concentration were 10 ppm or less (by weight), to give a light emitting layer. After pressure reduction to 1.0×10 Pa or less, sodium fluoride was vapor-deposited with a thickness of about 3 nm on the film of the polymer compound P6, then, aluminum was vapor-deposited with a thickness of about 80 nm on the sodium fluoride layer, as a cathode. After vapor deposition, it was sealed using a glass plate to fabricate an organic light emitting device (hereinafter, referred to as “organic light emitting device DP6”). A voltage was applied from 0 V to 12 V on the organic light emitting device DP6 using OLED 25ch-IVL measurement apparatus manufactured by System Engineers' Co., Ltd. to cause light emission of the device, and light-emission luminance, efficiency and chromaticity thereof were measured, to find that the driving voltage was 4.4 V, the light emission efficiency was 21.8 cd/A and the CIE chromaticity coordinate was (0.36, 0.59) at a luminance of 1000 cd/m², showing excellent green light emission. The initial luminance was set at 8000 cd/m² and the device was driven under constant current, to find that the time necessary until 80% luminance (that is, 20% reduction of luminance from the initial luminance) was 110 hours. These results are shown in Table 20.

### Comparative Example 3

### Fabrication of Organic Light Emitting Device DCP4

An organic light emitting device was fabricated in the same manner as in Example 12, excepting that a 1.6 wt % xylene solution of the polymer compound CP4 was used instead of the 1.6 wt % xylene solution of the polymer compound P6 and the rotation speed of spin coating was changed from 2800 rpm to 2380 rpm (hereinafter, referred to as “organic light emitting device DCP4”). For the organic light emitting device DCP4, light-emission luminance, efficiency, voltage and chromaticity thereof were measured in the same manner as in Example 12, to find that the driving voltage was 4.8 V, the light emission efficiency was 18.2 cd/A and the CIE chromaticity coordinate was (0.28, 0.61) at a luminance of 1000 cd/m², showing excellent green light emission. The initial luminance was set at 8000 cd/m² and the device was driven under constant current, to find that the time necessary until 80% luminance (that is, 20% reduction of luminance from the initial luminance) was 89 hours. These results are shown in Table 20.

TABLE 20

| | | At luminance of | | time [hr] |
|---|---|---|---|---|
| | | 1000 [cd/m²] | | necessary until |
| | | light | | 80% luminance |
| | | emission | driving | at initial |
| | | efficiency | voltage | luminance of |
| | | [cd/A] | [V] | 8000 cd/m² |
| Example 12 | organic light | 21.8 | 4.4 | 110 |
| | emitting | | | |
| | device DP6 | | | |
| Comparative | organic light | 18.2 | 4.8 | 89 |
| Example 3 | emitting | | | |
| | device DCP4 | | | |

The polymer compound P6 is a polymer compound having as the first constitutional unit a constitution chain directly linking the constitutional unit (1) and the constitutional unit (3) in the polymer compound CP4. As shown in Table 20, the organic light emitting device DP6 using the polymer compound P6 is a light emitting device showing higher light emission efficiency, better luminance stability in driving and lower driving voltage, owing to the presence of the first constitutional unit, as compared with the organic light emitting device DCP4 using the polymer compound CP4.

### Example 13

### Synthesis of Polymer Compound P7

In this example, the following compound MC-4 was used as a raw material monomer as an original of a phosphorescent constitutional unit. The compound MC-4 was synthesized according to a method described in JP-A No. 2001-105701.

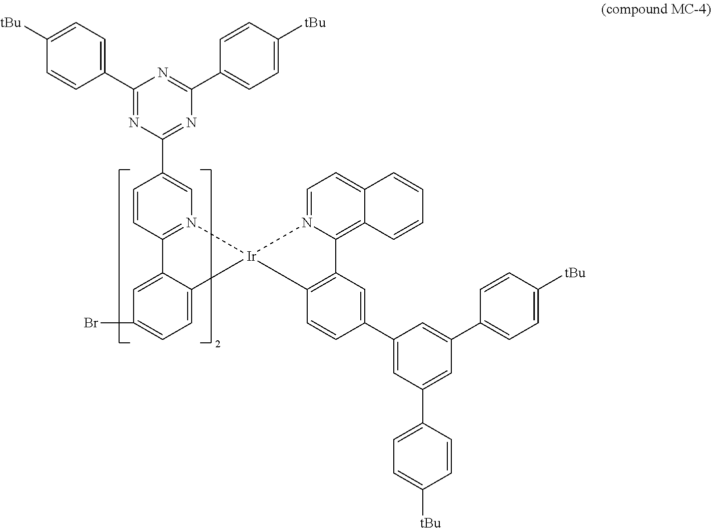

2,7-bis(4,4,5,5-tetramethyl-1,3,2-dioxaborolan-2-yl)-9,9-bis(4-n-hexylphenyl)fluorine (0.7977 g, 1.08 mmol), 2,7-bis(4,4,5,5-tetramethyl-1,3,2-dioxaborolan-2-yl)-9,9-dioctylfluorene (0.2699 g, 0.42 mmol), 9,9-bis(3-n-hexylphenyl)-2,7-dibromofluorene (0.8631 g, 1.34 mmol), N,N′-bis(4-bromophenyl)-N,N′-bis(2,6-dimethyl-4-tert-butylphenyl)-1,4-phenylenediamine (0.1108 g, 0.15 mmol), the mixture of the compound M1a and the compound M1b synthesized in Example 1 (0.0047 g, 0.0048 mmol), the compound MC-4 (0.0113 g, 0.0060 mmol) and toluene (47 mL) were mixed to prepare a monomer solution. Under a nitrogen gas atmosphere, the monomer solution was heated, bistriphenylphosphinepalladium dichloride (1.1 mg) was added, then, a 20 wt % tetraethylammonium hydroxide aqueous solution (5.1 mL) was dropped at 100° C. over a period of about 25 minutes. The mixture was stirred at 100° C. for 3.5 hours from initiation of dropping of the tetraethylammonium hydroxide aqueous solution. Next, to the resultant solution were added phenylboronic acid (36.9 mg), bistriphenylphosphinepalladium dichloride (1.1 mg) and a 20 wt % tetraethylammonium hydroxide aqueous solution (5.1 mL), and the mixture was further stirred for 18.5 hours.

The aqueous layer was removed from the reaction solution, then, to this were added sodium N,N-diethyldithiocarbamate trihydrate (0.42 g) and ion exchanged water (8 mL), and the mixture was stirred at 85° C. for 2.5 hours. In the resultant solution, the organic layer was separated from the aqueous layer, then, the organic layer was washed with ion exchanged water (twice), with a 3 wt % acetic acid aqueous solution (twice) and with ion exchanged water (twice) in this order.

The organic layer was dropped into methanol, to find precipitation of a solid. This solid was filtrated, then, dried to obtain a solid. This solid was dissolved in toluene, the solution was allowed to pass through a silica gel/alumina column through which toluene had previously passed and the passed eluate was dropped into methanol, to find precipitation of a solid. This solid was filtrated, then, dried. This solid (hereinafter, referred to as “polymer compound P7”) showed a yield of 1.278 g. The polymer compound P7 had a polystyrene-equivalent number-average molecular weight of 1.4×10⁵ and a polystyrene-equivalent weight-average molecular weight of 4.7×10⁵.

It is guessed from the structures and charging ratios of raw materials that the polymer compound P7 is a polymer composed of constitutional units having structures and ratios (molar ratios) shown in Table 21.

TABLE 21

| | first constitutional unit | second constitutional unit |
|---|---|---|
| structure | 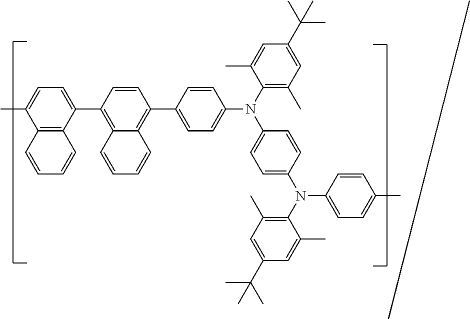 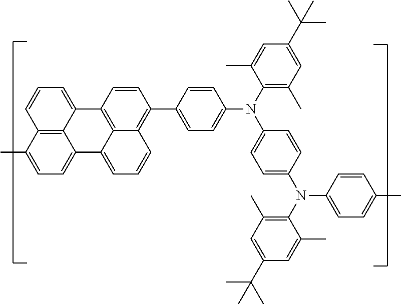 | 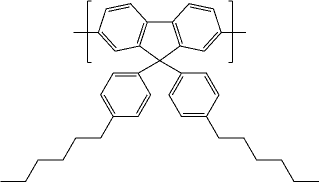 |
| ratio | 0.14 | 36 |
| (% by | | |
| mol) | | |

| | second constitutional unit | |
|---|---|---|
| structure | 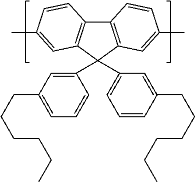 | 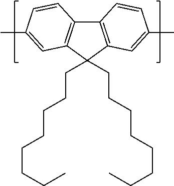 |
| ratio | 44.64 | 14 |
| (% by | | |
| mol) | | |

| | third consitutional unit |
|---|---|
| structure | 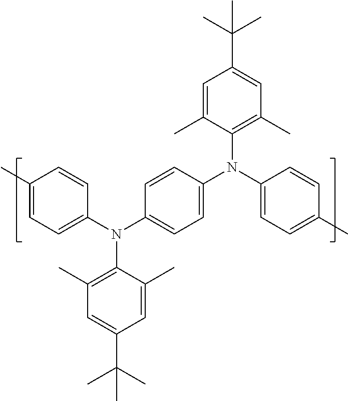 |
| ratio | 5 |
| (% by | |
| mol) | |
| | phosphorescent constitutional unit |
| structure | 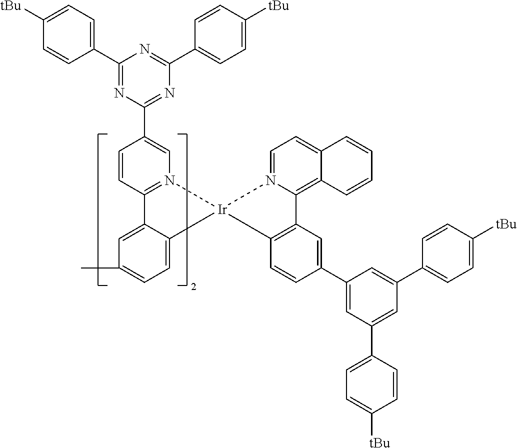 |
| ratio | 0.20 |
| (% by | |
| mol) | |

### Example 14

### Fabrication of Organic Light Emitting Device DP7

On a glass substrate carrying thereon an ITO film with a thickness of 45 nm formed by a sputtering method, AQ-1200 (manufactured by Plextronics) which is a polythiophene•sulfonic acid type hole injecting agent was spin-coated to form a film with a thickness of about 65 nm, which was then dried on a hot plate at 170° C. for 15 minutes. Next, the polymer compound CP5 was dissolved in xylene (manufactured by Kanto Chemical Co., Inc., for electronic industry (EL grade)) at a concentration of 0.7% by weight. The resultant xylene solution was spin-coated at a rotating speed of 1890 rpm on the above-described film to form a film of the polymer compound CP5 with a thickness of 20 nm, then, the film was dried at 180° C. for 60 minutes under a nitrogen atmosphere in which both the oxygen concentration and the moisture concentration were 10 ppm or less (by weight). Next, a 1.4 wt % xylene solution of the polymer compound P7 was prepared. This xylene solution was spin-coated at a rotating speed of 2910 rpm to form a film with a thickness of about 80 nm on the film of the polymer compound CP5, then, the film was dried at 130° C. for 10 minutes under a nitrogen atmosphere in which both the oxygen concentration and the moisture concentration were 10 ppm or less (by weight), to give a light emitting layer. After pressure reduction to 1.0×10−4 Pa or less, sodium fluoride was vapor-deposited with a thickness of about 3 nm on the film of the polymer compound P7, then, aluminum was vapor-deposited with a thickness of about 80 nm on the sodium fluoride layer, as a cathode. After vapor deposition, it was sealed using a glass plate to fabricate an organic light emitting device (hereinafter, referred to as “organic light emitting device DP7”). A voltage was applied from 0 V to 12 V on the organic light emitting device DP7 using OLED 25ch-IVL measurement apparatus manufactured by System Engineers' Co., Ltd. to cause light emission of the device, and light-emission luminance, efficiency and chromaticity thereof were measured, to find a driving voltage of 7.5 V, a light emission efficiency of 12.4 cd/A and while light emission at a luminance of 1000 cd/m². The light emission spectrum of the organic light emitting device DP7 at 1000 cd/m² is shown in FIG. 5. The initial luminance was set at 8000 cd/m² and the device was driven for 500 hours under constant condition, to observe a luminance maintenance ratio of 60%.

The polymer compound P7 is a polymer compound having as the first constitutional unit a constitution chain directly linking the constitutional unit (1) and the constitutional unit (3). As shown in FIG. 5, the EL spectrum of the organic light emitting device DP7 obtained by using the polymer compound P7 shows light emission spectra in a blue range around 420 to 470 nm, a green range around 500 to 550 nm and a red range around 600 to 650 nm, thus, it is understood that the polymer compound of the present invention can give a light emitting device showing high efficiency, long life and excellent white light emission in one preferable embodiment thereof.

### INDUSTRIAL APPLICABILITY

According to the present invention, a polymer compound which is useful for production of an organic light emitting device excellent in light emission efficiency can be provided. In preferable embodiments, this polymer compound is also excellent in driving stability of light-emission luminance, and useful also for production of an organic light emitting device showing long life.

1. A polymer compound comprising as a constitutional unit a residue of a compound represented by the following general formula (1): 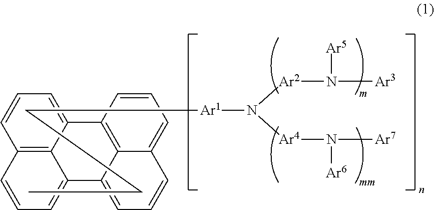
wherein
n is an integer of 1 to 4;
m and mm are each independently 0 or 1;
Ar¹ represents an arylene group or a divalent aromatic heterocyclic group,
Ar² and Ar⁴ each independently represent an arylene group, a divalent aromatic heterocyclic group or a divalent group obtained by linking two or more identical or different groups selected from the group consisting of an arylene group and a divalent aromatic heterocyclic group,
Ar³, Ar⁵, Ar⁶ and Ar⁷ each independently represent an aryl group or a monovalent aromatic heterocyclic group,
Ar¹, Ar², Ar³, Ar⁴, Ar⁵, Ar⁶ and Ar⁷ may have one or several substituents selected from the group consisting of an alkyl group, an aryl group, a monovalent aromatic heterocyclic group, a group represented by —O—R^{A}, a group represented by a group represented by —C(═O)—R^{A}, a group represented by —C(═O)—O—R^{A}, a cyano group and a fluorine atom, and
of groups represented by Ar¹, Ar², Ar³, Ar⁴, Ar⁵, Ar⁶ and Ar⁷, groups linked to the same nitrogen atom may be mutually linked via a single bond or a group represented by —O—, —S—, —C(═O)—, —C(═O)—O—, —N(R^{A})—, —C(═O)—N(R^{A})— or —C(R^{A})(R^{A})—;
R^{A} represents an alkyl group, an aryl group or a monovalent aromatic heterocyclic group, and these groups may have a substituent, when a plurality of R^{A}s are present, these may be the same or different.

2. The polymer compound according to claim 1, wherein the compound represented by said general formula (1) is a compound represented by the following general formula (1a) or the following general formula (1b): 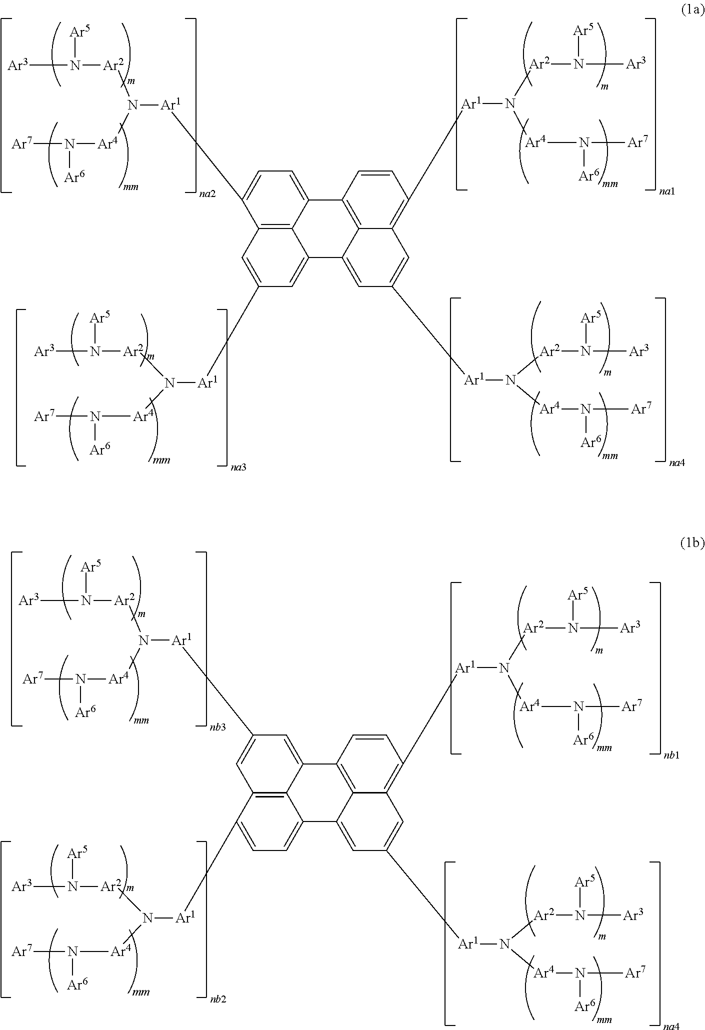
wherein
m, mm, Ar¹, Ar², Ar³, Ar⁴, Ar⁵, Ar⁶ and Ar⁷ represent the same meaning as described above. na1, na2, na3, na4, nb1, nb2, nb3 and nb4 are each independently 0 or 1,
with the proviso that at least one of na1, na2, na3 and na4 is 1, and at least one of nb1, nb2, nb3 and nb4 is 1,
when there are a plurality of ms, mms, Ar¹s, Ar²s, Ar³s, Ar⁴s, Ar⁵s, Ar⁶s and Ar⁷s, respective symbols may be the same or different.

3. The polymer compound according to claim 2, wherein na1 and nb1 are 1 and na3, na4, nb3 and nb4 are 0.

4. The polymer compound according to claim 3, wherein na2 and nb2 are 0.

5. The polymer compound according to claim 4, wherein m is 1 and mm is 0.

6. The polymer compound according to claim 1, further comprising a constitutional unit represented by the following general formula (2): 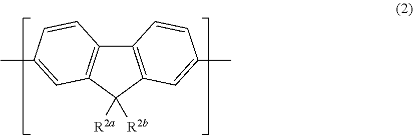
wherein
R^{2a} and R^{2b} each independently represent an alkyl group, an aryl group or a monovalent aromatic heterocyclic group, alternatively R^{2a} and R^{2b} are mutually linked together to represent a divalent group;
the constitutional unit represented by the formula (2) may have one or several substituents selected from the group consisting of an alkyl group, an aryl group, a monovalent aromatic heterocyclic group, a group represented by —O—R^{A}, a group represented by —S—R^{A}, a group represented by —C(═O)—R^{A}, a group represented by —C(═O)—O—R^{A}, a group represented by —N(R^{A})₂, a cyano group and a fluorine atom;
R^{A} represents the same meaning as described above.

7. The polymer compound according to claim 6, wherein the content of the constitutional unit composed of the residue of the compound represented by said general formula (1) is 0.1% by mol or more and 20% by mol or less with respect to the total content of the constitutional unit composed of the residue of the compound represented by said general formula (1) and the constitutional unit represented by said general formula (2).

8. The polymer compound according to claim 6, wherein the total content of the constitutional unit composed of the residue of the compound represented by said general formula (1) and the constitutional unit represented by said general formula (2) is 80% by mass or more with respect to the total amount of said polymer compound.

9. The polymer compound according to claim, 6, further comprising a constitutional unit represented by the following general formula (3): 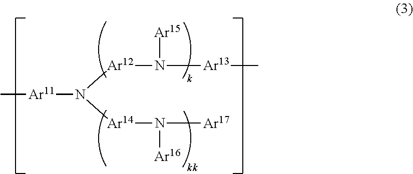
wherein
k and kk are each independently 0 or 1;
Ar¹¹, Ar¹², Ar¹³ and Ar¹⁴ each independently represent an arylene group, a divalent aromatic heterocyclic group or a divalent group obtained by linking two or more identical or different groups selected from the group consisting of an arylene group and a divalent aromatic heterocyclic group,
Ar¹⁵, Ar¹⁶ and Ar¹⁷ each independently represent an aryl group or a monovalent aromatic heterocyclic group,
Ar¹¹, Ar¹², Ar¹³, Ar¹⁴, Ar¹⁵, Ar¹⁶ and Ar¹⁷ may have one or several substituents selected from the group consisting of an alkyl group, an aryl group, a monovalent aromatic heterocyclic group, a group represented by —O—R^{A}, a group represented by —S—R^{A}, a group represented by —C(═O)—R^{A}, a group represented by —C(═O)—O—R^{A}, a cyano group and a fluorine atom, and
of groups represented by Ar¹¹, Ar¹², Ar¹³, Ar¹⁴, Ar¹⁵, Ar¹⁶ and Ar¹⁷, groups linked to the same nitrogen atom may be mutually linked via a single bond or a group represented by —O—, —S—, —C(═O)—, —C(═O)—O—, —N(R^{A})—, —C(═O)—N(R^{A})— or —C(R^{A})(R^{A})—;
R^{A} represents the same meaning as described above.

10. The polymer compound according to claim 9, wherein the content of the constitutional unit composed of the residue of the compound represented by said general formula (1) is 0.1% by mol or more and 15% by mol or less with respect to the total content of the constitutional unit composed of the residue of the compound represented by said general formula (1), the constitutional unit represented by said general formula (2) and the constitutional unit represented by said general formula (3).

11. The polymer compound according to claim 9, wherein the total content of the constitutional unit composed of the residue of the compound represented by said general formula (1), the constitutional unit represented by said general formula (2) and the constitutional unit represented by said general formula (3) is 80% by mass or more with respect to the total amount of said polymer compound.

12. The polymer compound according to claim 2, comprising as a constitutional unit a residue of a compound represented by said general formula (1a) and comprising as a constitutional unit a residue of a compound represented by said general formula (1b).

13. The polymer compound according to claim 1, further comprising a constitutional unit derived from a phosphorescent compound.

14. A composition comprising the polymer compound according to claim 1 and at least one material selected from the group consisting of a hole transporting material, an electron transporting material and a light emitting material.

15. A composition comprising the polymer compound according to claim 1 and a solvent.

16. A composition comprising the polymer compound according to claim 1, a solvent and at least one material selected from the group consisting of a hole transporting material, an electron transporting material and a light emitting material.

17. An organic film comprising the polymer compound according to claim 1.

18. An organic film produced by using the composition according to claim 15.

19. An organic semiconductor device having the organic film according to claim 17.

20. An organic light emitting device having the organic film according to claim 17.

21. A surface light source having the organic light emitting device according to claim 20.

22. A display having the organic light emitting device according to claim 20.

23. A compound represented by the following general formula (Ma) or the following general formula (Mb): 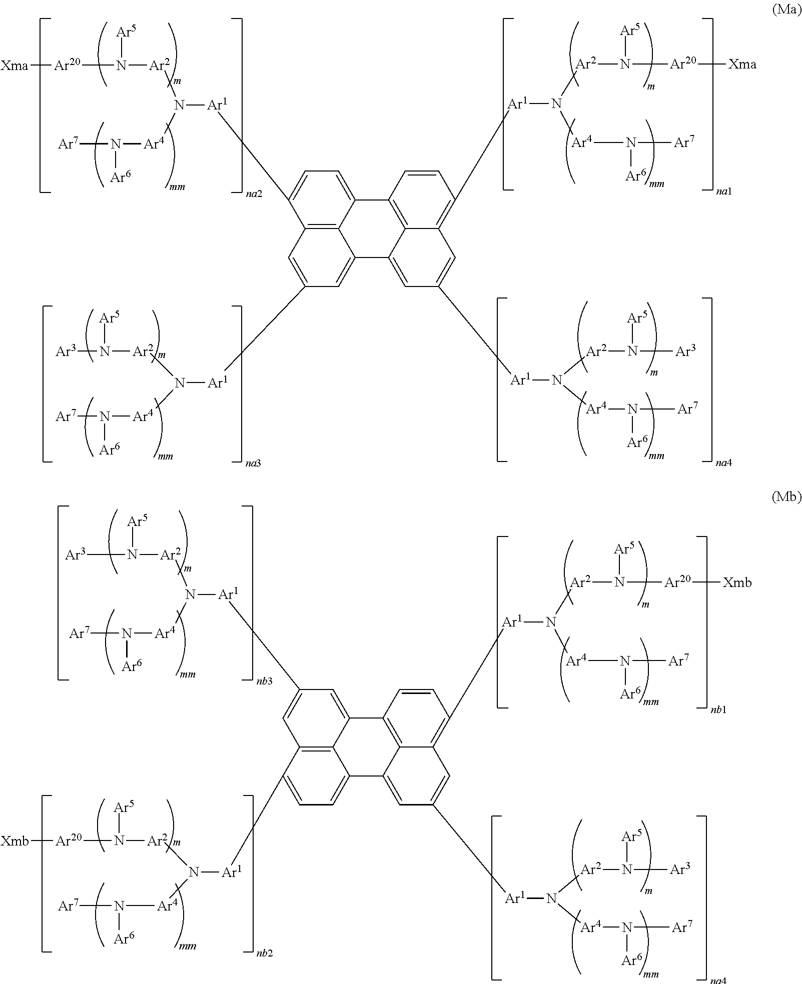
wherein
m and mm are each independently 0 or 1;
Ar¹ represents an arylene group or a divalent aromatic heterocyclic group,
Ar² and Ar⁴ each independently represent an arylene group, a divalent aromatic heterocyclic group or a divalent group obtained by linking two or more identical or different groups selected from the group consisting of an arylene group and a divalent aromatic heterocyclic group,
Ar³, Ar⁵, Ar⁶ and Ar⁷ each independently represent an aryl group or a monovalent aromatic heterocyclic group,
Ar¹, Ar², Ar³, Ar⁴, Ar⁵, Ar⁶ and Ar⁷ may have one or several substituents selected from the group consisting of an alkyl group, an aryl group, a monovalent aromatic heterocyclic group, a group represented by —O—R^{A}, a group represented by —S—R^{A}, a group represented by —C(═O)—R^{A}, a group represented by —C(═O)—O—R^{A}, a cyano group and a fluorine atom, and
of groups represented by Ar¹, Ar², Ar³, Ar⁴, Ar⁵, Ar⁶ and Ar⁷, groups linked to the same nitrogen atom may be mutually linked via a single bond or a group represented by —O—, —S—, —C(═O)—, —C(═O)—O—, —N(R^{A})—, —C(═O)—N(R^{A})— or —C(R^{A})(R^{A})—;
R^{A} represents an alkyl group, an aryl group or a monovalent aromatic heterocyclic group, and these groups may have a substituent, when a plurality of R^{A}s are present, these may be the same or different;
na1, na2, na3, na4, nb1, nb2, nb3 and nb4 are each independently 0 or 1,
with the proviso that at least one of na1, na2, na3 and na4 is 1, and at least one of nb1, nb2, nb3 and nb4 is 1,
when there are a plurality of ms, mms, Ar¹s, Ar²s, Ar³s, Ar⁴s, Ar⁵s, Ar⁶s and Ar⁷s, respective symbols may be the same or different;
Ar²⁰ represents an arylene group or a divalent aromatic heterocyclic group, and when there are a plurality of Ar²⁰s, these may be the same or different;
Xma and Xmb each independently represent a group selected from the group consisting of the following substituent group A and the following substituent group B, and two Xmas may be the same or different and two Xmbs may be the same or different;
(Substituent group A)
a chlorine atom, a bromine atom, an iodine atom and groups represented by —O—S(═O)₂R²⁰ wherein R²⁰ represents an alkyl group or an aryl group optionally substituted by an alkyl group, an alkoxy group, a nitro group, a fluorine atom or a cyano group;
(Substituent group B)
groups represented by —B(OR²¹)₂ wherein R²¹ represents a hydrogen atom or an alkyl group, two R²¹s may be the same or different, and may be mutually linked together to form a ring,
groups represented by —BF₄Q¹ wherein Q¹ represents a monovalent cation of lithium, sodium, potassium, rubidium or cesium,
groups represented by —Sn(R²²)₃ wherein R²² represents a hydrogen atom or an alkyl group, three R²²s may be the same or different, and may be mutually linked together to form a ring,
groups represented by —MgY¹ wherein Y¹ represents a chlorine atom, a bromine atom or an iodine atom, and
groups represented by —ZnY² wherein Y² represents a chlorine atom, a bromine atom or an iodine atom.

24. A composition comprising a compound represented by the following general formula (Ma) and a compound represented by the following general formula (Mb): 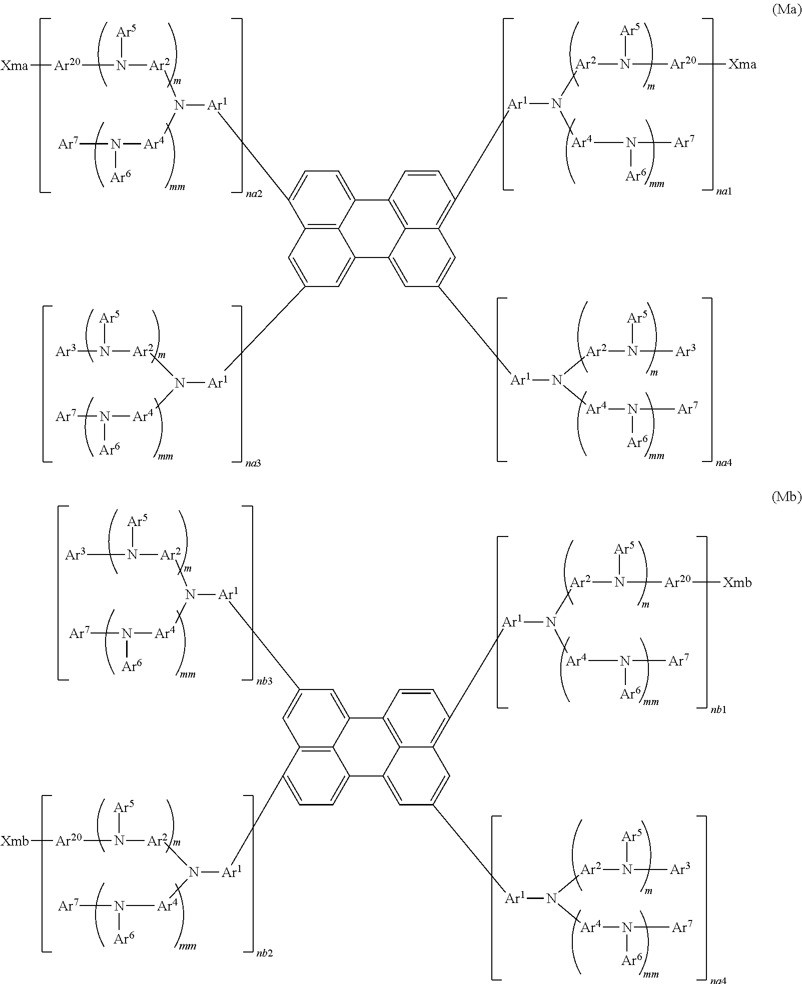
wherein
m and mm are each independently 0 or 1;
Ar¹ represents an arylene group or a divalent aromatic heterocyclic group,
Ar² and Ar⁴ each independently represent an arylene group, a divalent aromatic heterocyclic group or a divalent group obtained by linking two or more identical or different groups selected from the group consisting of an arylene group and a divalent aromatic heterocyclic group,
Ar³, Ar⁵, Ar⁶ and Ar⁷ each independently represent an aryl group or a monovalent aromatic heterocyclic group,
Ar¹, Ar², Ar³, Ar⁴, Ar⁵, Ar⁶ and Ar⁷ may have one or several substituents selected from the group consisting of an alkyl group, an aryl group, a monovalent aromatic heterocyclic group, a group represented by —O—R^{A}, a group represented by —S—R^{A}, a group represented by —C(═O)—R^{A}, a group represented by —C(═O)—O—R^{A}, a cyano group and a fluorine atom, and
of groups represented by Ar¹, Ar², Ar³, Ar⁴, Ar⁵, Ar⁶ and Ar⁷, groups linked to the same nitrogen atom may be mutually linked via a single bond or a group represented by —O—, —S—, —C(═O)—, —C(═O)—O—, —N(R^{A})—, —C(═O)—N(R^{A})— or —C(R^{A})(R^{A})—;
R^{A} represents an alkyl group, an aryl group or a monovalent aromatic heterocyclic group, and these groups may have a substituent, when a plurality of R^{A}s are present, these may be the same or different;
na1, na2, na3, na4, nb1, nb2, nb3 and nb4 are each independently 0 or 1,
with the proviso that at least one of na1, na2, na3 and na4 is 1, and at least one of nb1, nb2, nb3 and nb4 is 1,
when there are a plurality of ms, mms, Ar¹s, Ar²s, Ar³s, Ar⁴s, Ar⁵s, Ar⁶s and Ar⁷s, respective symbols may be the same or different;
Ar²⁰ represents an arylene group or a divalent aromatic heterocyclic group, and when there are a plurality of Ar²⁰s, these may be the same or different;
Xma and Xmb each independently represent a group selected from the group consisting of the following substituent group A and the following substituent group B, and two Xmas may be the same or different and two Xmbs may be the same or different;
(Substituent group A)
a chlorine atom, a bromine atom, an iodine atom and groups represented by —O—S(═O)₂R²⁰ wherein R²⁰ represents an alkyl group or an aryl group optionally substituted by an alkyl group, an alkoxy group, a nitro group, a fluorine atom or a cyano group;
(Substituent group B)
groups represented by —B(OR²¹)₂ wherein R²¹ represents a hydrogen atom or an alkyl group, two R²¹s may be the same or different, and may be mutually linked together to form a ring,
groups represented by —BF₄Q¹ wherein Q¹ represents a monovalent cation of lithium, sodium, potassium, rubidium or cesium,
groups represented by —Sn(R²²)₃ wherein R²² represents a hydrogen atom or an alkyl group, three R²²s may be the same or different, and may be mutually linked together to form a ring,
groups represented by —MgY¹ wherein Y¹ represents a chlorine atom, a bromine atom or an iodine atom, and
groups represented by —ZnY² wherein Y² represents a chlorine atom, a bromine atom or an iodine atom.
